(19) United States
(12) Patent Application Publication
(10) Pub. No.: US 2026/0031768 A1
(43) Pub. Date: Jan. 29, 2026

(54) DYNAMIC DIGITAL PRE-DISTORTION (DPD) SAMPLING RATE SWITCHING BASED ON NETWORK SIGNALING

(71) Applicant: QUALCOMM Incorporated, San Diego, CA (US)

(72) Inventors: Sanjay AVASARALA, San Diego, CA (US); Sanket Vinod AGARWAL, San Diego, CA (US); Akshay RAVI, San Diego, CA (US); Tarandeep VIRK, San Diego, CA (US); Ryan Scott Castro SPRING, San Diego, CA (US); Ashish Kumar BONDIA, Hyderabad (IN)

(21) Appl. No.: 19/173,647

(22) Filed: Apr. 8, 2025

Related U.S. Application Data
(60) Provisional application No. 63/674,666, filed on Jul. 23, 2024.

(51) Int. Cl. H03F 1/32; H04B 1/04

(52) U.S. Cl. CPC H03F 1/3247; H04B 1/0475; H04B 2001/0425

(57) ABSTRACT

An apparatus transmits a transmitted signal in a first band defined by a first center frequency and a first bandwidth, receives parameters associated with other signals in a second band defined by a first frequency and a second frequency greater than the first frequency, the first frequency and the second frequency being outside of the first bandwidth, the other signals being actual or prospective products of the transmitted signal, determines a first sampling frequency associated with the transmitted signal, determines a first digital pre-distortion (DPD) sampling rate based on the first sampling frequency, and changes the first DPD sampling rate to a second DPD sampling rate, greater than the first DPD sampling rate in response to a third frequency, corresponding to the first center frequency shifted by the first DPD sampling rate, being outside the second band. A DPD sampling rate is adjusted based on a network signaling value.

### CROSS-REFERENCE TO RELATED APPLICATIONS

This application for patent claims priority to and the benefit of provisional patent application No. 63/674,666 entitled “Dynamic Digital Pre-Distortion (DPD) Sampling Rate Switching Based on Network Signaling” filed in the United States Patent and Trademark Office on Jul. 23, 2024, the entire content of which is incorporated herein by reference as if fully set forth below in its entirety and for all applicable purposes.

### TECHNICAL FIELD

This disclosure relates generally to wireless communication and, more specifically, to dynamic digital pre-distortion (DPD) sampling rate switching based on network signaling.

### INTRODUCTION

A user equipment (UE) (e.g., an apparatus, a scheduled entity, a wireless communication device, a mobile communication device, a sidelink entity) may include one or more power amplifier circuits. The one or more power amplifier circuits may amplify a signal, such as an uplink signal or a sidelink signal, before transmission of the signal from an antenna or antenna array of a transmitting UE via the one or more power amplifier circuits. The signal may be amplified to, for example, overcome signal attenuation (path loss) between the transmitting UE and a receiving base station and/or a receiving sidelink UE (each referred to as a receiving entity). Some factors that may contribute to path loss include but are not limited to, a distance between the transmitting UE and the receiving entity, atmospheric absorption of the transmitted signal, fading (e.g., due to rain or snow), obstructions in the path of the transmitted signal, and/or multipath characteristics between the transmitting UE and the receiving entity, to name a few. Scientists and engineers continue to research and develop ways to improve the efficiency of power amplifier circuits.

### BRIEF SUMMARY OF SOME EXAMPLES

The systems, methods, and devices of this disclosure each have several innovative aspects, no single one of which is solely responsible for the desirable attributes disclosed herein.

In one example, an apparatus is described. The apparatus includes one or more transmitters, one or more memories, and one or more processors coupled to the one or more transmitters and the one or more memories. The one or more processors are configured to, individually or collectively, based at least in part on information stored in the one or more memories: transmit, from the one or more transmitters, a transmitted signal in a first band defined by a first center frequency and a first bandwidth, receive parameters associated with other signals in a second band defined by a first frequency and a second frequency greater than the first frequency, the first frequency and the second frequency being outside of the first bandwidth, the other signals being actual or prospective products of the transmitted signal, determine a first sampling frequency associated with the transmitted signal, determine a first digital pre-distortion (DPD) sampling rate based on the first sampling frequency, and change the first DPD sampling rate to a second DPD sampling rate, greater than the first DPD sampling rate in response to a third frequency, corresponding to the first center frequency shifted by the first DPD sampling rate, being outside the second band.

In one example, an apparatus is described. The apparatus includes one or more transmitters, one or more memories, and one or more processors coupled to the one or more transmitters and the one or more memories. The one or more processors are configured to, individually or collectively, based at least in part on information stored in the one or more memories, receive a network signaling value, and adjust a DPD sampling rate associated with a digital pre-distortion circuit based on the received network signaling value.

In one example, an apparatus is described. The apparatus includes means for receiving a network signaling value and means for adjusting a DPD sampling rate associated with a digital pre-distortion circuit based on the received network signaling value.

In another example, an apparatus is described. The apparatus includes one or more memories and one or more processors coupled to the one or more memories. In the example the one or more processors are configured to, individually or collectively, based at least in part on information stored in the one or more memories: receive a network signaling value, and adjust a digital pre-distortion (DPD) sampling rate associated with a digital pre-distortion circuit in response to the network signaling value.

In another example a method at an apparatus is described. The method includes receiving a network signaling value, and adjusting a digital pre-distortion (DPD) sampling rate associated with a digital pre-distortion circuit in response to the network signaling value.

In another example an apparatus is described. The apparatus includes one or more memories and one or more processors coupled to the one or more memories. In the example the one or more processors are configured to, individually or collectively, based at least in part on information stored in the one or more memories: receive a network signaling value defining at least a transmission channel bandwidth, an emission band lower frequency, and an emission band upper frequency, digitally pre-distort a digital signal sampled at a digital pre-distortion (DPD) sampling rate, convert the digitally pre-distorted digital signal to an analog signal, upconvert, in frequency, the analog signal, input the upconverted analog signal to a power amplifier configured to transmit at a transmission channel center frequency within the transmission channel bandwidth, and adjust the DPD sampling rate based on a distance between the transmission channel center frequency and a closest one of the emission band lower frequency or the emission band upper frequency.

Details of one or more implementations of the subject matter described in this disclosure are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 is a schematic illustration of an example of a wireless communication system according to some aspects of the disclosure.

FIG. 2 is a schematic illustration of an example of a radio access network according to some aspects of the disclosure.

FIG. 3 is an expanded view of an exemplary subframe, showing an orthogonal frequency division multiplexing (OFDM) resource grid according to some aspects of the disclosure.

FIG. 4A depicts a schematic drawing of a power amplifier, a first graph of an ideal gain transfer function, and a second graph of an exemplary and non-limiting generic real-world gain transfer function according to some aspects of the disclosure.

FIG. 4B depicts a schematic drawing of a digital pre-distortion circuit/function, the amplifier of FIG. 4A, a third graph of the digital pre-distortion transfer function, and a fourth graph of an amplified digitally pre-distorted signal according to some aspects of the disclosure.

FIG. 5 is a simplified high-level block diagram of several components of a transmitter according to some aspects of the disclosure.

FIG. 6A and FIG. 6B are a first example and a second example of respective applications of network signaling indicative of one or more emission constraints in an emission band according to some aspects of the disclosure.

FIG. 7A and FIG. 7B are a first example and a second example of respective applications of network signaling indicative of one or more emission constraints in an emission band according to some aspects of the disclosure.

FIG. 8 is an example of relative distances between an emission band and a transmission channel according to some aspects of the disclosure.

FIG. 9 is an example of relative distances between an emission band and a transmission channel according to some aspects of the disclosure.

FIG. 10 depicts a first graph and a second graph of emission suppression values for channel center frequencies ranging from 723-728 MHz, where the channel center frequencies are in the n28 band, and the emission suppression values are measured in the frequency range defined in N_17 according to some aspects of the disclosure.

FIG. 11A depicts a first graph illustrating channel center frequency versus time and a second graph illustrating DPD sampling rate versus time according to some aspects of the disclosure.

FIG. 11B depicts a third graph illustrating channel center frequency versus time and a fourth graph illustrating DPD sampling rate versus time according to some aspects of the disclosure.

FIG. 12 is a block diagram illustrating a schematic arrangement of signals, circuits/functions, processes, and hardware employing one or more processing systems according to some aspects of the disclosure.

FIG. 13 is a block diagram illustrating an example of a hardware implementation of an apparatus employing one or more processing systems according to some aspects of the disclosure.

FIG. 14 is a flow chart illustrating an example process of wireless communication at an apparatus in accordance with some aspects of the disclosure.

FIG. 15 is a flow chart illustrating an example process of wireless communication at an apparatus in accordance with some aspects of the disclosure.

FIG. 16 is a flow chart illustrating an example process of wireless communication at an apparatus in accordance with some aspects of the disclosure.

FIG. 17 is a flow chart illustrating an example process of wireless communication at an apparatus in accordance with some aspects of the disclosure.

Like reference numbers and designations in the various drawings indicate like elements.

### DETAILED DESCRIPTION

The detailed description set forth below in connection with the appended drawings is directed to some particular examples for the purpose of describing innovative aspects of this disclosure. However, a person having ordinary skill in the art will readily recognize that the teachings herein can be applied in a multitude of different ways. Some or all of the described examples may be implemented in any device, system, or network that is capable of transmitting and receiving radio frequency (RF) signals according to one or more of the Institute of Electrical and Electronics Engineers IEEE) 802.11 standards, the IEEE 802.15 standards, the Bluetooth® standards as defined by the Bluetooth Special Interest Group (SIG), or the Long Term Evolution (LTE), 3G, 4G or 5G (New Radio (NR)) standards promulgated by the 3rd Generation Partnership Project (3GPP), among others. The described examples can be implemented in any device, system, or network that is capable of transmitting and receiving RF signals according to, but not limited to, one or more of the following technologies or techniques: code division multiple access (CDMA), time division multiple access (TDMA), frequency division multiple access (FDMA), orthogonal FDMA (OFDMA), single-carrier FDMA (SC-FDMA), spatial division multiple access (SDMA), rate-splitting multiple access (RSMA), multi-user shared access (MUSA), single-user (SU) multiple input multiple output (MIMO) and multi-user (MU)-MIMO. The described examples also can be implemented using other wireless communication protocols or RF signals suitable for use in one or more of a wireless personal area network (WPAN), a wireless local area network (WLAN), a wireless wide area network (WWAN), a wireless metropolitan area network (WMAN), or an internet of things (IoT) network.

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to persons having ordinary skill in the art that these concepts may be practiced without these specific details. In some examples, well-known structures and components are shown in block diagram form in order to avoid obscuring such concepts.

While aspects and examples are described in this application by illustration to some examples, persons having ordinary skill in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip examples and other non-module-component-based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range a spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for the implementation and practice of claimed and described examples. For example, transmission and reception of wireless signals necessarily includes a number of components for analog and digital purposes (e.g., hardware components including antenna, radio frequency (RF)-chains, power amplifiers, modulators, buffer, processor(s), interleaver, adders/summers, etc.). It is intended that innovations described herein may be practiced in a wide variety of devices, chip-level components, systems, distributed arrangements, disaggregated arrangements (e.g., base station and/or user equipment (UE)), end-user devices, etc. of varying sizes, shapes, and constitution.

Described herein are techniques associated with an apparatus (e.g., a UE) that may implement dynamic digital pre-distortion (DPD) in connection with the use of an amplifier in a transmitter chain of the apparatus. For example, DPD may be used in connection with a power amplifier. In one non-limiting example, the power amplifier may operate in a linear region (operate out of compression). In another non-limiting example, the power amplifier may operate in a non-linear region (e.g., operate in compression). In another non-limiting example, the operation of the power amplifier may transition from the linear to the non-linear region or transition from the non-linear to the linear region.

By way of example and not limitation, a power amplifier operating in its compression region may maximize the power-added efficiency (PAE) associated with an amplification of in-band signals. Still, the operation in the compression region may result in an increase in spurious signals, intermodulation products, and noise out-of-band. The spurious signals, intermodulation products, and noise out-of-band may be due, at least in part, to operating the power amplifier in its non-linear compression region. Gain linearization of an amplified and transmitted signal utilizing digital pre-distortion may suppress the out-of-band spurious signals, intermodulation products, and noise in cases where the DPD sampling rate is increased to overlap in frequency, at least in part, with the frequency of the out-of-band region. Additional suppression may be desirable in cases where network signaling (NS) is scheduled to the apparatus that includes the power amplifier. Accordingly, dynamic DPD sampling rate switching based on network signaling is explored.

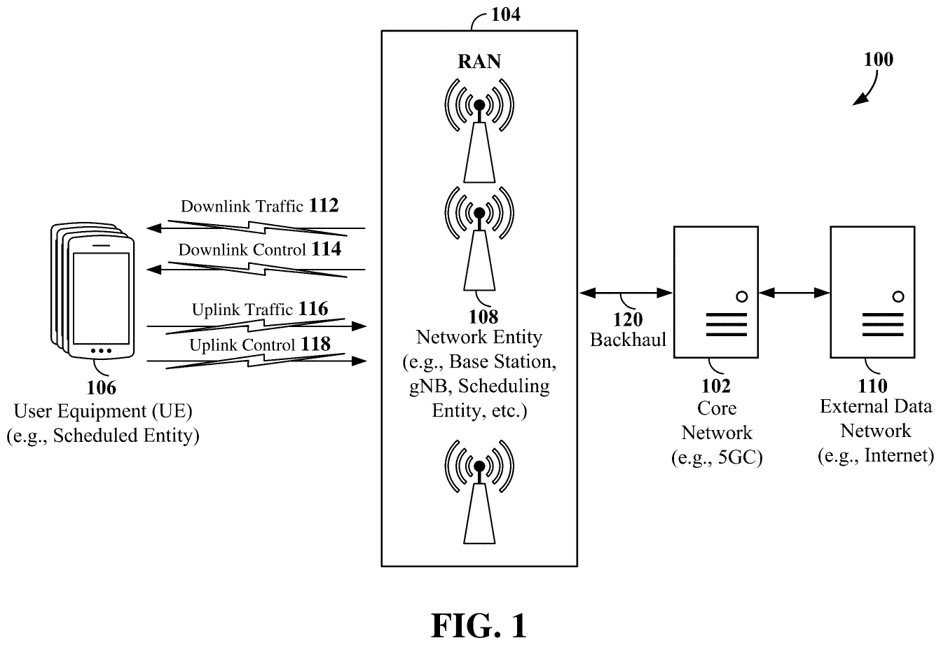

The various concepts presented throughout this disclosure may be implemented across a broad variety of telecommunication systems, network architectures, and communication standards. Referring now to FIG. 1, as an illustrative example without limitation, a schematic illustration of an example of a wireless communication system 100 according to some aspects of the disclosure is presented. The wireless communication system 100 includes three interacting domains: a core network 102, a radio access network (RAN) 104, and a user equipment (UE) 106 (e.g., of a plurality of UEs). By virtue of the wireless communication system 100, the UE 106 (e.g., an apparatus, a scheduled entity, a wireless communication device, a mobile communication device, a sidelink entity) may be enabled to carry out data communication with an external data network 110, such as, but not limited to, the Internet.

The RAN 104 may implement any suitable wireless communication technology or technologies to provide radio access to the UE 106. As one example, the RAN 104 may operate according to 3rd Generation Partnership Project (3GPP) New Radio (NR) specifications, often referred to as 5G. As another example, the RAN 104 may operate under a hybrid of 5G NR and Evolved Universal Terrestrial Radio Access Network (CUTRAN) standards, often referred to as Long Term Evolution (LTE). The 3GPP refers to this hybrid RAN as a next-generation RAN or NG-RAN. Of course, many other examples may be utilized within the scope of the present disclosure.

As illustrated, the RAN 104 includes a plurality of network entities 108. Broadly, a network entity 108 may be implemented in an aggregated or monolithic base station architecture or a disaggregated base station architecture and may include one or more of a central unit (CU), a distributed unit (DU), a radio unit (RU), a Near-Real Time (Near-RT) RAN Intelligent Controller (RIC), or a Non-Real Time (Non-RT) RIC. In some examples, a network entity 108 may be a network element in a radio access network responsible for radio transmission and reception in one or more cells to or from a UE. In different technologies, standards, or contexts, the network entity 108 may variously be referred to by persons having ordinary skill in the art as a base transceiver station (BTS), a radio base station, a base station, a radio transceiver, a transceiver function, a basic service set (BSS), an extended service set (ESS), an access point (AP), a Node B (NB), an eNode B (eNB), a gNode B (gNB), a transmission-reception point (TRP), a scheduling entity, a network access point, or some other suitable terminology. In some examples, a network entity 108 may include two or more TRPs that may be collocated or non-collocated. Each TRP may communicate on the same or different carrier frequency within the same or different frequency band. In examples where the RAN 104 operates according to both the LTE and 5G NR standards, one of the network entities may be an LTE network entity, while another network entity may be a 5G NR network entity.

The RAN 104 is further illustrated as supporting wireless communication for multiple mobile apparatuses, one of which may be identified as UE 106. A mobile apparatus may be referred to as user equipment (UE) in 3GPP standards, but may also be referred to by persons having ordinary skill in the art as a mobile station (MS), a subscriber station, a mobile unit, a subscriber unit, a wireless unit, a remote unit, a mobile device, a wireless device, a wireless communication device, a remote device, a mobile subscriber station, an access terminal (AT), a mobile terminal, a wireless terminal, a remote terminal, a handset, a terminal, a user agent, a mobile client, a client, a scheduled entity, or some other suitable terminology. The UE 106 may be an apparatus (e.g., a mobile apparatus, a wireless communication device) that provides a user with access to network services.

Within the present disclosure, a “mobile” apparatus need not necessarily have a capability to move and may be stationary. The term mobile apparatus or mobile device broadly refers to a diverse array of devices and technologies. UEs may include a number of hardware structural components sized, shaped, and arranged to help in communication; such components can include antennas, antenna arrays, RF chains, amplifiers, one or more processors, etc., electrically coupled to each other. For example, some non-limiting examples of a mobile apparatus include a mobile, a cellular (cell) phone, a smartphone, a session initiation protocol (SIP) phone, a laptop, a personal computer (PC), a notebook, a smartbook, a tablet, a personal digital assistant (PDA), and a broad array of embedded systems, e.g., corresponding to an “Internet of Things” (IoT).

A mobile apparatus (e.g., UE 106) may additionally be an automotive or other type of transportation vehicle, a remote sensor or actuator, a robot or robotics device, a satellite radio, a global positioning system (GPS) device, an object tracking device, a remote control device, a consumer and/or wearable device, such as eyewear, a wearable camera, a virtual reality device, a smartwatch, a health or fitness tracker, a digital audio player (e.g., MP3 player), a camera, a game console, etc. A mobile apparatus may additionally be a digital home or smart home device such as a home audio, video, and/or multimedia device, an appliance, a vending machine, intelligent lighting, a home security system, a smart meter, etc. A mobile apparatus may additionally be a smart energy device, a security device, a solar panel or solar array, a municipal infrastructure device controlling electric power (e.g., a smart grid), lighting, water, etc., an industrial automation and enterprise device, a logistics controller, and/or agricultural equipment, etc. Still further, a mobile apparatus may provide and/or facilitate connected medicine or telemedicine support (e.g., health care at a distance, also referred to as telehealth). Telehealth devices may include telehealth monitoring devices and telehealth administration devices, whose communication may be given preferential treatment or prioritized access over other types of information, for example, in terms of prioritized access for transport of critical service data and/or relevant QoS for transport of critical service data.

Wireless communication between the RAN 104 and the UE 106 may be described as utilizing an air interface. Transmissions over the air interface from a network entity (e.g., similar to network entity 108) to one or more UEs (e.g., similar to UE 106) may be referred to as downlink (DL) transmission. In accordance with certain aspects of the present disclosure, the term downlink may refer to a point-to-multipoint transmission or a point-to-point transmission (e.g., groupcast, multicast, or unicast) originating at a network entity (e.g., network entity 108). Another way to describe this scheme may be to use the term broadcast channel multiplexing. Transmissions from a UE (e.g., UE 106) to a network entity (e.g., network entity 108) may be referred to as uplink (UL) transmissions. In accordance with further aspects of the present disclosure, the term uplink may refer to a point-to-point transmission originating at a UE (e.g., UE 106).

In some examples, access to the air interface may be scheduled, where a network entity (e.g., a network entity 108) allocates resources for communication among some or all devices and equipment within its service area or cell. Within the present disclosure, as discussed further below, the network entity (e.g., network entity 108) may be responsible for scheduling, assigning, reconfiguring, and releasing resources for one or more scheduled entities (e.g., UEs 106). That is, for scheduled communication, a plurality of UEs 106, which may be scheduled entities, may utilize resources allocated by the network entity 108.

Network entities 108 are not the only entities that may function as scheduling entities. That is, in some examples, a UE may function as a scheduling entity, scheduling resources for one or more scheduled entities (e.g., one or more other UEs). For example, UEs may communicate directly with other UEs in a peer-to-peer or device-to-device fashion and/or in a relay configuration.

As illustrated in FIG. 1, the network entity 108 may broadcast downlink traffic 112 (also referred to as downlink data traffic) to one or more UEs 106. Broadly, the network entity 108 may be a node or device responsible for scheduling traffic (e.g., data traffic, user data traffic) in a wireless communication network, including the downlink traffic 112 and, in some examples, uplink traffic 116 (also referred to as uplink data traffic) from one or more UEs 106 to the network entity 108. On the other hand, the UE 106 (e.g., the scheduled entity) may be a node or device that receives downlink control 114 information, including but not limited to scheduling information (e.g., a grant), synchronization or timing information, or other control information from another entity in the wireless communication network such as the network entity 108. The UE 106 may further transmit uplink control 118 information, including but not limited to a scheduling request, feedback information, or other control information, to the network entity 108.

In addition, the uplink control 118 information and/or downlink control 114 information and/or uplink traffic 116 and/or downlink traffic 112 may be transmitted on a waveform that may be time-divided into frames, subframes, slots, and/or symbols. As used herein, a symbol may refer to a unit of time that, in an orthogonal frequency division multiplexed (OFDM) waveform, carries one resource element (RE) per sub-carrier. A slot may carry 7 or 14 OFDM symbols. A subframe may refer to a duration of 1 ms. Multiple subframes or slots may be grouped together to form a single frame or radio frame. Within the present disclosure, a frame may refer to a predetermined duration (e.g., 10 ms) for wireless transmissions, with each frame consisting of, for example, 10 subframes of 1 ms each. Of course, these definitions are not required; any suitable scheme for organizing waveforms may be utilized, and various time divisions of the waveform may have any suitable duration.

In general, the network entity 108 may include a backhaul interface (not shown) for communication with a backhaul portion 120 of the wireless communication system 100. The backhaul portion 120 may provide a link between a network entity 108 and the core network 102. Further, in some examples, a backhaul network may provide interconnection between respective network entities 108. Various types of backhaul interfaces may be employed, such as a direct physical connection, a virtual network, or the like, using any suitable transport network.

The core network 102 may be a part of the wireless communication system 100 and may be independent of the radio access technology used in the RAN 104. In some examples, the core network 102 may be configured according to 5G standards (e.g., 5G core (5GC)). In other examples, the core network 102 may be configured according to a 4G evolved packet core (EPC) or any other suitable standard or configuration.

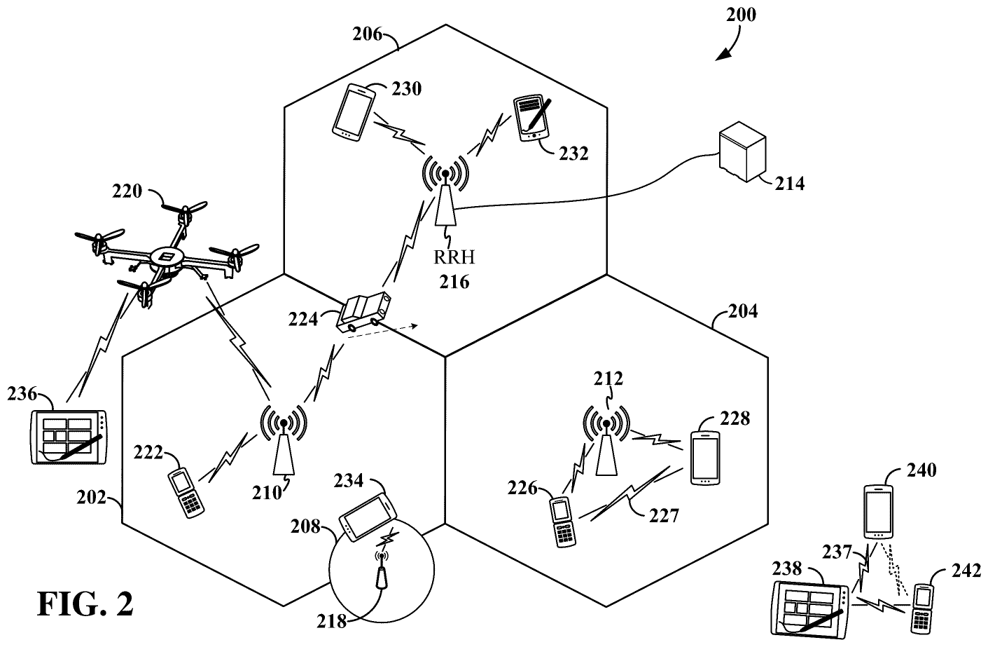

Referring now to FIG. 2, as an illustrative example without limitation, a schematic illustration of an example of a radio access network (RAN) 200 according to some aspects of the disclosure is provided. In some examples, the RAN 200 may be the same as the RAN 104 described above and illustrated in FIG. 1.

The geographic region covered by the RAN 200 may be divided into a number of cellular regions (cells) that can be uniquely identified by a user equipment (UE) based on an identification broadcasted over a geographical area from one access point or network entity. FIG. 2 illustrates cells 202, 204, 206, and 208, each of which may include one or more sectors (not shown). A sector is a sub-area of a cell. All sectors within one cell are served by the same network entity. A radio link within a sector can be identified by a single logical identification belonging to that sector. In a cell that is divided into sectors, the multiple sectors within a cell can be formed by groups of antennas, with each antenna responsible for communication with UEs in a portion of the cell.

Various network entity arrangements can be utilized. For example, in FIG. 2, two network entities, referred to as base station 210 and base station 212, are shown in cells 202 and 204. A third network entity, referred to as base station 214, is shown controlling a remote radio head (RRH) 216 in cell 206. That is, a network entity can have an integrated antenna or can be connected to an antenna or RRH 216 by feeder cables. In the illustrated example, cells 202, 204, and 206 may be referred to as macrocells, as the base stations 210, 212, and 214 support cells having a large size. Further, a base station 218 is shown in cell 208, which may overlap with one or more macrocells. In this example, the cell 208 may be referred to as a small cell (e.g., a small cell, a microcell, picocell, femtocell, home base station, home Node B, home eNode B, etc.), as the base station 218 supports a cell having a relatively small size. Cell sizing can be done according to system design as well as component constraints.

It is to be understood that the RAN 200 may include any number of network entities (e.g., base stations, gNBs, TRPs, scheduling entities) and cells. Further, a relay node may be deployed to extend the size or coverage area of a given cell. The base stations 210, 212, 214, 218 provide wireless access points to a core network for any number of mobile apparatuses. In some examples, the base stations 210, 212, 214, 218 may be the same as or similar to the network entity 108 described above and illustrated in FIG. 1.

FIG. 2 further includes a mobile network entity 220. The mobile network entity 220 may be configured to function as a base station or, more specifically, as a mobile base station. That is, in some examples, a cell may not necessarily be stationary, and the geographic area of the cell may move according to the location of a mobile base station, such as the mobile network entity 220.

Within the RAN 200, the cells may include UEs that may be in communication with one or more sectors of each cell. Further, each base station 210, 212, 214, 218, and 220 may be configured to provide an access point to a core network 102 (see FIG. 1) for all the UEs in the respective cells. For example, UEs 222 and 224 may be in communication with base station 210, UEs 226 and 228 may be in communication with base station 212, UEs 230 and 232 may be in communication with base station 214 by way of RRH 216, UE 234 may be in communication with base station 218, and UE 236 may be in communication with mobile base station 220. In some examples, the UEs 222, 224, 226, 228, 230, 232, 234, 236, 238, 240, 242 may be the same as or similar to the one or more UEs 106 described above and illustrated in FIG. 1. In some examples, the mobile base station 220 may be a mobile network entity and may be configured to function as a UE. For example, the mobile network entity 220 may operate within cell 202 by communicating with base station 210.

In a further aspect of the RAN 200, sidelink signals may be used between UEs without necessarily relying on scheduling or control information from a base station. Sidelink communication may be utilized, for example, in a device-to-device (D2D) network, peer-to-peer (P2P) network, vehicle-to-vehicle (V2V) network, vehicle-to-everything (V2X) network, and/or another suitable sidelink network. For example, two or more UEs (e.g., UEs 238, 240, 242) may communicate with each other using sidelink signals 237 without relaying that communication through a base station. In some examples, the UEs 238, 240, 242 may each function as a scheduling entity or transmitting sidelink device and/or a scheduled entity or a receiving sidelink device to schedule resources and communicate sidelink signals 237 therebetween without relying on scheduling or control information from a base station (e.g., a network entity). In other examples, two or more UEs (e.g., UEs 226, 228) within the coverage area of a network entity (e.g., base station 212) may also communicate sidelink signals 227 over a direct link (sidelink) without conveying that communication through the network entity (e.g., base station 212). In this example, the base station 212 may allocate resources to UE 226 and UE 228 for the sidelink communication.

In order for transmissions over the air interface to obtain a low block error rate (BLER) while still achieving very high data rates, channel coding may be used. That is, wireless communication may generally utilize a suitable error correcting block code. In a typical block code, an information message or sequence is split up into code blocks (CBs), and an encoder (e.g., a CODEC) at the transmitting device then mathematically adds redundancy to the information message. The exploitation of this redundancy in the encoded information message can improve the reliability of the message, enabling correction for any bit errors that may occur due to the noise.

Data coding may be implemented in multiple manners. In early 5G NR specifications, user data is coded using quasi-cyclic low-density parity check (LDPC) with two different base graphs: one base graph is used for large code blocks and/or high code rates, while the other base graph is used otherwise. Control information and the physical broadcast channel (PBCH) are coded using Polar coding based on nested sequences. Puncturing, shortening, and repetition may be used for rate matching in these channels.

Aspects of the present disclosure may be implemented utilizing any suitable channel code. Various implementations of network entities and UEs may include suitable hardware and capabilities (e.g., an encoder, a decoder, and/or a CODEC) to utilize one or more of these channel codes for wireless communication.

In the RAN 200, the ability of UEs to communicate while moving, independent of their location, is referred to as mobility. The various physical channels between the UE and the RAN 200 are generally set up, maintained, and released under the control of an access and mobility management function (AMF). In some scenarios, the AMF may include a security context management function (SCMF) and a security anchor function (SEAF) that performs authentication. The SCMF can manage, in whole or in part, the security context for both the control plane and the user plane functionality.

In various aspects of the disclosure, the RAN 200 may utilize DL-based mobility or UL-based mobility to enable mobility and handovers (i.e., the transfer of a UE's connection from one radio channel to another). In a network configured for DL-based mobility, during a call with a network entity (e.g., an aggregated or disaggregated base station, gNB, cNB, TRP, scheduling entity, etc.), or at any other time, a UE may monitor various parameters of the signal from its serving cell as well as various parameters of neighboring cells. Depending on the quality of these parameters, the UE may maintain communication with one or more of the neighboring cells. During this time, if the UE moves from one cell to another or if the signal quality from a neighboring cell exceeds that from the serving cell for a given amount of time, the UE may undertake a handoff or handover from the serving cell to the neighboring (target) cell. For example, the UE 224 may move from the geographic area corresponding to its serving cell (e.g., cell 202) to the geographic area corresponding to a neighboring cell (e.g., cell 206). When the signal strength or quality from the neighboring cell exceeds that of its serving cell for a given amount of time, the UE 224 may transmit a reporting message to its serving network entity (e.g., base station 210), indicating this condition. In response, the UE 224 may receive a handover command, and the UE may undergo a handover to the neighboring cell (e.g., cell 206).

In a network configured for UL-based mobility, UL reference signals from each UE may be utilized by the network to select a serving cell for each UE. In some examples, the base stations 210, 212, 214/216 may broadcast unified synchronization signals (e.g., unified Primary Synchronization Signals (PSSs), unified Secondary Synchronization Signals (SSSs), and unified Physical Broadcast Channels (PBCHs)). The UEs 222, 224, 226, 228, 230, 232 may receive the unified synchronization signals, derive the carrier frequency and slot timing from the synchronization signals, and, in response to deriving timing, transmit an uplink pilot or reference signal. The uplink pilot signal transmitted by a UE (e.g., UE 224) may be concurrently received by two or more cells (e.g., base stations 210 and 214/216) within the RAN 200. Each of the cells may measure a strength of the pilot signal, and the radio access network (e.g., one or more of the base stations 210 and 214/216 and/or a central node within the core network) may determine a serving cell for the UE 224. As the UE 224 moves through the RAN 200, the RAN 200 may continue to monitor the uplink pilot signal transmitted by the UE 224. When the signal strength or quality of the pilot signal measured by a neighboring cell exceeds that of the signal strength or quality measured by the serving cell, the RAN 200 may handover the UE 224 from the serving cell to the neighboring cell, with or without informing the UE 224.

Although the synchronization signal transmitted by the base stations 210, 212, 214/216 may be unified, the synchronization signal may not identify a particular cell but rather may identify a zone of multiple cells operating on the same frequency and/or with the same timing. The use of zones in 5G networks or other next-generation communication networks enables the uplink-based mobility framework and improves the efficiency of both the UE and the network, at least because the number of mobility messages that need to be exchanged between the UE and the network may be reduced.

In various implementations, the air interface in the radio access network 200 may utilize licensed spectrum, unlicensed spectrum, or shared spectrum. Licensed spectrum provides for the exclusive use of a portion of the spectrum, generally by virtue of a mobile network operator purchasing a license from a government regulatory body. Unlicensed spectrum provides for the shared use of a portion of the spectrum without the need for a government-granted license. While compliance with some technical rules is generally still required to access unlicensed spectrum, generally, any operator or device may gain access. Shared spectrum may fall between licensed and unlicensed spectrum, where technical rules or limitations may be required to access the spectrum, but the spectrum may still be shared by multiple operators and/or multiple radio access technologies (RATs). For example, the holder of a license for a portion of a licensed spectrum may provide licensed shared access (LSA) to share that spectrum with other parties, e.g., with suitable licensee-determined conditions to gain access.

The electromagnetic spectrum is often subdivided, based on frequency/wavelength, into various classes, bands, channels, etc. In 5G NR, two initial operating bands have been identified as frequency range designations FR1 (410 MHZ-7.125 GHZ) and FR2 (24.25 GHz-52.6 GHZ). It should be understood that although a portion of FR1 is greater than 6 GHZ, FR1 is often referred to (interchangeably) as a “Sub-6 GHz” band in various documents and articles. A similar nomenclature issue sometimes occurs with regard to FR2, which is often referred to (interchangeably) as a “millimeter wave” band in documents and articles despite being different from the extremely high frequency (EHF) band (30 GHz-300 GHz) which is identified by the International Telecommunications Union (ITU) as a “millimeter wave” band.

The frequencies between FR1 and FR2 are often referred to as mid-band frequencies. Recent 5G NR studies have identified an operating band for these mid-band frequencies as frequency range designation FR3 (7.125 GHZ-24.25 GHZ). Frequency bands falling within FR3 may inherit FR1 characteristics and/or FR2 characteristics and thus may effectively extend features of FR1 and/or FR2 into the mid-band frequencies. In addition, higher frequency bands are currently being explored to extend 5G NR operation beyond 52.6 GHz. For example, three higher operating bands have been identified as frequency range designations FR4-a or FR4-1 (52.6 GHZ-71 GHZ), FR4 (52.6 GHZ-114.25 GHZ), and FR5 (114.25 GHZ-300 GHz). Each of these higher frequency bands falls within the EHF band.

With the above aspects in mind, unless specifically stated otherwise, it should be understood that the term “sub-6 GHZ” or the like, if used herein, may broadly represent frequencies that may be less than 6 GHZ, may be within FR1, or may include mid-band frequencies. Further, unless specifically stated otherwise, it should be understood that the term “millimeter wave” or the like, if used herein, may broadly represent frequencies that may be within FR2, FR4, FR4-a, FR4-1, and/or FR5 or may be within the EHF band.

Devices communicating in the radio access network 200 may utilize one or more multiplexing techniques and multiple access algorithms to enable simultaneous communication of the various devices. For example, 5G NR specifications provide multiple access for UL transmissions from UEs 222 and 224 to base station 210 and for multiplexing for DL transmissions from base station 210 to one or more UEs 222 and 224, utilizing orthogonal frequency division multiplexing (OFDM) with a cyclic prefix (CP). In addition, for UL transmissions, 5G NR specifications provide support for discrete Fourier transform-spread-OFDM (DFT-s-OFDM) with a CP (also referred to as single-carrier FDMA (SC-FDMA)). However, within the scope of the present disclosure, multiplexing and multiple access are not limited to the above schemes and may be provided utilizing time division multiple access (TDMA), code division multiple access (CDMA), frequency division multiple access (FDMA), sparse code multiple access (SCMA), resource spread multiple access (RSMA), or other suitable multiple access schemes. Further, and by example, multiplexing DL transmissions from the base station 210 to UEs 222 and 224 may be provided utilizing time division multiplexing (TDM), code division multiplexing (CDM), frequency division multiplexing (FDM), orthogonal frequency division multiplexing (OFDM), sparse code multiplexing (SCM), or other suitable multiplexing schemes.

Devices in the radio access network 200 may also utilize one or more duplexing algorithms. Duplex refers to a point-to-point communication link where both endpoints can communicate with one another in both directions. Full-duplex means both endpoints can simultaneously communicate with one another. Half-duplex means only one endpoint can send information to the other at a time. Half-duplex emulation is frequently implemented for wireless links utilizing time division duplex (TDD). In TDD, transmissions in different directions on a given channel are separated from one another using time division multiplexing. That is, in some scenarios, a channel is dedicated to transmissions in one direction, while at other times, the channel is dedicated to transmissions in the other direction, where the direction may change very rapidly, e.g., several times per slot. In a wireless link, a full-duplex channel generally relies on the physical isolation between a transmitter and receiver, as well as suitable interference cancellation technologies. Full-duplex emulation is frequently implemented for wireless links by utilizing frequency division duplex (FDD) or spatial division duplex (SDD). In FDD, transmissions in different directions may operate at different carrier frequencies (e.g., within a paired spectrum). In SDD, transmissions in different directions on a given channel are separated from one another using spatial division multiplexing (SDM). In other examples, full-duplex communication may be implemented within an unpaired spectrum (e.g., within a single carrier bandwidth), where transmissions in different directions occur within different subbands of the carrier bandwidth. This type of full-duplex communication may be referred to herein as subband full-duplex (SBFD), also known as flexible duplex.

Deployment of communication systems, such as 5G new radio (variously referred to as 5G NR or NR herein) systems, may be arranged in multiple manners with various components or constituent parts. In a 5G NR system or network, a network entity, a mobility element of a network, a radio access network (RAN) node, a core network entity, a network element, or network equipment, such as a base station (BS), or one or more units (or one or more components) performing base station functionality, may be implemented in an aggregated or disaggregated architecture. For example, a BS (such as a Node B (NB), evolved NB (cNB), gNB, NR BS, 5G NR, access point (AP), TRP, or a cell, etc.) may be implemented as an aggregated base station (also known as a standalone BS or a monolithic BS) or a disaggregated base station.

An aggregated base station may be configured to utilize a radio protocol stack that is physically or logically integrated within a single RAN node. A disaggregated base station may be configured to utilize a protocol stack that is physically or logically distributed among two or more units (such as one or more central or centralized units (CUs), one or more distributed units (DUs), or one or more radio units (RUs)). In some aspects, a CU may be implemented within a RAN node, and one or more DUs may be co-located with the CU, or alternatively, may be geographically or virtually distributed throughout one or multiple other RAN nodes. The DUs may be implemented to communicate with one or more RUs. Each of the CU, DU, and RU can also be implemented as virtual units, i.e., a virtual central unit (VCU), a virtual distributed unit (VDU), or a virtual radio unit (VRU).

Base station-type operation or network design may consider aggregation characteristics of base station functionality. For example, disaggregated base stations may be utilized in an integrated access backhaul (IAB) network, an open radio access network (O-RAN (such as the network configuration sponsored by the O-RAN Alliance)), or a virtualized radio access network (vRAN, also known as a cloud radio access network (C-RAN)). Disaggregation may include distributing functionality across two or more units at various physical locations, as well as distributing functionality for at least one unit virtually, which can enable flexibility in network design. The various units of the disaggregated base station, or disaggregated RAN architecture, can be configured for wired or wireless communication with at least one other unit.

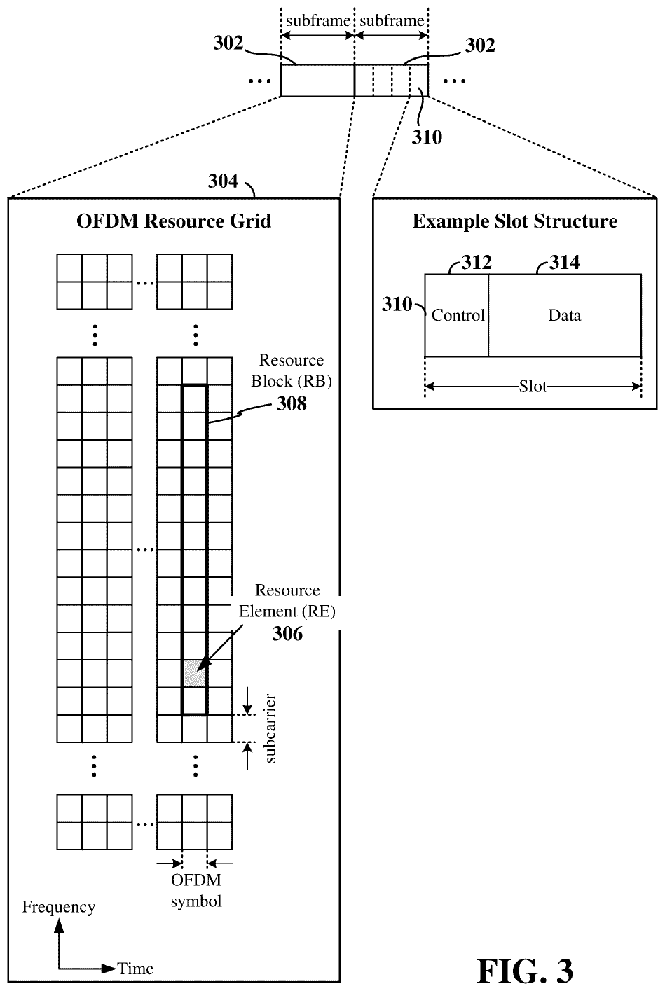

Various aspects of the present disclosure will be described with reference to an OFDM waveform, schematically illustrated in FIG. 3. It should be understood by persons having ordinary skill in the art that the various aspects of the present disclosure may be applied to an SC-FDMA waveform in substantially the same way as described hereinbelow. That is, while some examples of the present disclosure may focus on an OFDM link for clarity, it should be understood that the same principles may be applied to SC-FDMA waveforms as well.

Referring now to FIG. 3, an expanded view of an exemplary subframe 302 is illustrated, showing an OFDM resource grid. However, as persons having ordinary skill in the art will readily appreciate, the physical (PHY) transmission structure for any particular application may vary from the example described here, depending on any number of factors. Here, time is in the horizontal direction with units of OFDM symbols, and frequency is in the vertical direction with units of subcarriers of the carrier.

The resource grid 304 may be used to schematically represent time-frequency resources for a given antenna port. That is, in a multiple input multiple output (MIMO) implementation with multiple antenna ports available, a corresponding multiple number of resource grids 304 may be available for communication. The resource grid 304 is divided into multiple resource elements (REs) 306. An RE, which is 1 subcarrier×1 symbol, is the smallest discrete part of the time-frequency grid and contains a single complex value representing data from a physical channel or signal. Depending on the modulation utilized in a particular implementation, each RE may represent one or more bits of information. In some examples, a block of REs may be referred to as a physical resource block (PRB) or, more simply, a resource block (RB) 308, which contains any suitable number of consecutive subcarriers in the frequency domain. In one example, an RB may include 12 subcarriers, a number independent of the numerology used. In some examples, depending on the numerology, an RB may include any suitable number of consecutive OFDM symbols in the time domain.

A set of continuous or discontinuous resource blocks may be referred to herein as a Resource Block Group (RBG), subband, or bandwidth part (BWP). A set of subbands or BWPs may span the entire bandwidth. Scheduling of wireless communication devices (e.g., V2X devices, sidelink devices, or other UEs, hereinafter generally referred to as UEs) for downlink, uplink, or sidelink transmissions may involve scheduling one or more resource elements 306 within one or more subbands or bandwidth parts (BWPs). Thus, a UE generally utilizes only a subset of the resource grid 304. In some examples, an RB may be the smallest unit of resources that can be allocated to a UE. Thus, the more RBs scheduled for a UE and the higher the modulation scheme chosen for the air interface, the higher the data rate for the UE. The RBs may be scheduled by a network entity (e.g., an aggregated or disaggregated base station, gNB, eNB, TRP, scheduling entity, etc.) or may be self-scheduled by a UE/sidelink device implementing D2D sidelink communication.

In this illustration, the RB 308 is shown as occupying less than the entire bandwidth of the subframe 302, with some subcarriers illustrated above and below the RB 308. In a given implementation, the subframe 302 may have a bandwidth corresponding to any number of one or more RBs 308. Further, in this illustration, the RB 308 is shown as occupying less than the entire duration of the subframe 302, although this is merely one possible example.

Each 1 ms subframe 302 may consist of one or multiple adjacent slots. In the example shown in FIG. 3, one subframe 302 includes four slots 310, as an illustrative example. In some examples, a slot may be defined according to a specified number of OFDM symbols with a given cyclic prefix (CP) length. For example, a slot may include 7 or 14 OFDM symbols with a nominal CP. An additional example may include mini-slots, sometimes referred to as shortened transmission time intervals (TTIs), having a shorter duration (e.g., one to three OFDM symbols). These mini-slots or shortened transmission time intervals (TTIs) may, in some cases, be transmitted and may occupy resources scheduled for ongoing slot transmissions for the same or different UEs. Any number of resource blocks may be utilized within a subframe or slot.

An expanded view of slot 310 illustrates that the slot 310 includes a control region 312 and a data region 314. In general, the control region 312 may carry control channels, and the data region 314 may carry data channels. In some examples, a Uu slot (e.g., slot 310) may contain all DL, all UL, or at least one DL portion and at least one UL portion. The structures illustrated in FIG. 3 are merely exemplary in nature, and different slot structures may be utilized and may include one or more of each of the control region(s) and data region(s).

Although not illustrated in FIG. 3, the various REs 306 within the RB 308 may be scheduled to carry one or more physical channels, including control channels, shared channels, data channels, etc. Other REs 306 within the RB 308 may also carry pilots or reference signals. These pilots or reference signals may provide for a receiving device to perform channel estimation of the corresponding channel, which may enable coherent demodulation/detection of the control and/or data channels within the RB 308.

In some examples, the slot 310 may be utilized for broadcast, multicast, groupcast, or unicast communication. For example, a broadcast, multicast, or groupcast communication may refer to a point-to-multipoint transmission by one device (e.g., a network entity, UE, or another similar device) to other devices. Here, a broadcast communication is delivered to all devices, whereas a multicast or groupcast communication is delivered to multiple intended recipient devices. A unicast communication may refer to a point-to-point transmission by one device to a single other device.

In an example of cellular communication over a cellular carrier via a Uu interface, for a DL transmission, the network entity may allocate one or more REs 306 (e.g., within the control region 312) of the slot 310 to carry DL control information, including one or more DL control channels, such as a physical downlink control channel (PDCCH), to one or more UEs (e.g., scheduled entities). The PDCCH carries downlink control information (DCI), including but not limited to power control commands (e.g., one or more open loop power control parameters and/or one or more closed loop power control parameters), scheduling information, a grant, and/or an assignment of REs for DL and UL transmissions. The PDCCH may further carry hybrid automatic repeat request (HARQ) feedback transmissions such as an acknowledgment (ACK) or negative acknowledgment (NACK). HARQ is a technique well-known to persons having ordinary skill in the art, where the integrity of packet transmissions may be checked at the receiving side for accuracy, e.g., utilizing any suitable integrity checking mechanism, such as a checksum or a cyclic redundancy check (CRC). If the integrity of the transmission is confirmed, an ACK may be transmitted, whereas if not confirmed, a NACK may be transmitted. In response to a NACK, the transmitting device may send a HARQ retransmission, which may implement chase combining, incremental redundancy, etc.

The network entity may further allocate one or more REs 306 (e.g., in the control region 312 or the data region 314) of the Uu slot 310 to carry other DL signals, such as a demodulation reference signal (DMRS); a phase-tracking reference signal (PT-RS); a channel state information (CSI) reference signal (CSI-RS); and a synchronization signal block (SSB). SSBs may be broadcast at regular intervals based on a periodicity (e.g., 4, 10, 20, 50, 80, or 160 ms). An SSB includes a primary synchronization signal (PSS), a secondary synchronization signal (SSS), and a physical broadcast control channel (PBCH). A UE may utilize the PSS and SSS to achieve radio frame, subframe, slot, and symbol synchronization in the time domain, identify the center of the channel (system) bandwidth in the frequency domain, and identify the physical cell identity (PCI) of the cell.

The PBCH in the SSB may further include a master information block (MIB) that includes various system information, along with parameters for decoding a system information block (SIB). The SIB may be, for example, a SystemInformationType 1 (SIB1) that may include various additional system information. The MIB and SIB1 together provide the minimum system information (MSI) for initial access. Examples of system information transmitted in the MIB may include, but are not limited to, a subcarrier spacing (e.g., default downlink numerology), system frame number, a configuration of a PDCCH control resource set (CORESET) (e.g., PDCCH CORESET0), a cell barred indicator, a cell reselection indicator, a raster offset, and a search space for SIB1. Examples of remaining minimum system information (RMSI) transmitted in the SIB1 may include, but are not limited to, a random access search space, a paging search space, downlink configuration information, and uplink configuration information. A network entity may transmit other system information (OSI) as well.

In an UL transmission, the UE (e.g., scheduled entity) may utilize one or more REs 306 of the Uu slot 310 to carry UL control information (UCI), including one or more UL control channels, such as a physical uplink control channel (PUCCH), to the scheduling entity. UCI may include a variety of packet types and categories, including pilots, reference signals, and information configured to enable or assist in decoding uplink data transmissions. Examples of uplink reference signals may include a sounding reference signal (SRS) and an uplink DMRS. In some examples, the UCI may include a scheduling request (SR), i.e., a request for the scheduling entity to schedule uplink transmissions. In response to the SR transmitted on the UCI, the scheduling entity may transmit downlink control information (DCI) that may schedule resources for uplink packet transmissions. UCI may also include HARQ feedback, channel state feedback (CSF), such as a CSI report, a measurement report (e.g., a Layer 1 (L1) measurement report), or any other suitable UCI.

In addition to control information, one or more REs 306 (e.g., within the data region 314) of the Uu slot 310 may be allocated for data traffic. Such data traffic may be carried on one or more traffic channels, such as, for a DL transmission, a physical downlink shared channel (PDSCH), or for a UL transmission, a physical uplink shared channel (PUSCH). In some examples, one or more REs 306 within the data region 314 may be configured to carry other signals, such as one or more SIBs and DMRSs. In some examples, the PDSCH may carry a plurality of SIBs, not limited to SIB1, discussed above. For example, the OSI may be provided in these SIBs, e.g., SIB2 and above.

In an example of sidelink communication over a sidelink carrier via a PC5 interface, the control region 312 of the slot 310 may include a physical sidelink control channel (PSCCH), including sidelink control information (SCI) transmitted by an initiating (transmitting) sidelink device (e.g., Tx V2X device or other Tx UE) towards a set of one or more other receiving sidelink devices (e.g., Rx V2X device or other Rx UE). The data region 314 of the slot 310 may include a physical sidelink shared channel (PSSCH), including sidelink data traffic transmitted by the initiating (transmitting) sidelink device within resources reserved over the sidelink carrier by the transmitting sidelink device via the SCI. Other information may further be transmitted over various REs 306 within slot 310. For example, sidelink MAC-CEs may be transmitted in the data region 314 of the slot 310. In addition, HARQ feedback information may be transmitted in a physical sidelink feedback channel (PSFCH) within the slot 310 from the receiving sidelink device to the transmitting sidelink device. In addition, one or more reference signals, such as a sidelink SSB, a sidelink CSI-RS, a sidelink SRS, and/or a sidelink positioning reference signal (PRS), may be transmitted within the slot 310.

The physical channels described above are generally multiplexed and mapped to transport channels for handling at the medium access control (MAC) layer. Transport channels carry blocks of information called transport blocks (TB). The transport block size (TBS), which may correspond to a number (e.g., a quantity) of bits of information, may be a controlled parameter based on the modulation and coding scheme (MCS) and the number of RBs in a given transmission.

Returning to the concept of a receiving entity, a receiving entity may receive a transmitted signal from a transmitting entity (such as a UE or a sidelink UE). However, as the transmitted signal travels toward the receiving entity, power is lost. The receiving entity may have a predefined minimum received power level. Signals received at power levels below the minimum received power level may be difficult or impossible to coherently demodulate and decode. The minimum power level may be defined in a specification, such as those promulgated by the Third Generation Partnership Project (3GPP), the European Telecommunication Standards Institute (ETSI), or the Institute of Electrical and Electronics Engineers (IEEE), to name a few.

Power amplifier circuits may be configured to amplify a signal before the signal is transmitted via one or more antennas or an antenna array of a UE or a sidelink UE (both referred to as a UE or an apparatus herein). The amplification may be sufficient to compensate for and possibly provide a margin of additional power to overcome the expected signal attenuation between a transmitting entity and a receiving entity. However, all amplifier circuits, including power amplifier circuits, may be subject to gain compression. Gain compression may occur when the input power (i.e., input signal power, as opposed to transistor bias power) to an amplifier is increased linearly to a point where a one-to-one ratio between input power and output power becomes non-linear, and gain of the power amplifier is reduced. The reduction in gain may be referred to as gain compression.

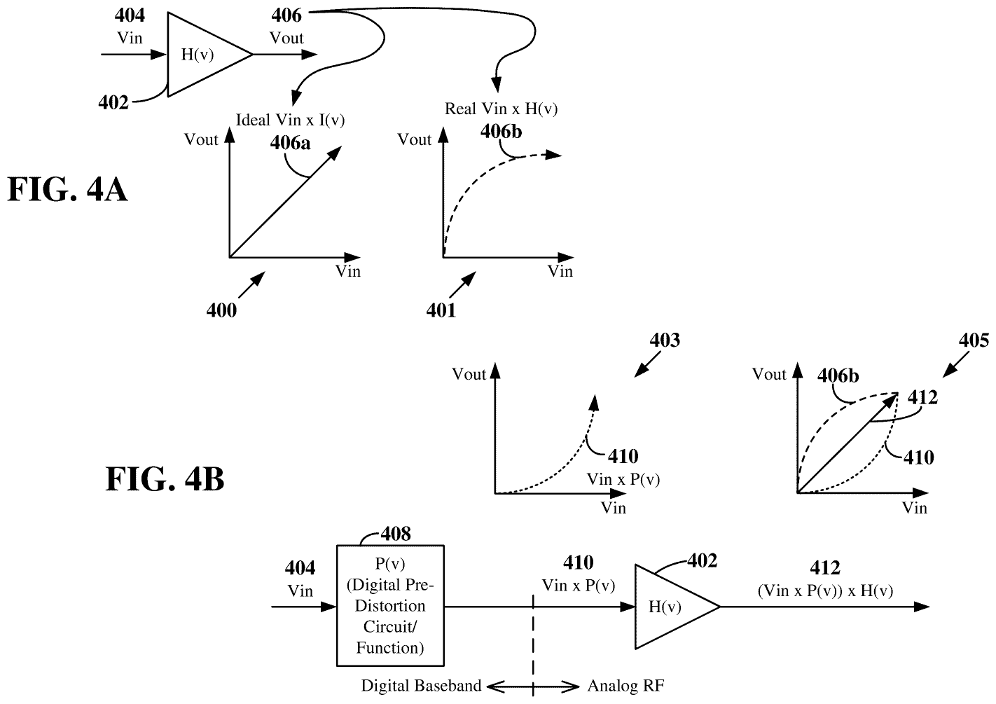

FIG. 4A depicts a schematic drawing of an amplifier 402 (e.g., a power amplifier), a first graph 400 of an ideal gain transfer function, I(v), and a second graph 401 of an exemplary and non-limiting generic real-world gain transfer function, H(v), according to some aspects of the disclosure. FIG. 4B depicts a schematic drawing of a digital pre-distortion circuit/function 408, the amplifier 402 of FIG. 4A, a third graph 403 of the digital pre-distortion gain transfer function, P(v), and a fourth graph 405 of an amplified digital pre-distorted signal 412 according to some aspects of the disclosure. The examples of FIGS. 4A and 4B are provided for exemplary and non-limiting purposes and are not intended to limit the scope of the disclosure, which may be applied to the transmission of any signal form any amplifier, including any power amplifier, having any response. For example, in connection with power amplifiers, some power amplifier responses may exhibit a linear response, yet the scope of the disclosure includes power amplifiers (and other amplifiers) with both linear and non-linear responses.

In the first graph 400, the second graph 401, the third graph 403, and the fourth graph 405, voltage out (Vout) is represented along the vertical axis, and voltage in (Vin) is represented along the horizontal axis. Although not shown to avoid cluttering the drawings, the scales of both axes in each graph are equal and linear (i.e., not logarithmic). The numeric values of Vout and Vin are not shown because each graph is meant to illustrate linear and non-linear characteristics of the amplifier 402 and the digital pre-distortion circuit/function 408, as opposed to realized numeric values of gain. As shown in FIG. 4B, the digital pre-distortion circuit/function 408 may operate in the digital baseband portion of a transmitter, while the amplifier 402 may operate in a radio frequency (RF) portion (e.g., analog RF portion, analog processing section) of the transmitter.

A feedback receiver (not shown to avoid cluttering the drawing) may sample the output of the amplifier 402 in the analog RF portion of the transmitter, downconvert the sample, convert the downconverted sample to a digital baseband signal that may be fed back to the digital pre-distortion circuit/function 408 in the digital baseband portion (e.g., the digital processing section) of the transmitter. In FIG. 4A, the amplifier 402 may have the ideal gain transfer function, I(v), or the real-world non-linear gain transfer function, H(v) (hereinafter referred to as “the transfer function, H(v)” or “H(v)”) An input signal, Vin 404, may be applied to the amplifier 402. The input signal, Vin 404, may be a voltage that linearly increases over time. The ideal transfer function, I(v), or the real-world transfer function, H(v), of the amplifier 402 operates on Vin 404, producing an amplifier output 406, Vout. The first graph 400 depicts an ideal output 406a as an ideal product of Vin and I(v). For an ideal amplifier with an ideal transfer function, each unit increase in Vin would correspond to a unit increase in Vout, as shown in the first graph 400.

However, the amplifier 402 is not ideal; it has real-world non-linearities, which may manifest themselves as non-linearities in the transfer function, H(v), of the amplifier 402. The second graph 401 depicts a real-world non-linear output 406b as a product of Vin and H(v). The real-world non-linearities of the amplifier 402 are reflected in the non-linear output 406b, as shown in the second graph 401.

In FIG. 4B, the amplifier 402 is the same amplifier 402, with the same transfer function, H(v), as shown and described in connection with FIG. 4A. The digital pre-distortion circuit/function 408 has a digital pre-distortion transfer function given as P(v). The digital pre-distortion transfer function, P(v), may be the inverse of the transfer function, H(v).

The digital pre-distortion transfer function, P(v), of the digital pre-distortion circuit/function 408, operates on Vin 404 and produces a digital pre-distortion output 410. The digital pre-distortion output 410 may be represented as Vin×P(v). The third graph 403 depicts the digital pre-distortion output 410.

The digital pre-distortion output 410 is applied to the amplifier 402, which has the transfer function H(v). The fourth graph 405 depicts the amplified digital pre-distorted signal 412 (Vin×P(v)×H(v)) of the amplifier 402. The amplified digital pre-distorted signal 412 is a straight line (i.e., it is linear), similar to the ideal output 406a, as shown in the first graph 400.

As used in the context of FIG. 4A and the first graph 400, the word “ideal” is meant to infer that an ideal power amplifier circuit maintains linearity regardless of the value of Vin (i.e., Vout increases in a 1:1 ratio with Vin as shown in the first graph 400, which depicts a straight line with a constant slope). In contrast, the word “real-world” or “real” is meant to infer that a real-world power amplifier exhibits a non-linearity in its transfer function H(v). The non-linear characteristics represented in the second graph 401 are manifest by illustrating a constant gain at lower input voltage values and a compressed (reduced) gain as the input voltage values increase. The non-linearities present in a real-world amplifier (e.g., similar to the amplifier 402 having the transfer function H(v)) may result in the generation of intermodulation products and spurious emissions observable at the output of the amplifier.

A parameter referred to as power-added efficiency (PAE) may be used as a measure of the efficiency of a power amplifier as it converts input bias power (i.e., input DC power used to bias the transistor(s) of the power amplifier) to output RF power. Power-added efficiency may be given as a percentage and may be obtained using the formula PAE=(Pout−Pin)/PDC*100%, where Pin is input RF power, Pout is output RF power, and PDC is input DC power (used to bias the transistor(s)/component(s) of the power amplifier circuit).

According to some aspects, the power-added efficiency of a power amplifier that operates in its compression region (in its non-linear region) at a given frequency is improved (e.g., increased, maximized) in comparison to the power-added efficiency realized by the same power amplifier operating in its linear region at the given frequency. In other words, a power amplifier operating in its compression region (non-linear region) operates at the power amplifier's maximum gain (i.e., increasing Vin or Pin does not increase Vout or Pout). When operating at its maximum gain and providing its maximum Pout, the power amplifier maximizes its power-added efficiency. Maximization of the power-added efficiency is recognized from at least the formula of power-added efficiency (just provided) and an example in which PDC is constant, and Pin is raised to a level (and not higher) that causes the power amplifier to operate in its compression region. Due to its operation in the compression region, Pout is maximized, and PAE is necessarily maximized.

Some techniques that may be used to ensure that a power amplifier remains in compression may include but are not limited to envelope tracking (ET) and enhanced power tracking. These techniques may operate to keep a power amplifier operating in its compression region without regard to the signal input power (e.g., RF input power) applied to the power amplifier. According to some examples, techniques to keep the power amplifier operating in compression may be used at mid and high-output power operation. According to some examples, a power amplifier may operate in its linear region for low-output power operation.

Power amplifiers with non-linear characteristics, such as but not limited to the non-linear characteristics represented by the second graph 401 of FIG. 4A may have their non-linear characteristics linearized, for example, with analog tuning (e.g., changing bias currents, bias voltages, tuning components) of the power amplifier circuit or with digital pre-distortion. Analog tuning may degrade the power-added efficiency of a power amplifier. Digital pre-distortion, which is applied to a signal in the digital processing section of a transmitter, before the signal is input to a power amplifier in the analog processing section of the transmitter, maintains the power-added efficiency of the power amplifier.

Linearity is important because if a signal is passed through a non-linear power amplifier, the non-linear power amplifier may yield unwanted emissions. The unwanted emissions may be caused, for example, by the generation of intermodulation products due to the non-linear aspects of the power amplifier. The unwanted emissions may be outside of specific frequency and power restrictions or limitations imposed on UEs by the various specifications established by standard-setting bodies (e.g., 3GPP, ETSI, IEEE, etc.) and followed (e.g., accepted and abided to) worldwide.

Therefore, at least because the operation of certain power amplifiers in a non-linear manner offers certain benefits (e.g., improved power-added efficiency in comparison to the power-added efficiency realized by a power amplifier operating linearly at the same frequency and output power level), engineers and scientists continue to search for ways to linearize amplifiers (such as power amplifiers) operating in a non-linear region of the transfer function of the amplifiers.

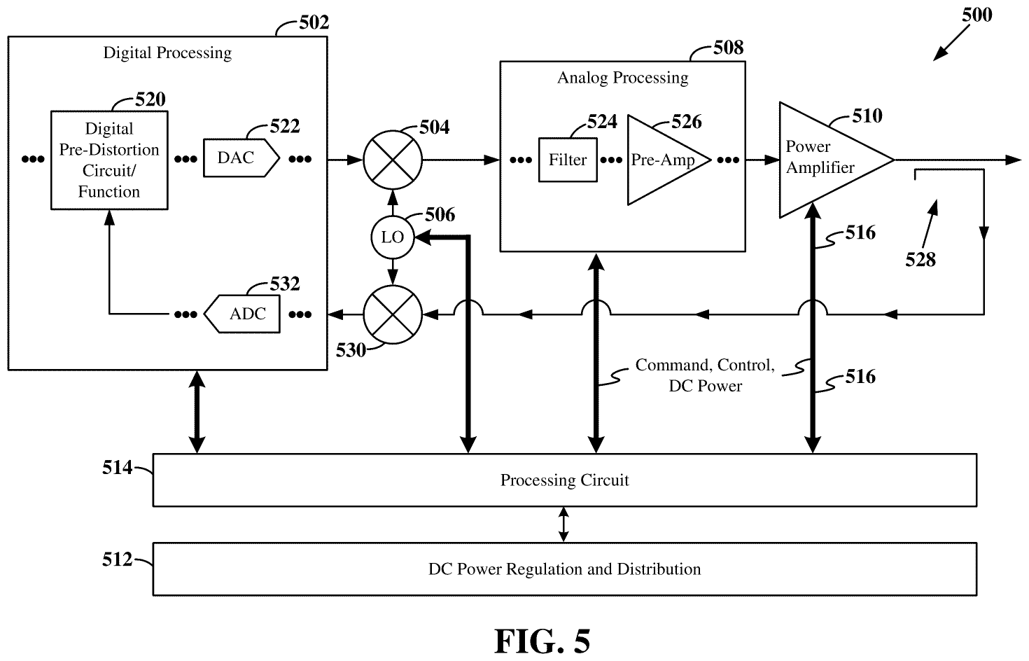

FIG. 5 is a simplified high-level block diagram of several components of a transmitter 500 according to some aspects of the disclosure. The transmitter 500 includes a digital processing section 502, a first mixer 504, a local oscillator 506, an analog processing section 508, a power amplifier 510, a coupler 528, and a feedback receiver mixer 530 (which may be a component of or associated with, a feedback receiver (not shown) that may provide training data derived from the output of the power amplifier 510 to a digital pre-distortion circuit/function 520). Each of the components in the transmitter 500 is coupled to a DC power regulation and distribution circuit 512 and a processing circuit 514 via a plurality of command, control, and DC power busses 516. The digital processing section 502 includes a plurality of circuits, of which the digital pre-distortion circuit/function 520, a digital-to-analog converter 522, and an analog-to-digital converter 532 are shown to avoid cluttering the drawing. The analog processing section 508 includes a plurality of circuits, of which a filter circuit 524 and a preamplifier circuit 526 are shown to avoid cluttering the drawing.

The digital pre-distortion circuit/function 520 may operate on a signal in the digital baseband to transform the digital baseband signal (e.g., a signal received from a modem, not shown) before the signal undergoes digital-to-analog conversion in the digital-to-analog converter 522. In other words, digital pre-distortion may be applied to the signal in the digital domain (e.g., a digital baseband) at the digital pre-distortion circuit/function 520. The digital pre-distortion circuit/function 520 may be exemplified as a mathematical operation, a time domain transform, or a lookup table that applies an inverse characteristic of the power amplifier 510 to the signal. The analog signal may then undergo a frequency up-conversion to an over-the-air transmission frequency. The frequency up-conversion may be accomplished by mixing the output of the digital-to-analog converter 522 with an output from the local oscillator 506.

Using digital pre-distortion via the digital pre-distortion circuit/function 520 may effectively linearize the operation of the power amplifier 510. In other words, applying digital pre-distortion to a digital baseband signal may correspond to using a transform (e.g., based on a lookup table) on the digital baseband signal. The digital pre-distortion could change the digital baseband signal such that, if transmitted from the power amplifier 510 (having a given transfer function), the transformed digital baseband signal, subsequently applied to a digital-to-analog converter 522 and mixed to an over-the-air transmission frequency, could have an effect of canceling the distortion (e.g., caused by the gain compression of the power amplifier 510) and thereby result in an output from the power amplifier 510 that appears to have been amplified with a linear transform.

A sample of the output of the power amplifier 510 may be obtained via the use of, for example, and without limitation, a coupler 528 at a tap point after the power amplifier 510. This sample of the output of the power amplifier 510 may be down-converted in frequency by mixing the sample with the output of the local oscillator 506. The frequency down-converted sample may be applied to an analog-to-digital converter 532. The analog-to-digital converter 532 may feed or may be a part of a feedback receiver (not shown). The output of the feedback receiver may be applied to the digital pre-distortion circuit/function 520 and may be used to train the digital pre-distortion circuit/function 520. Ultimately, the digital pre-distortion format and/or the DPD sampling rate may be derived utilizing the information obtained from the feedback receiver (not shown).

UEs operate according to one or more standards. However, occasionally, depending on the region, for example, a base station may transmit a message (e.g., a control message in radio resource control (RRC) signaling) via the control plane or any other path, including transmission in user plane messaging, indicating a “network signaling” (NS) requirement. The NS requirement may correspond to additional constraints on emissions that the network requires the UE to meet. For purposes of discussion and not limitation, two examples of network signaling are provided in Table 1 and Table 2 below.

Table 1 relates to network signaling known as NS_43 and NS_43U. Table 2 relates to network signaling known as NS_17. The details of NS_43, NS_43U, NS_17, and other network signaling requirements are described in 3GPP Technical Standards. The tables below and the discussions identifying specific examples of network signaling and frequency bands are exemplary; they are provided for discussion and are not intended to limit the scope of the disclosure to any particular example, technical specification, standard, or technology.

In the example of the 3GPP standards, each NS is applied to one or more NR radio frequency bands. For instance, NS_43 and NS_43U apply to NR bands n8 (FDD) and n81 (SUL) (supplementary uplink), where both bands are specified as occupying 880-915 MHz. NS_17 applies to NR bands n28 (FDD) and n83 (SUL), where both bands are specified as occupying 703-748 MHz.

TABLE 1
Additional Requirements for “NS_43” and “NS_43U”*

| | Channel bandwidth (MHz)/ | |
|---|---|---|
| | Spectrum emission limit | |
| Frequency | (dBm) | Measurement |
| range (MHz) | 5, 10, 15 | bandwidth |
| 860 ≤ f ≤ 890 | −40 | 1 MHz |

Note 1:
Acceptable for 5 MHz and 15 MHz channel BW confined between 900 MHz and 915 MHz and for 10 MHz channel BW confined between 905 MHz and 915 MHz
*From 3GPP TS 38.101-1, Table 6.5.3.3.5-1

TABLE 2
Additional Requirements for “NS_17”*

| | Channel bandwidth (MHz)/ | |
|---|---|---|
| | Spectrum emission limit | |
| Frequency | (dBm) | Measurement |
| range (MHz) | 5, 10 | bandwidth |
| 470 ≤ f ≤ 710 | −26.2 | 6 MHz |

Note 1:
Acceptable when assigned NR carrier is confined within 718 MHz and 748 MHz and when the channel bandwidth used is 5 or 10 MHz.
*From 3GPP TS 38.101-1, Table 6.5.3.3.2-1

The example of Table 1 (NS_43, NS_43U) illustrates a case in which, within a frequency range of 860-890 MHZ (and as further specified in Note 1 in Table 1), in connection with channel bandwidths of 5, 10, and 15 MHz, a spectrum emission limit of −40 dBm (as measured in a 1 MHz bandwidth) is imposed on the UE. In other words, the UE may not emit signals in the specified frequency range that exceed-40 dBm.

The example of Table 2 (NS_17) illustrates a case in which, within a frequency range of 470-710 MHZ (and as further specified in Note 1 in Table 2), in connection with channel bandwidths of 5 and 10 MHz, a spectrum emission limit of −26.2 dBm (as measured in a 1 MHz bandwidth) is imposed on the UE. In other words, the UE may not emit signals in the specified frequency range that exceeds-26.2 dBm.

The parameters provided in Table 1 and Table 2 may be in addition to existing requirements, new requirements, or a combination of both that may be imposed on the UE in the specified frequency ranges. In some examples, the requirements imposed on the UE via network signaling may be asymmetric with respect to a New Radio (NR) band (e.g., NR band n28, covering 703-748 MHZ). If asymmetric, the UE may apply the spectrum emission limit to one side of its uplink transmission in a given NR band rather than both sides. In other examples, a spectrum emission limit may apply to both sides of the NR band.

In summation, a base station (e.g., a network entity, an eNodeB, a gNodeB) with a connected UE in an LTE or an NR network may schedule a network signaling (NS) value for the UE. The NS value may depend on the region and scenario within which the UE exists. The NS value may impose, on the UE, additional or more stringent specifications/requirements relative to the general 3GPP specifications within which the UE regularly operates. The additional or more stringent specifications/requirements imposed on the UE may include, by way of example and not limitation, a further reduction in maximum power (e.g., maximum emitted RF power output), additional limits on spurious emission levels, a change, update, or addition to spectral emission mask levels, to name a few. These additional or more stringent imposed specifications/requirements may exist on one or both sides of the transmitter (TX) channel allocation (e.g., frequency allocation for the UE uplink). Furthermore, they may exist at farther frequency offsets from the TX channel center relative to the initial requirement set forth in the 3GPP specifications.

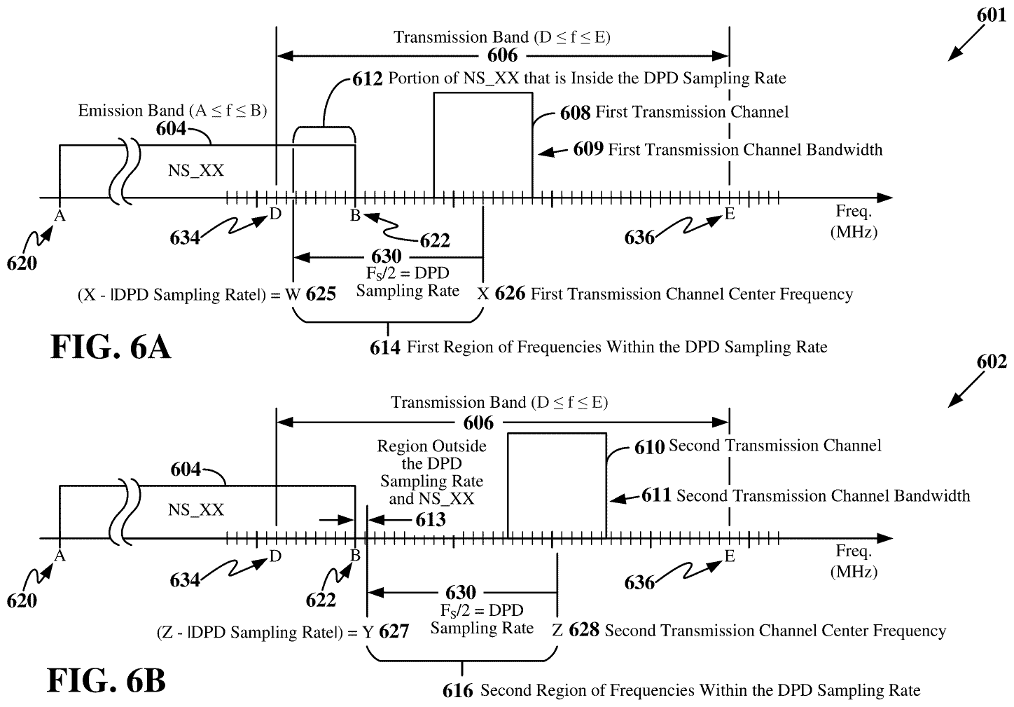

FIG. 6A and FIG. 6B are a first example 601 and a second example 602 of respective applications of network signaling (NS) indicative of one or more emission constraints in an emission band 604 (also referred to herein as a second band) according to some aspects of the disclosure. The identity of the network signaling is given as NS_XX for ease of reference. In the examples of FIG. 6A and FIG. 6B, frequency is depicted on the horizontal axis in units of MHz. A vertical axis (e.g., amplitude or power) is not depicted in the first example 601, or the second example 602, as the examples are provided for discussion in the context of frequency. The height of any block relative to the vertical axis in FIG. 6A and FIG. 6B is not representative of any magnitude of any characteristic of that block. As used herein, the variables A, B, D, E, W, X, Y, and Z may each be any non-zero number. In the examples described herein, the variables A, B, D, E, W, X, Y, and Z are all representative of frequencies and are all represented in the same units of measure, for example, Hertz or MHz.

The examples of FIG. 6A and FIG. 6B presume that NS_XX, graphically represented as the emission band 604, was scheduled to a given UE by a base station (e.g., a network entity). Table 3 below presents exemplary and non-limiting parameters associated with NS_XX. According to some aspects, the emission band 604 is associated with a frequency range (A≤f≤B) in Table 3. The emission band 604 may therefore be defined by an emission band lower frequency 620, given by the variable A, and an emission band upper frequency 622, given by the variable B.

TABLE 3
Additional Requirements for “NS_XX”

| | Channel bandwidth (MHz)/ | |
|---|---|---|
| | Spectrum emission limit | |
| Frequency | (dBm) | Measurement |
| range (MHz) | 5, 10 | bandwidth |
| A ≤ f ≤ B | −30 | 5 MHz |

Any given UE (not shown, but similar to any of the scheduled entities 106 as shown and described in connection with FIG. 1, and UEs 222, 224, 230, 232, 234, 236, 238, 240, 242 as shown and described in connection with FIG. 2) may be required to meet the requirements of any set of NS parameters (referred to herein as an NS case) once the given NS case (e.g., NS_XX) is scheduled to the given UE by a base station (not shown, but similar to any of the network entities 108 as shown and described in connection with FIG. 1, and base stations 210, 212, 214 or (transmitting) sidelink UEs 236, 238, 240, 242 as shown and described in connection with FIG. 2).

Just as NS_17 is associated with NR bands n28 (FDD) and n83 (SUL), the exemplary NS_XX may be associated with one or more transmission bands (e.g., one or more NR transmission bands). By way of example and not limitation, the uplink of a transmission band 606 (also referred to herein as an NR band, an npp band, an operating band, a given frequency band) corresponds to D≤f≤E MHz (where “f” represents the frequency in MHz for exemplary and non-limiting purposes). In some aspects, the transmission band 606 may be defined by a transmission band center frequency and a transmission band bandwidth. For example, in a case in which the uplink of NR band n28 was considered to represent the transmission band 606 defined by a transmission band center frequency and a transmission band bandwidth, the transmission band center frequency may be understood to be 725.5 MHZ, and the transmission band bandwidth (sometimes referred to herein as the first bandwidth) may be understood to be 45 MHZ.

A number of channels may be defined within the transmission band 606. As depicted in FIG. 6A, a first transmission channel 608 (also referred to herein as a first band), may be defined by a first transmission channel center frequency 626 given as X (also referred to herein as Fc, a first channel center frequency, or a first center frequency) and a first transmission channel bandwidth 609 (exemplified as 10 MHz in FIG. 6A). As depicted in FIG. 6B, a second transmission channel 610 may be defined by a second transmission channel center frequency 628 given as Z and a second transmission channel bandwidth 611 (also exemplified as 10 MHz in FIG. 6B). The equality of channel bandwidths is for ease of illustration and not limitation.

As set forth in Table 3 above and as illustrated in FIG. 6A and FIG. 6B, the requirements of NS_XX cover the emission band 604, which may defined between and including an emission band lower frequency 620, given as “A,” and an emission band upper frequency 622, given as “B,” where the emission band upper frequency 622 is greater than the emission band lower frequency 620 (e.g., A≤f≤B). In the examples described herein, A and B are in units of MHz for case of illustration and not limitation.

In one example, a network (e.g., via signaling from a base station, a network entity) may invoke a given network signaling (NS) regime, referred to for exemplary and non-limiting purposes herein as NS_XX. As exemplified in Table 3 above and as illustrated in FIG. 6A and FIG. 6B, the NS_XX may specify emission constraints (also referred to herein as transmission constraints) in the emission band 604 spanning from the emission band lower frequency 620 (A) to the emission band upper frequency 622 (B), greater than the emission band lower frequency 620 (A). For example, the emission constraints exemplified in Table 3 indicate that within the emission band 604 (A≤f≤B), in association with transmission channels of 5 and 10 MHZ transmission channel bandwidth, emissions may be no greater than −30 dBm as measured in a 5 MHz bandwidth.

The NS_XX may be associated with another band, referred to for exemplary and non-limiting purposes herein as the transmission band 606. In one example, the transmission band 606 may be specified for uplink and may span from a first frequency D 634 to a second frequency E 636, greater than the first frequency D 634. The transmission band 606 may utilize channel bandwidths (CHBWs) of 3, 5, 10, 15, 20, 25, and 30 MHz, for example. However, as shown in Table 3, the limitations imposed by NS_XX apply to channel bandwidths of 5 and 10 MHz, as distinct from the other channel bandwidths of 3, 15, 20, 25, and 30 MHZ.

For purposes of explanation and not limitation, FIG. 6A depicts one channel, which may be described as a first transmission channel 608, defined by a first transmission channel bandwidth 609 (also referred to herein as a first bandwidth or a first channel bandwidth) and the first transmission channel center frequency 626 (X), all within the transmission band 606. For purposes of explanation and not limitation, FIG. 6B depicts another channel, which may be described as a second transmission channel 610, which is different from the first transmission channel 608. The second transmission channel 610 may be defined by a second transmission channel bandwidth 611 and a second transmission channel center frequency 628 (Z), all within the transmission band 606. As described above, in the examples of FIG. 6A and FIG. 6B, the first transmission channel bandwidth 609, and the second transmission channel bandwidth 611 are both depicted as 10 MHz for case of illustration and not limitation.

As mentioned above, DPD may be employed at a UE in connection with a power amplifier (similar to the power amplifier 510 as shown and described in connection with FIG. 5) of the UE. In general, a power amplifier may operate in a linear region, a non-linear region, or both. In one example, as the input power to a power amplifier increases, the output of the power amplifier may be pushed into the compression region. Operation in the compression region (where a non-linear Vout to Vin (or Pout to Pin) transfer characteristic exists) may be desirable to increase and/or maximize the energy efficiency of the power amplifier. However, operation in the compression region may distort the signal being amplified by the power amplifier. DPD may be employed to linearize the gain (e.g., the transfer characteristic, the transform, the response) of the power amplifier and reduce distortion; however, DPD may be employed in any situation, for example, in connection with any type of amplifier operating in any linear or non-linear region, and without limitation as to whether the amplifier is operating in compression or not in compression.

As described above, in the non-limiting examples described herein, DPD compensates for the distortion of the power amplifier by digitally pre-distorting the signal before the signal is input to the power amplifier. The digital pre-distortion may be applied to the signal by a digital pre-distortion circuit/function (similar to the digital pre-distortion circuit/function 520 as shown and described in connection with FIG. 5). The digital pre-distortion circuit/function may exist in the DC baseband portion (e.g., the digital processing section) of the circuitry associated with a transmitter, such as the transmitter 500 as shown and described in connection with FIG. 5. The amplifier (e.g., the power amplifier 510 (FIG. 5) may exist in the RF analog portion (e.g., the analog processing section) of the circuitry associated with the transmitter 500. The digital pre-distortion circuit/function 520 may thus operate in the digital domain.

The cascade of the digital pre-distortion circuit/function 520 and the power amplifier 510 results in more linear operation than just the power amplifier 510 alone.

Digital pre-distortion may use mathematical modeling and signal processing techniques. The digital pre-distortion circuit/function 520 may sample a signal at a DPD sampling rate. The DPD sampling rate may be used with a DPD model (e.g., stored on and manipulated on one or more memories of a processing system) to train the DPD model to predict the distortion introduced by the power amplifier 510 (e.g., operating in its compression region) and to consequently apply an inverse correction to the input signal, in the digital domain (in the digital processing section 502, the DC baseband stage, of the transmitter 500). By digitally pre-distorting the input signal (in the digital domain) before conversion of the signal to the analog domain and before applying the signal to the power amplifier 510, the digital pre-distortion may cause the amplified signal output from the power amplifier 510 to appear as if the signal had been amplified in a linear region of the power amplifier 510. The use of digital pre-distortion does not affect the efficiency of the power amplifier 510. Therefore, employing digital pre-distortion causes the output of the power amplifier 510 to remain closer to an ideal linear response (in comparison to a real-world non-linear response).

Referring to FIG. 6A for purposes of explanation and not limitation, if all or a portion 612 of the frequency range specified for NS_XX (e.g., all or a portion 612 of the frequency range identified for spectral suppression, all or a portion 612 of the frequency range identified for emission constraint, all or a portion 612 of the emission band 604 defined between and including the emission band lower frequency 620 (A) and the emission band upper frequency 622 (B), greater than the emission band lower frequency 620 (A)) lies within a digital pre-distortion (DPD) sampling rate 630 (as shown in FIG. 6A), the linearization of the in-band signal (e.g., within the first transmission channel 608) that is amplified by the power amplifier (implementing DPD linearization) and out-of-band emissions (e.g., unwanted spectral emissions, intermodulation products, etc. outside of the first transmission channel 608) that are within the DPD sampling rate 630 would all be understood to be linearized. As used herein, the term “within the DPD sampling rate,” “frequencies within the DPD sampling rate,” or “region of frequencies within the DPD sampling rate” may mean a region in the frequency domain between and including a transmission channel center frequency and a frequency that is spaced-apart from the transmission channel center frequency by the DPD sampling rate (i.e., by the magnitude of the DPD sampling rate). By way of example and not limitation, if a DPD sampling rate is given as 1,000 samples per second, then the phrase “within the DPD sampling rate” would mean within a range of frequencies equal to the transmission channel center frequency plus or minus 1,000 Hertz).

Referring to FIG. 6B for purposes of explanation and not limitation, if all of the frequency range specified for NS_XX (e.g., all of the frequency range identified for spectral suppression, all of the frequency range identified for emission constraint, all of the emission band 604 defined between and including the emission band lower frequency 620 (A) and the emission band upper frequency 622 (B), greater than the emission band lower frequency 620 (A)) lies outside of the DPD sampling rate 630 (as shown in FIG. 6B, e.g., the region including NS_XX that is outside 613 the DPD sampling rate 630), the linearization of the in-band signal (e.g., within the second transmission channel 610) that is amplified by the power amplifier (implementing DPD linearization) and out-of-band emissions (e.g., unwanted spectral emissions, intermodulation products, etc. outside of the second transmission channel 610) that are within the DPD sampling rate 630 (i.e., within and between the second transmission channel center frequency 628 (Z) and a spaced-apart frequency 627 given as Y (corresponding to (Z−|DPD sampling rate|) would all be understood as being other than linearized; in other words, being not linearized.

In some examples, the DPD sampling rate may be equal to one-half of the sampling frequency (i.e., Fs/2, where Fs may be determined per Nyquist sampling rate theory) being used to train the DPD model. One example of a first region 614 of frequencies within the DPD sampling rate 630 is depicted in FIG. 6A. One example of a second region 616 of frequencies within the DPD sampling rate 630 is depicted in FIG. 6B. The relationship of Fs/2=DPD sampling rate is offered as a non-limiting example. Other relationships, such as but not limited to Fs=DPD sampling rate, are within the scope of the disclosure.

In general, the region of frequencies within the DPD sampling rate may extend below a transmission channel's center frequency or extend above a transmission channel's center frequency. In both examples of FIG. 6A and FIG. 6B, the emission band 604 lies in frequencies below (i.e., less than) the first transmission channel center frequency 626 (X) and the second transmission channel center frequency 628 (Z), respectively. Consequently, in the example of FIG. 6A, the DPD sampling rate 630 may extend from and include the first transmission channel center frequency 626 (X) of the first transmission channel 608 toward frequencies below (i.e., less than) the first transmission channel center frequency 626 (X). Specifically, the first region 614 of frequencies within the DPD sampling rate 630 in FIG. 6A extends from the first transmission channel center frequency 626 (X) to a spaced-apart frequency 625 given as W, which is substantially equal to the first transmission channel center frequency 626 (X) minus the magnitude of the DPD sampling rate 630 (X−|DPD sampling rate|). However, if the emission band extended above the first transmission channel 608, a region of frequencies within the DPD sampling rate 630 in FIG. 6A would extend from the first transmission channel center frequency 626 (X) to a frequency (not shown), which is substantially equal to the first transmission channel center frequency 626 (X) plus the magnitude of the DPD sampling rate 630 (X+|DPD sampling rate|).

In the example of FIG. 6B, the DPD sampling rate 630 may extend from and include the second transmission channel center frequency 628 (Z) of the second transmission channel 610 toward frequencies below (i.e., less than) the second transmission channel center frequency 628 (Z). Specifically, the second region 616 of frequencies within the DPD sampling rate 630 in FIG. 6B extends from the second transmission channel center frequency 628 (Z) to the spaced-apart frequency 627 (Y), which is substantially equal to the second transmission channel center frequency 628 (Z) minus the magnitude of the DPD sampling rate 630 (Z−|DPD sampling rate|). However, if the emission band extended above the second transmission channel 610, a region of frequencies within the DPD sampling rate 630 in FIG. 6B would extend from the second transmission channel center frequency 628 (Z) to a frequency (not shown) that is substantially equal to the second transmission channel center frequency 628 (Z) plus the magnitude of the DPD sampling rate 630 (Z+|DPD sampling rate|).

When determining whether any portion of an NS frequency range (e.g., any portion of the emission band 604 defined between and including the emission band lower frequency 620 (A) and the emission band upper frequency 622 (B), greater than the emission band lower frequency 620 (A)) is within the DPD sampling rate 630, it may be useful to define a frequency sometimes referred to herein as a “third frequency” or alternatively as the spaced-apart frequency 625 (W) in connection with FIG. 6A and alternatively as the spaced-apart frequency 627 (Y) in connection with FIG. 6B. The spaced-apart frequency 625 (W) and the spaced-apart frequency 627 (Y) correspond to the first transmission channel center frequency 626 (X) of FIG. 6A, and the second transmission channel center frequency 628 (Z) of FIG. 6B, shifted (in frequency) by the DPD sampling rate 630.

For example, in connection with FIG. 6A, the DPD sampling rate 630 may be maintained in response to the spaced-apart frequency 625 (W) (corresponding to the first transmission channel center frequency 626 (X) shifted by the DPD sampling rate 630), being inside the emission band 604. Specifically, the spaced-apart frequency 625 (W) falls on or within the portion 612 of NS_XX that is inside the DPD sampling rate 630. However, in connection with FIG. 6B, the DPD sampling rate 630 may be changed in response to the spaced-apart frequency 627 (Y) (corresponding to the second transmission channel center frequency 628 (Z), shifted by the DPD sampling rate 630), being in a region that is outside 613 the DPD sampling rate 630 and outside the emission band 604.

In summary, if all or a portion of the NS frequency range (e.g., all or a portion of a spectrum emission suppression region defined by an NS, all or a portion of the emission band 604) lies within the DPD sampling rate 630, adequate linearization of out-of-band emissions within the NS frequency range and the DPD sampling rate (e.g., in the overlapping regions of the NS frequency range and the DPD sampling rate) may be expected. However, if none of the NS frequency range (e.g., none of a spectrum emission suppression region defined by an NS, none of the emission band 604) lies within the DPD sampling rate 630, inadequate linearization of out-of-band emissions within the NS frequency range may be expected.

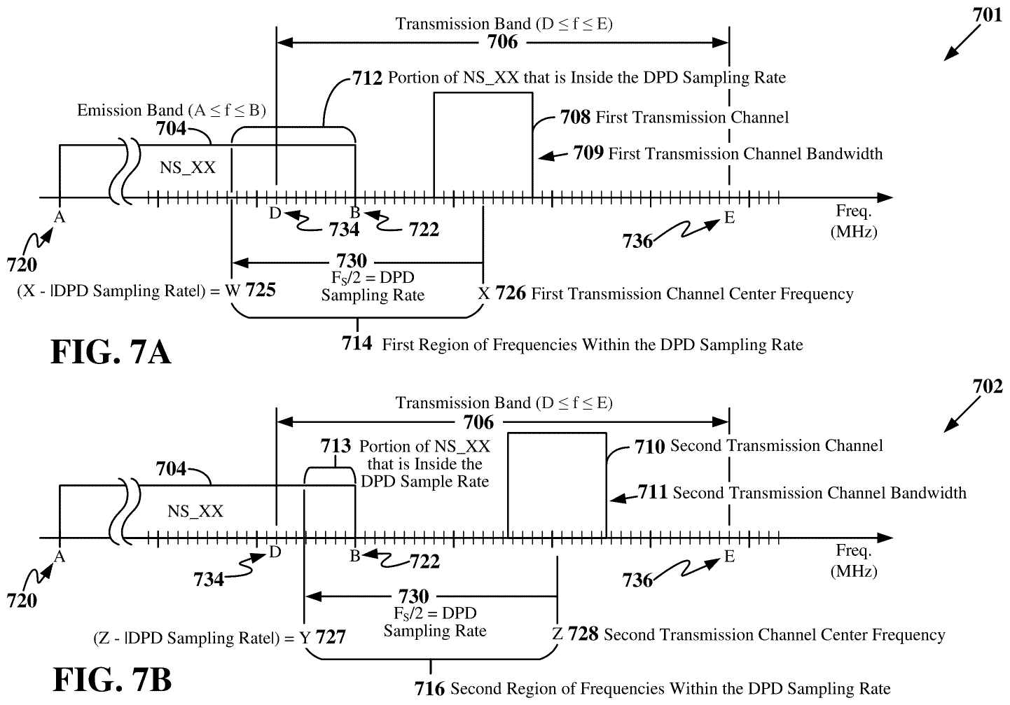

FIG. 7A and FIG. 7B are a first example 701 and a second example 702 of respective applications of network signaling (generically identified as NS_XX for case of reference) indicative of one or more emission constraints in an emission band 704 according to some aspects of the disclosure. In the examples of FIG. 7A and FIG. 7B, frequency is depicted on the horizontal axis in units of MHz. A vertical axis (e.g., amplitude or power) is not shown in the first example 701 and the second example 702, as the examples are provided for discussion in the context of frequency. The heights of any blocks in FIG. 7A and FIG. 7B are not representative of any limiting characteristic of that block. As explained in connection with FIGS. 6A and 6B, the variables A, B, D, E, W, X, Y, and Z may each be any non-zero number. In this example, the variables A, B, D, E, W, X, Y, and Z are all representative of frequencies and are all represented in the same units of measure, for example, Hertz or MHz.

For purposes of explanation and not limitation, FIG. 7A depicts one channel, which may be described as a first transmission channel 708, defined by a first transmission channel bandwidth 709 and a first transmission channel center frequency 726 given as X, all within the transmission band 706. For purposes of explanation and not limitation, FIG. 7B depicts another channel, which may be described as a second transmission channel 710, which is different from the first transmission channel 708. The second transmission channel 710, may be defined by a second transmission channel bandwidth 711, and a second transmission channel center frequency 728 given as Z, all within the transmission band 706. In the examples of FIG. 7A and FIG. 7B, the first transmission channel bandwidth 709, and the second transmission channel bandwidth 711 are both depicted as being 10 MHz for case of illustration and not limitation.

The examples of FIG. 7A and FIG. 7B presume that NS_XX, having the emission band 704, was scheduled to a given UE by a base station (e.g., a network entity). Table 3 above presents parameters associated with NS_XX.

In FIG. 7A and FIG. 7B, the emission band 704, defined between and including the emission band lower frequency 720 (A) and the emission band upper frequency 722 (B), greater than the emission band lower frequency 720 (A), remains unchanged from the emission band 604 as shown and described in connection with FIG. 6A and FIG. 6B. The emission band 704 is defined by the frequency range provided in NS_XX (see Table 3 above). Similarly, the first transmission channel 708 of FIG. 7A and the second transmission channel 710 of FIG. 7B, have the first transmission channel bandwidth 709 and the second transmission channel bandwidth 711, respectively.

However, in FIG. 7A and FIG. 7B, even though the equation for the sampling frequency (Fs) remains the same as in FIG. 6A and FIG. 6B (i.e., Fs=2×the DPD sampling rate), the DPD sampling rate has increased in magnitude to a DPD sampling rate 730, which is greater than the DPD sampling rate 630 of FIGS. 6A and 6B. The increase to the DPD sampling rate 730 has expanded the first region 714 of frequencies within the DPD sampling rate 730 to a region of frequencies spanning from the spaced-apart frequency 725, given as W, corresponding to the first transmission channel center frequency 726 (X) minus the magnitude of the DPD sampling rate 730, up to the first transmission channel center frequency 726 (X). The increase to the DPD sampling rate 730 has expanded the second region 716 of frequencies within the DPD sampling rate (in FIG. 7B) to a region of frequencies spanning from a spaced-apart frequency 727, given as Y, corresponding to the second transmission channel center frequency 728 (Z) minus the magnitude of the DPD sampling rate 730, up to the second transmission channel center frequency 728 (Z). Accordingly, the spaced-apart frequency 725 (W) in FIG. 7A is shifted downward (i.e., toward a lower frequency) compared to the spaced-apart frequency 625 (W) in FIG. 6A. The spaced-apart frequency 727 (Y) in FIG. 7B is shifted downward (i.e., toward a lower frequency) compared to the spaced-apart frequency 627 (Y) in FIG. 6B.

Shifting the spaced-apart frequency 725 (W) in FIG. 7A has increased the portion 712 of NS_XX that is inside the DPD sampling rate 730 in connection with the example of FIG. 7A. Shifting the spaced-apart frequency 727 (Y) in FIG. 7B results in a portion 713 of NS_XX to be included within the DPD sampling rate 730 in connection with the example of FIG. 7B.

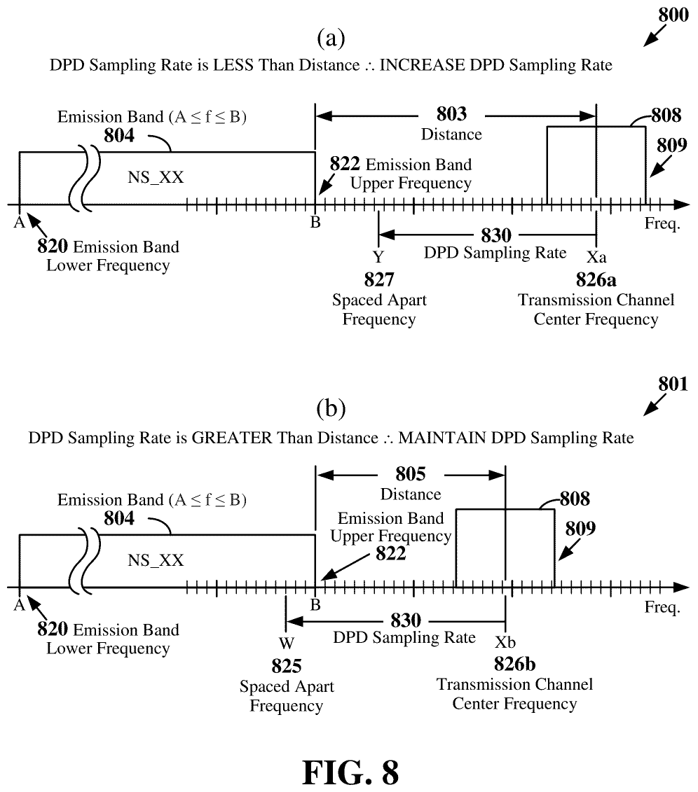

FIG. 8 is an example of relative distances between an emission band 804 and a transmission channel 808 according to some aspects of the disclosure. In the examples of FIG. 8, frequency is depicted along the horizontal axis. The vertical dimensions and widths of the features of FIG. 8 are for purposes of differentiation and not limitation. The emission band 804 may be defined by a network signaling value referred to as NS_XX herein between an emission band lower frequency 820 (A) and an emission band upper frequency 822 (B). According to some aspects of the disclosure, in a first example 800 (a) and a second example 801 (b), an apparatus may transmit a signal sampled at a DPD sampling rate 830 in a transmission channel 808 having a transmission channel center frequency. The transmission channel 808 also has a transmission channel bandwidth 809. The difference between the first example 800 and the second example 801 is in the location of the transmission channel center frequency. For purposes of explanation and not limitation, the transmission channel center frequency illustrated in the first example 800 is referred to as a transmission channel center frequency 826a, given as Xa. The transmission channel center frequency illustrated in the second example 801 is referred to as a transmission channel center frequency 826b, given as Xb.

Although the DPD sampling rate 830 may be understood as being given in units of samples per second, for purposes of side-by-side comparisons of DPD sampling rate and distance (between two points on a frequency axis) in this disclosure, the DPD sampling rate 830 will be considered as being expressed in units of frequency (e.g., Hertz (Hz), kHz, MHz, etc.). In the first example 800, the starting magnitude of the DPD sampling rate 830 may be measured between the transmission channel center frequency 826a, given as Xa, and a spaced-apart frequency 827, given as Y. In the second example 801, the starting magnitude of the DPD sampling rate 830 may be measured between the transmission channel center frequency 826b, given as Xb, and a spaced-apart frequency 825, given as W. The starting magnitudes of the DPD sampling rate 830 are the same in both examples (i.e., Xb−W=Xa−Y).

In the first example, the apparatus may determine a distance 803 between the transmission channel center frequency 826a (Xa) and a closest one, relative to the transmission channel center frequency 826a, of an emission band lower frequency 820 and an emission band upper frequency 822. Similarly, in the second example, the apparatus may determine a distance 805 between the transmission channel center frequency 826b (Xb) and a closest one, relative to the transmission channel center frequency 826b, of the emission band lower frequency 820 and the emission band upper frequency 822. The closest one (e.g., the closest edge, or band edge of the emission band 804) is the emission band upper frequency 822, given as B, in both examples.

In the first example 800, to adjust the DPD sampling rate 830 based on the distance 803, the apparatus (e.g., one or more processors of the apparatus) may be configured to one of: increase the DPD sampling rate 830 in response to the DPD sampling rate 830 being less than the distance 803, and maintain the DPD sampling rate 830 (i.e., not change, neither increase nor decrease the DPD sampling rate 830) in response to the DPD sampling rate 830 being greater than the distance 803. An observation of the first example 800 reveals that the DPD sampling rate 830 is less than the distance 803; therefore, the apparatus would increase the DPD sampling rate 830. According to the examples described herein, the increase would cause the magnitude of the DPD sampling rate 830 to be greater than the magnitude of the distance 803. In other words, the increase would result in a portion of NS_XX (e.g., a portion of the emission band 804) being included within the DPD sampling rate 830. In still other words, the increase would result in the spaced-apart frequency 827 (Y) being lowered in frequency to the emission band upper frequency 822 (B) or less.

In the second example 801, to adjust the DPD sampling rate 830 based on the distance 805, the apparatus (e.g., one or more processors of the apparatus) may be configured to one of: increase the DPD sampling rate 830 in response to the DPD sampling rate 830 being less than the distance 805, and maintain the DPD sampling rate 830 (i.e., not change, neither increase nor decrease the DPD sampling rate 830) in response to the DPD sampling rate 830 being greater than the distance 805. An observation of the second example 801 reveals that the DPD sampling rate 830 is greater than the distance 805; therefore, the apparatus would maintain the DPD sampling rate 830. According to examples described herein, maintaining the DPD sampling rate 830 keeps a portion of NS_XX (e.g., a portion of the emission band 804 between the spaced-apart frequency 825 (W) and the emission band upper frequency 822 (B)) included within the DPD sampling rate 830.

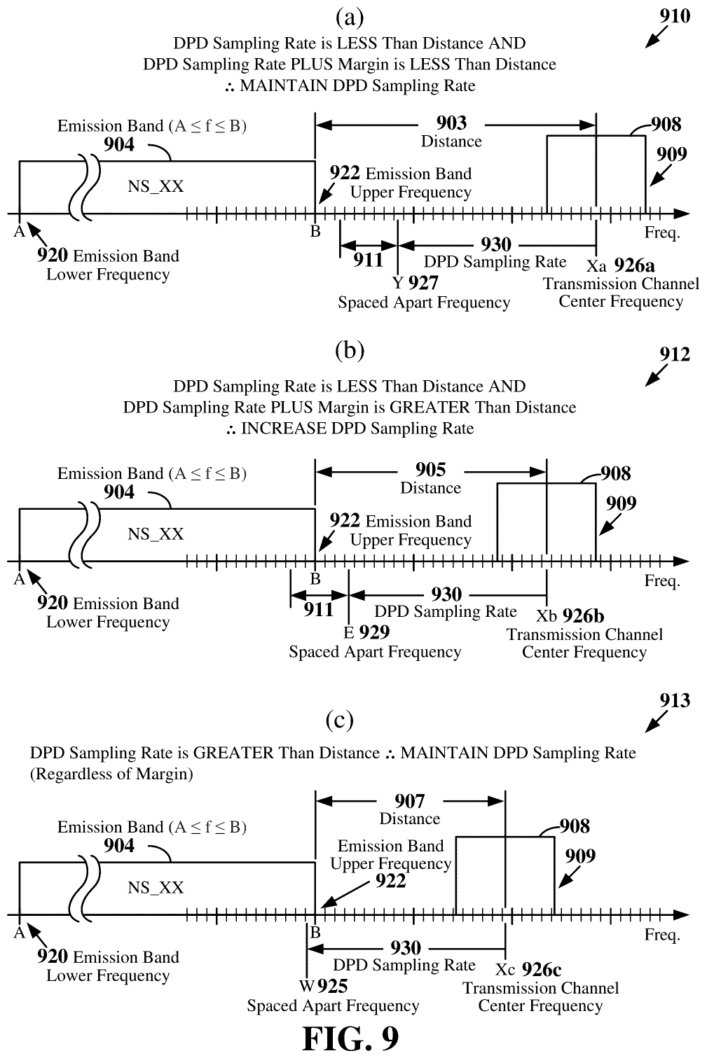

FIG. 9 is an example of relative distances between an emission band 904 and a transmission channel 908 according to some aspects of the disclosure. In the examples of FIG. 9, frequency is depicted along the horizontal axis. The vertical dimensions and widths of the features of FIG. 9 are for purposes of differentiation and not limitation. The emission band 904 may be defined by a network signaling value referred to as NS_XX herein between an emission band lower frequency 920 (A) and an emission band upper frequency 922 (B). According to some aspects of the disclosure, in a first example 910 (a), a second example 912 (b), and a third example 913 (c), an apparatus may transmit a signal sampled at a DPD sampling rate 930 in a transmission channel 908 having a transmission channel center frequency. The transmission channel 908 also has a transmission channel bandwidth 909. The difference between the first example 910, the second example 912, and the third example 913 is in the location of the transmission channel center frequency. For purposes of explanation and not limitation, the transmission channel center frequency illustrated in the first example 910 is referred to as a transmission channel center frequency 926a, given as Xa. The transmission channel center frequency illustrated in the second example 912 is referred to as a transmission channel center frequency 926b, given as Xb. The transmission channel center frequency illustrated in the third example 913 is referred to as a transmission channel center frequency 926c, given as Xc.

In the examples of FIG. 9, as described above in connection with FIG. 8, the DPD sampling rate and the distances are given in the same units of frequency (e.g., Hz, kHz, MHz, etc.). In the examples of FIG. 9, a frequency span, or a value of frequency, referred to herein as a margin 911, is appended to the vector representing the DPD sampling rate 930. The margin 911 may be predefined.

The various values (e.g., the magnitudes of the distances) that are compared in the examples of FIG. 9 are: the distance 903, 905, 907 between the transmission channel center frequency 926a, 926b, 926c and the closest one, relative to the transmission channel center frequency 926a, 926b, 926c, of the emission band lower frequency 920 and the emission band upper frequency 922; the DPD sampling rate 930 (e.g., the magnitude of the DPD sampling rate); and the DPD sampling rate 930 plus the margin 911 (e.g., the total of the magnitude of the DPD sampling rate 930 plus the magnitude of the margin 911).

In the first example 910, the apparatus may determine a distance 903 between the transmission channel center frequency 926a (Xa) and a closest one, relative to the transmission channel center frequency 926a, of an emission band lower frequency 920 and an emission band upper frequency 922. Similarly, in the second example 912, the apparatus may determine a distance 905 between the transmission channel center frequency 926b (Xb) and a closest one, relative to the transmission channel center frequency 926b, of the emission band lower frequency 920 and the emission band upper frequency 922. Similarly, in the third example 913, the apparatus may determine a distance 907 between the transmission channel center frequency 926c (Xc) and a closest one, relative to the transmission channel center frequency 926c, of the emission band lower frequency 920 and the emission band upper frequency 922. The closest one (e.g., the closest edge or band edge of the emission band 804) in each example is the emission band upper frequency 922, given as B.

In each of the first example 910, the second example 912, and the third example 913, the apparatus may be configured to adjust the DPD sampling rate 930, based on the distance 903, 905, 907 by being configured to one of: maintain and increase (i.e., configured to either maintain or increase) the DPD sampling rate 930. Once increased, the apparatus may be configured to decrease the DPD sampling rate 930 in response to a change to the conditions that caused the increase.

According to one aspect, the DPD sampling rate 930 may be maintained in response to both the following conditions being true: the DPD sampling rate 930 is less than the distance (903, 905, 907) and the DPD sampling rate 930 plus the margin 911 is less than the distance 903. Here, the addition of the margin 911 prevents an increase to the DPD sampling rate 930 if the transmission center frequency 926 is at a distance from the emission band 904, where the increase to the DPD sampling rate 930 would not be needed to suppress out-of-band emissions within the emission band 904 (e.g., a natural roll-off of the amplifier or the presence of filtering would be sufficient suppression of the out-of-band emissions). Alternatively (e.g., the Boolean “or”), the DPD sampling rate 930 may be maintained in response to the following condition being true: the DPD sampling rate 930 is greater than the distance (903, 905, 907) (regardless of the margin 911). In this aspect, because the margin 911 is appended to the DPD sampling rate 930, if the magnitude of the DPD sampling rate 930 is already greater than the magnitude of the distance (903, 905, 907), then the magnitude of the DPD sampling rate 930 plus the magnitude of the margin 911 will also be greater than the distance (903, 905, 907).

According to one aspect, the DPD sampling rate 930 may be configured to increase in response to both the following conditions being true: the DPD sampling rate is less than the distance (903, 905, 907) and the DPD sampling rate 930 plus the margin 911 is greater than the distance (903, 905, 907). In this aspect, the margin ensures that if the transmission center frequency 926 is at a distance from the emission band 904, where the increase to the DPD sampling rate 930 would be needed to suppress out-of-band emissions within the emission band 904, then the increase would occur.

An observation of the first example 910 reveals that the DPD sampling rate 930 is less than the distance 903 and the DPD sampling rate 930 plus the margin 911 is also less than the distance 903; therefore, the apparatus would maintain the DPD sampling rate 930.

An observation of the second example 912 reveals that the DPD sampling rate 930 is less than the distance 905 and the DPD sampling rate 930 plus the margin 911 is greater than the distance 905; therefore, the apparatus would increase the DPD sampling rate 930. According to some examples described herein, the increase may cause the magnitude of the DPD sampling rate 930 to be greater than the magnitude of the distance 905. In other words, the increase would result in a portion of NS_XX (e.g., a portion of the emission band 904) being included within the DPD sampling rate 930. In still other words, the increase would result in the spaced-apart frequency 929 (E) being lowered in frequency to the emission band upper frequency 922 (B) or less.

An observation of the third example 913 reveals that the DPD sampling rate 930 is greater than the distance 907 (with or without the margin 911 appended thereto). Therefore, the apparatus would maintain the DPD sampling rate 930. According to examples described herein, maintaining the DPD sampling rate 930 keeps a portion of NS_XX (e.g., a portion of the emission band 904 between the spaced-apart frequency 925 (W) and the emission band upper frequency 822 (B)) included within the DPD sampling rate 930.

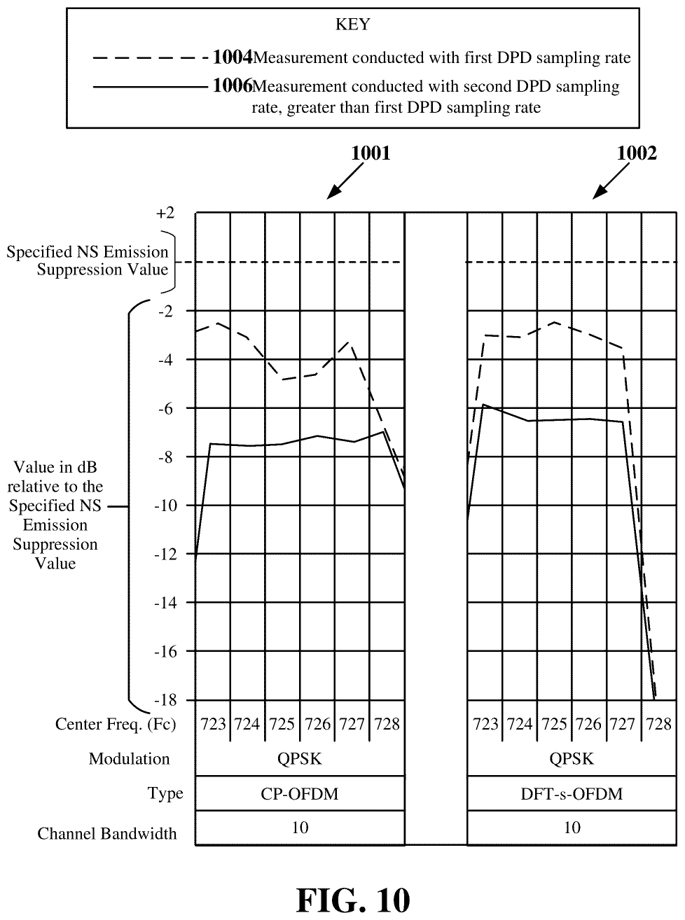

FIG. 10 depicts a first graph 1001 and a second graph 1002 of emission suppression values for transmission channel center frequencies ranging from 723-728 MHz, where the transmission channel center frequencies are in the n28 band, and the emission suppression values are measured in the frequency range defined in N_17 according to some aspects of the disclosure. The range of transmission channel center frequencies and use of n28 and NS_17 are exemplary and non-limiting. The traces in dashed lines correspond to measurements taken with a first DPD sampling rate 1004. The traces depicted in solid lines correspond to measurements taken with a second DPD sampling rate 1006, greater than the first DPD sampling rate 1004. The first graph 1001 and the second graph 1002 are representative of the same modulation (e.g., QPSK) and transmission channel bandwidth (e.g., 10 MHZ). The first graph 1001 employs CP-OFDM, while the second graph 1002 employs DFT-s-OFDM. As depicted in FIG. 10, the emission suppression is greater in the examples using the second DPD sampling rate 1006 than in the first DPD sampling rate 1004.

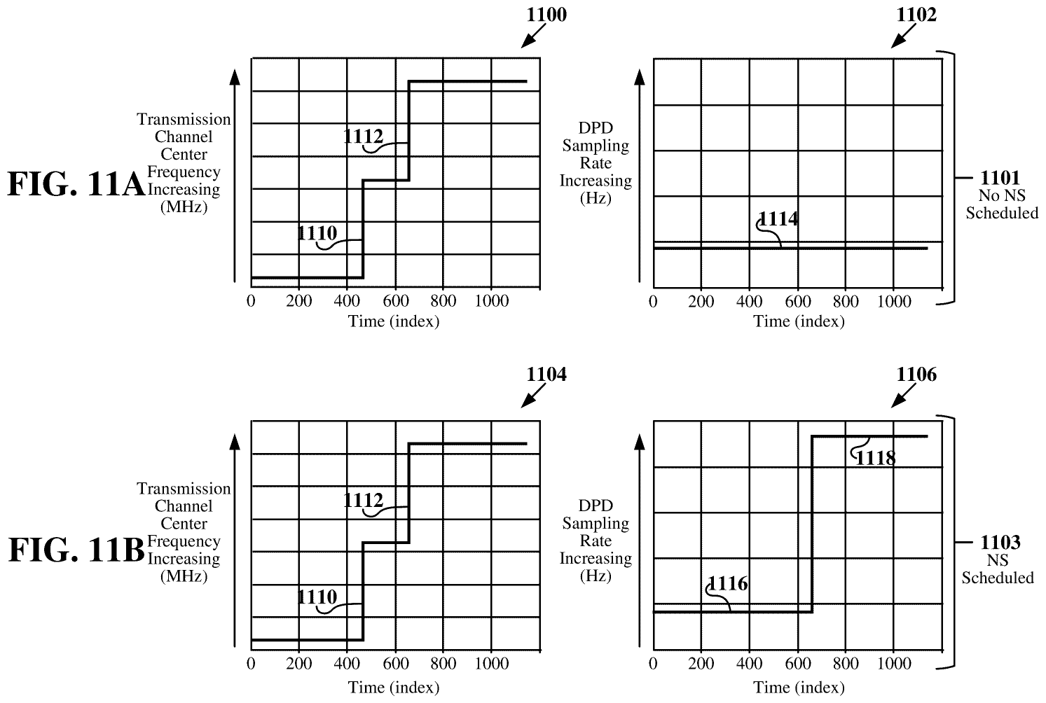

FIG. 11A depicts a first graph 1100, illustrating transmission channel center frequency (in MHz) (increasing from bottom to top) along the vertical axis versus time (expressed as an index value) along the horizontal axis, and a second graph 1102, illustrating a DPD sampling rate (in Hz) (increasing from bottom to top) along the vertical axis versus time (expressed as the index value) along the horizontal axis, both graphs are illustrated according to some aspects of the disclosure. FIG. 11B depicts a third graph 1104, illustrating channel center frequency (in MHZ) (increasing from bottom to top) along the vertical axis versus time (expressed as an index value) along the horizontal axis, and a fourth graph 1106, illustrating the DPD sampling rate (in Hz) (increasing from bottom to top) along the vertical axis versus time (expressed as the index value) along the horizontal axis, both graphs are illustrated according to some aspects of the disclosure.

In connection with the first graph 1100 and the second graph 1102 of FIG. 11A, there is no NS scheduled 1101 to a UE (not shown). The first graph 1100 depicts a first step change 1110 and a second step change 1112 made to the transmission channel center frequency. As there is no NS scheduled in connection with the first graph 1100 and the second graph 1102, the DPD sampling rate remains constant (as shown by the flat line 1114) for the entire duration shown in the first graph 1100 and the second graph 1102.

In connection with FIG. 11B, there is an NS scheduled 1103 to the UE (not shown). The NS scheduled 1103 may be exemplified with any NS identifier as used herein (e.g., NS_17, NS_XX). The third graph 1104 depicts the same first step change 1110 and second step change 1112 made to the transmission channel center frequency as shown in the first graph 1100 (FIG. 11A). Because of the NS scheduled 1103 in connection with the third graph 1104 and the fourth graph 1106, and because a third frequency (not shown, but similar to the spaced-apart frequency 625 (W) (FIG. 6A), the spaced-apart frequency 627 (Y) (FIG. 6B), the spaced-apart frequency 725 (W) (FIG. 7A), and the spaced-apart frequency 727 (Y) (FIG. 7B)) was determined to be outside an emission band specified or defined by the NS scheduled 1103 (e.g., outside of the emission band 604 and emission band 704 as exemplified in FIGS. 6A, 6B and 7A, 7B, respectively), upon the second step change 912 in transmission channel center frequency (at the time index 650) the DPD sampling rate was changed from a first value 1116 to a second value 1118, greater than the first value 1116. That is, the DPD sampling rate was increased to cause the spaced-apart frequency 625 (W), the spaced-apart frequency 627 (Y), the spaced-apart frequency 725 (W), the spaced-apart frequency 727 (Y) (also referred to herein as a third frequency) to fall within (to be shifted to being inside of) the emission band 604, 704 (utilizing the terminology described in connection with FIGS. 6A, 6B, 7A, and 7B) at the time index 650.

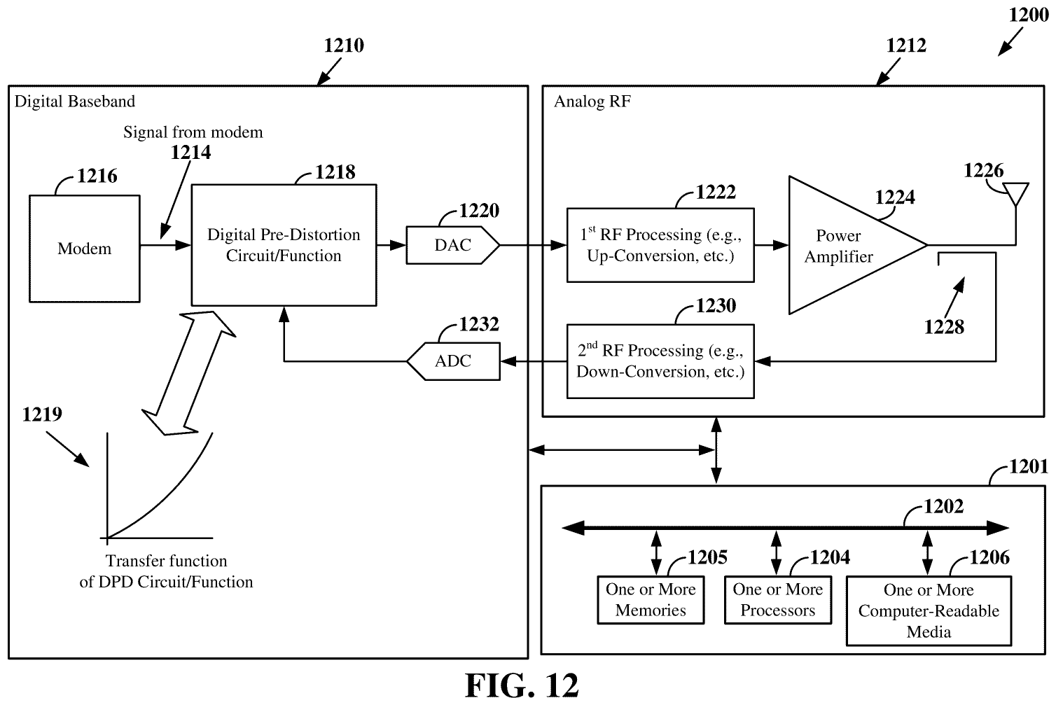

FIG. 12 is a block diagram illustrating a schematic arrangement of signals, circuits/functions, processes, and hardware employing one or more processing systems (collectively an apparatus 1200) according to some aspects of the disclosure. The apparatus 1200 may be similar to, for example, any of the scheduled entities 106 as shown and described in connection with FIG. 1, any of the UEs 222, 224, 230, 232, 234, 236, 238, 240, 242 as shown and described in connection with FIG. 2, and/or the transmitter 500 as shown and described in connection with FIG. 5.

In accordance with various aspects of the disclosure, an element, any portion of an element, or any combination of elements may be implemented with one or more processing systems, generally represented by processing system 1201. The processing system 1201 may be implemented with a bus architecture, represented generally by the bus 1202 that includes one or more processors 1204, one or more memories 1205, and additionally or alternatively one or more computer-readable media 1206. Examples of processors (represented by the one or more processors 1204) include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In various examples, the apparatus 1200 may be configured to perform any one or more of the functions described herein. That is, the one or more processors 1204, as utilized in the apparatus 1200, may be configured to, individually or collectively, based at least in part on information stored in the one or more memories 1205 and additionally or alternatively in the one or more computer-readable media 1206, implement (e.g., perform) any one or more of the methods or processes described and illustrated, for example, in FIGS. 1, 2, 4A, 4B, 5, 6A, 6B, 7A, 7B, 10, 11A, and/or 11B.

The apparatus 1200, as schematically represented, may exist in two domains: the digital domain (represented by the digital baseband 1210 block) and the analog domain (represented by the analog RF 1212 block). The digital baseband 1210 block schematically represents a signal 1214 from the modem 1216. The signal 1214 from the modem 1216 exists in the digital domain and may be described as a digital signal. The signal 1214 from the modem 1216 is applied to a digital pre-distortion circuit/function 1218. The digital pre-distortion circuit/function 1218 may implement/perform, for example, the DPD sampling rate determination, adjustment, switching, and/or changing described in connection with any one or more of FIGS. 4A, 4B, 5, 6A, 6B, 7A, 7B, 10, 11A, and/or 11B. The transfer function of the digital pre-distortion circuit/function 1218 is represented by the inset graph 1219 in the digital baseband 1210 block. The transfer function of the digital pre-distortion circuit/function 1218 may correspond to an inverse transfer function of the power amplifier 1224.

The signal 1214 from the modem 1216, following the transformation imparted to it by the digital pre-distortion circuit/function 1218, may be converted to an analog signal (not shown) by a digital-to-analog converter 1220 and applied to 1st RF processing circuitry 1222 (e.g., up-conversion to RF, quadrature mixing, etc.). Ultimately, the transformed and upconverted signal is applied to the power amplifier 1224 and then transmitted via an antenna or antenna array 1226.

In connection with the operation of the digital pre-distortion circuit/function 1218, a sample of the output of the power amplifier 1224 may be obtained from a coupler 1228 (e.g., an RF coupler, a divider, a tap) at an output of the power amplifier 1224. The sample obtained by the coupler 1228 may be applied to a 2nd RF processing circuitry 1230 (e.g., down-conversion to baseband, etc.). The output of the 2nd RF processing circuitry 1230 may be applied to an analog-to-digital converter 1232. The output of the analog-to-digital converter 1232 may be fed back to the digital pre-distortion circuit/function 1218 and may be used in connection with training the digital pre-distortion circuit/function 1218 in association with the derivation, updating, switching, changing, etc., of the digital pre-distortion format and/or DPD sampling rate and other parameters.

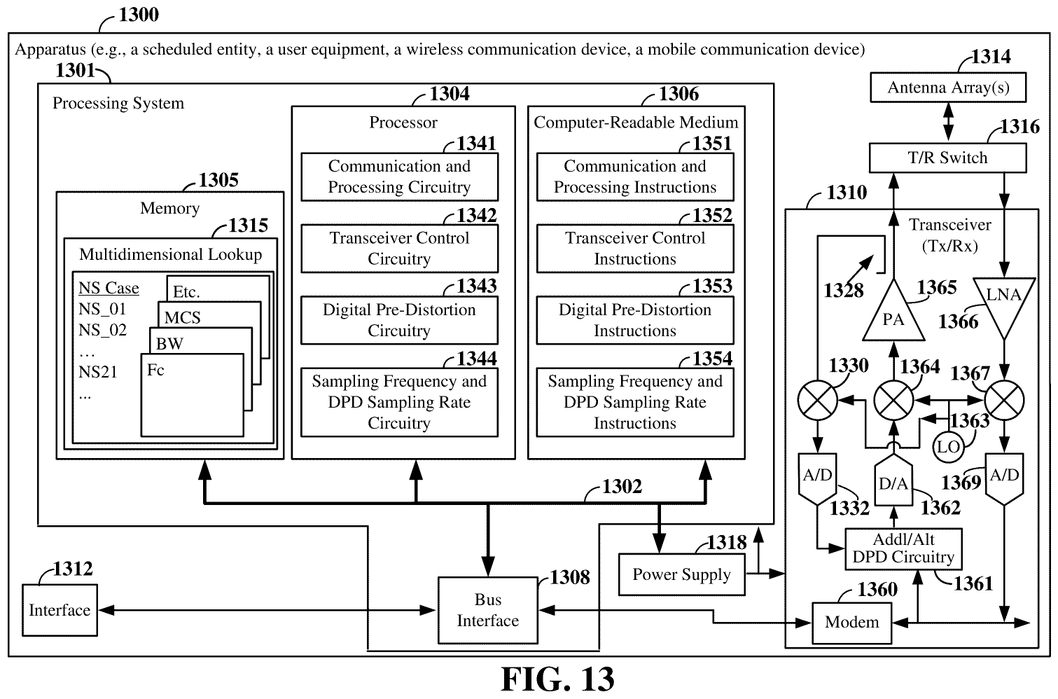

FIG. 13 is a block diagram illustrating an example of a hardware implementation of an apparatus 1300 (e.g., a UE, a wireless communication device, a scheduled entity), employing one or more processing systems (generally represented by processing system 1301) according to some aspects of the disclosure. The apparatus 1300 may be similar to, for example, any of the scheduled entities 106 as shown and described in connection with FIG. 1, any of the UEs 222, 224, 230, 232, 234, 236, 238, 240, 242 as shown and described in connection with FIG. 2, the transmitter 500 as shown and described in connection with FIG. 5, and/or the apparatus 1000 as shown and described in connection with FIG. 12.

In accordance with various aspects of the disclosure, an element, any portion of an element, or any combination of elements may be implemented with a processing system 1301 that includes one or more processors, generally represented by processor 1304, and one or more memories, generally represented by the memory 1305, and additionally or alternatively one or more computer-readable media, generally represented by the computer-readable medium 1306. Examples of processor 1304 include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In various examples, the apparatus 1300 may be configured to perform any one or more of the functions described herein. That is the one or more processors (generally represented by processor 1304), as utilized in the apparatus 1300, may be configured to, individually or collectively, based at least in part on information stored in the one or more memories (generally represented by the memory 1305 and additionally or alternatively generally represented by the computer-readable medium 1306), implement (e.g., perform) any one or more of the methods or processes described and illustrated, for example, in FIGS. 1, 2, 4A, 4B, 5, 6A, 6B, 7A, 7B, 10, 11A, 11B, and/or 12.

In this example, the processing system 1301 may be implemented with a bus architecture, represented generally by the bus 1302. The bus 1302 may include any number of interconnecting buses and bridges depending on the specific application of the processing system 1301 and the overall design constraints. The bus 1302 couples together various circuits, including one or more processors (generally represented by the processor 1304), one or more memories (generally represented by the memory 1305), and one or more computer-readable media (generally represented by the computer-readable medium 1306). The bus 1302 may also link various other circuits such as power supply circuits 1318, timing sources, peripherals, voltage regulators, and power management circuits, which are well known to persons having ordinary skill in the art and, therefore, will not be described any further.

A bus interface 1308 provides an interface between the bus 1302 and one or more transceivers, represented individually and collectively by a transceiver 1310 and associated hardware such as a transmit/receive switch 1316 (or one or more transmit/receive (T/R) switches) and the antenna(s)/antenna array(s) 1314. The transceiver 1310 may be, for example, a wireless transceiver. The transceiver 1310 may be operational with multiple RATs (e.g., LTE, 5G NR, IEEE 802.11 (WiFi®), etc.). The transceiver 1310 may provide respective means for communicating with various other apparatus, UEs, network entities, base stations, and core networks over a transmission medium (e.g., air interface). The transceiver 1310 may be coupled to one or more respective antenna(s)/antenna array(s) 1314 via the transmit/receive switch 1316. The bus interface 1308 may provide an interface between the bus 1302, the transceiver 1310, and a user interface 1312 (e.g., keypad, display, touch screen, speaker, microphone, control features, vibration circuit/device, etc.). Of course, such a user interface 1312 is optional and may be omitted in some examples.

The transceiver 1310 may include a modem 1360 that may modulate and demodulate baseband digital signals (e.g., traffic and control signals). The modem 1360 may be similar to the modem 1216, as shown and described in connection with FIG. 12. Although the modem 1360 is illustrated as a component of the transceiver 1310, the illustration is for ease of illustration and not limitation. The modem may be a component of the transceiver 1310, the processing system 1301, or any aspect of the apparatus 1300. The uplink signals input to (e.g., applied to) the modem 1360 and the downlink signals output from the modem 1360 may be coupled, for example, to the communication and processing circuitry 1341 of the processor 1304 via the bus interface 1308 and bus 1302. An output of the modem 1360 may be applied to digital pre-distortion circuitry, such as the digital pre-distortion circuitry 1343 of the processor 1304 and/or the additional/alternative digital pre-distortion circuitry 1361 of the transceiver 1310. The various digital pre-distortion circuitry may be similar to the digital pre-distortion circuit/function 408, 520, 1218 as shown and described in connection with FIGS. 4, 5, and 12, respectively.

The output of the digital pre-distortion circuitry (e.g., the digital pre-distortion circuitry 1343 of the processor 1304 and/or the additional/alternative digital pre-distortion circuitry 1361) may be applied to a digital-to-analog converter 1362, which may be similar to the digital-to-analog converter 522, 1220 as shown and described in connection with FIGS. 5 and 12, respectively.

With reference now to the transceiver 1310, the output of the digital-to-analog converter 1362 may be upconverted by a first mixer 1364. The output frequency of the first mixer 1364 may be controlled by the local oscillator 1363, whose frequency may be controlled, for example, by the communication and processing circuitry 1341. The first mixer 1364 may be similar to, for example, the first mixer 504 as shown and described in connection with FIG. 5, and/or a mixer (not shown) in the 1st RF processing circuitry 1222 as shown and described in connection with FIG. 12. The upconverted signal may be configured to be transmitted, for example, on the first transmission channel 608 or the second transmission channel 610, as shown and described in connection with FIG. 6A or FIG. 6B, respectively. The upconverted signal may be configured to be transmitted, for example, on the first transmission channel 708 or the second transmission channel 710 as shown and described in connection with FIG. 7A or FIG. 7B, respectively. The upconverted signal may be applied to a power amplifier 1365, similar to, for example, the power amplifier 402, 510, or 1224 as shown and described in connection with FIG. 4, 5, or 12, respectively.

A sample of the output of the power amplifier 1365 may be obtained from a coupler 1328, similar to, for example, the coupler 528, 1228 as shown and described in connection with FIGS. 5 and 12, respectively. The output of the coupler 1328 may be downconverted by a feedback receiver mixer 1330, which may be a component of, or associated with, a feedback receiver (not shown). The feedback receiver mixer 1330 may be similar to, for example, the feedback receiver mixer 530 as shown and described in connection with FIG. 5, and/or a feedback receiver mixer (not shown) in the 2nd RF processing circuitry 1230 as shown and described in connection with FIG. 12. The local oscillator 1363 frequency determines which transmission channel is downconverted to baseband.

The output of the feedback receiver mixer 1330 may be applied to an analog-to-digital converter 1332, similar to, for example, the analog-to-digital converter 532, 1232 as shown and described in connection with FIGS. 5 and 13, respectively. The output of the analog-to-digital converter 1332 may be fed back to the digital pre-distortion circuitry (e.g., the digital pre-distortion circuitry 1343 and/or the additional/alternative digital pre-distortion circuitry 1361) and may be used in connection with training the digital pre-distortion circuitry in association with the derivation, updating, switching, changing, etc. of the digital pre-distortion format and/or DPD sampling rate and other parameters.

On the receive side of the transceiver 1310, signaling may be received at a low noise amplifier (LNA) 1366 via the antenna(s)/antenna array(s) 1314 and the transmit/receive switch 1316. The signaling may be down-converted by applying an output of the local oscillator 1363 to a second mixer 1367. The down-converted signaling may be applied to an analog-to-digital converter 1369, which may provide the digital signaling bearing the parameters to, for example, the communication and processing circuitry 1341 via the modem 1360, bus interface 1308 and bus 1302 according to some aspects of the disclosure.

The one or more processors, represented individually and collectively by processor 1304, may be responsible for managing the bus 1302 and general processing, including the execution of software stored on the one or more memories (represented individually and collectively by a memory 1305) and/or on the one or more computer-readable media (represented individually and collectively by a computer-readable medium 1306). Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on the memory 1305 and/or the computer-readable medium 1306. The software, when executed by the one or more processors (generally represented by processor 1304), causes the processing system 1301 to perform the various processes and functions described herein for any particular apparatus.

The computer-readable medium 1306 may be a non-transitory computer-readable medium and may be referred to as a computer-readable storage medium or a non-transitory computer-readable medium. The non-transitory computer-readable medium may store computer-executable code (e.g., processor-executable code). The computer executable code may include code for causing a computer (e.g., a processor) to implement one or more of the functions described herein. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium 1306 may reside in the processing system 1301, external to the processing system 1301, or distributed across multiple entities, including the processing system 1301. The computer-readable medium 1306 may be embodied in a computer program product or article of manufacture. For example, a computer program product or article of manufacture may include a computer-readable medium in packaging materials. In some examples, the computer-readable medium 1306 may be part of the memory 1305. Persons having ordinary skill in the art will recognize how best to implement the described functionality presented throughout this disclosure depending on the particular application and the overall design constraints imposed on the overall system. The computer-readable medium 1306 and/or the memory 1305 may also be used for storing data that is manipulated by the processor 1304 when executing software. For example, memory 1305 may store a multidimensional table 1315 (e.g., a multi-dimensional lookup table) utilized in conjunction with the selection of DPD sampling rates and other parameters, according to some aspects of the disclosure.

In some aspects of the disclosure, the one or more processors (generally represented by processor 1304) may include communication and processing circuitry 1341 configured for various functions, including, for example, communicating with a network entity (e.g., a base station, a gNB, a scheduling entity) and/or a core network. In some examples, the communication and processing circuitry 1341 may include one or more hardware components that provide the physical structure that performs processes related to wireless communication (e.g., signal reception and/or signal transmission) and signal processing (e.g., processing a received signal and/or processing a signal for transmission). The communication and processing circuitry 1341 may further be configured to execute communication and processing instructions 1351 (e.g., software) stored, for example, on the computer-readable medium 1306 to implement one or more functions described herein.

In some aspects of the disclosure, the processor 1304 may include transceiver control circuitry 1342 configured for various functions, including, for example, configuring the transceiver 1310 to transmit via an amplifier (e.g., the power amplifier 1365) and the antenna array(s) 1314, a transmitted signal in a first transmission channel defined by a first transmission channel bandwidth and a first transmission channel center frequency. In some examples, the first band may be a channel in a predefined radio frequency band. In some examples, a channel center frequency and a channel bandwidth define the channel. In some examples, the first band may be a first channel among a plurality of channels in a predefined radio frequency band, the first center frequency and the first bandwidth may correspond to a first channel center frequency and a first channel bandwidth, and the one or more processors (generally represented by processor 1304) may be further configured to make the change (to the DPD sampling rate) in association with the first channel, as distinct from the plurality of channels.

In one example, the digital pre-distortion circuitry 1343 may be configured in the processor 1304. In another example, the digital pre-distortion circuitry/function may be configured in the transceiver 1310 (identified as additional/alternative digital pre-distortion circuitry 1361) or in a processor (not shown) of the transceiver 1310. In another example, the digital pre-distortion circuitry may be configured in a distributed manner in both the digital pre-distortion circuitry 1343 of the processor 1304 and the additional/alternative digital pre-distortion circuitry 1361 of the transceiver 1310. The digital pre-distortion circuitry 1343 may be configured to digitally pre-distort a digital signal sent to the digital pre-distortion circuitry 1343 from the communication and processing circuitry 1341 via the bus 1302 and bus interface 1308. The digitally pre-distorted signal may be provided to the digital-to-analog converter 1362. The digital-to-analog converter 1362 may convert the digital pre-distorted signal to a pre-distorted analog signal. The pre-distorted analog signal may be applied to the first mixer 1364. The first mixer 1364 may up-convert the pre-distorted analog signal to a transmission frequency by application of the transmitter side local oscillator 1363. The power amplifier 1365 may amplify the up-converted pre-distorted analog signal output from the first mixer 1364 for transmission via the antenna(s)/antenna array(s) 1314 via the transmit/receive switch 1316. Of course, those persons having ordinary skill in the art will recognize that numerous circuits and functions are omitted from the preceding explanation and the drawing to avoid clutter in the drawings and unnecessary detail in the description of the example.

In some aspects of the disclosure, the transceiver control circuitry 1342 may be configured for various functions, including, for example, configuring the transceiver 1310 to receive parameters associated with other signals (e.g., with reference to FIG. 6A for convenience, receive the NS values) in a second band (e.g., the second band may be the emission band 604) defined by a first frequency (e.g., the emission band lower frequency 620 (A)) and a second frequency (e.g., the emission band upper frequency 622 (B)), greater than the first frequency, the first frequency and the second frequency being outside of the first bandwidth (e.g., the emission band lower frequency 620 (A) and the emission band upper frequency 622 (B) being outside of the first transmission channel bandwidth 609). The other signals may be actual or prospective products of the transmitted signal. The received parameters may be parameters specified in a network signaling case (an NS case). In other words, the network signaling case may specify the parameters associated with the other signals. According to some aspects, the parameters associated with the other signals may correspond to at least one of: a reduction to a preexisting maximum output power level in the second band, a limit to a preexisting level of permissible spurious emissions in the second band, or a change, including an update or an addition, to a preexisting spectral emission mask level covering the second band. In some examples, the network signaling case defines the second band (e.g., the emission band 604) defined by the first frequency and the second frequency (e.g., defined between the emission band lower frequency 620 and the emission band upper frequency 622).

The signaling that conveys the received parameters may be received at a low noise amplifier (LNA) 1366 via the antenna(s)/antenna array(s) 1314 and the transmit/receive switch 1316. The signaling may be down-converted by applying an output of the local oscillator 1363 to the second mixer 1367. The down-converted signaling may be applied to an analog-to-digital converter 1369, which may provide the digital signaling bearing the parameters to, for example, the sampling frequency and DPD sampling rate circuitry 1344 and/or the communication and processing circuitry 1341 via the bus interface 1308 and bus 1302 according to some aspects of the disclosure. x

The transceiver control circuitry 1342 may further be configured to execute transceiver control instructions 1352 (e.g., software) stored, for example, on the computer-readable medium 1306 to implement one or more functions described herein.

In some aspects of the disclosure, the processor 1304 may include the digital pre-distortion circuitry 1343 that may be configured for various functions, including, for example, digitally pre-distorting a signal configured for transmission via the power amplifier 1365 13, as previously explained. The digital pre-distortion circuitry 1343 may further be configured to execute digital pre-distortion circuitry/function instructions 1353 (e.g., software) stored, for example, on the computer-readable medium 1306 to implement one or more functions described herein.

In some aspects of the disclosure, the processor 1304 may include sampling frequency and DPD sampling rate circuitry 1344 configured for various functions, including, for example, determining a first sampling frequency associated with the transmitted signal, determining a first DPD sampling rate based on the first sampling frequency, and changing the first DPD sampling rate to a second DPD sampling rate (greater than the first DPD sampling rate) in response to a third frequency, corresponding to the first center frequency (e.g., the first transmission channel center frequency 626) shifted by the first DPD sampling rate, being outside the second band (e.g., being outside the emission band 604) according to some aspects of the disclosure. In some examples, the sampling frequency and DPD sampling rate circuitry 1344 may be further configured to alternatively maintain the first DPD sampling rate in response to the third frequency being inside the second band (e.g., being inside the emission band 604).

In some examples, the first sampling frequency may be dependent on at least one of: a predefined radio frequency band (e.g., the transmission band 606), a channel center frequency (e.g., the first transmission channel center frequency 626), a channel bandwidth (e.g., the first transmission channel bandwidth 609), operating characteristics of the transmitter (e.g., the transmitter 500 as shown and described in connection with FIG. 5, the transmitter portion of the transceiver 1310 as shown and described in connection with FIG. 13), a value of a starting resource block (sRB) and a number of resource blocks (nRB), a modulation of the transmitted signal, or a type of the transmitted signal. The sampling frequency and DPD sampling rate circuitry 1344 may further be configured to execute sampling frequency and DPD sampling rate instructions 1354 (e.g., software) stored on the computer-readable medium 1306 to implement one or more functions described herein.

According to some aspects, the one or more processors (generally represented by processor 1304) may be further configured to use the DPD sampling rate to train a digital pre-distortion model associated with the transmitted signal. Additionally, or alternatively, the one or more processors may be further configured to dynamically change the DPD sampling rate in response to at least one of: a change of the third frequency, or a change of the second band defined by the first frequency and the second frequency. Additionally, or alternatively, the one or more processors may be further configured to dynamically change from the first DPD sampling rate to the second DPD sampling rate in response to the third frequency shifting from outside to inside the second band. Additionally, or alternatively, one or more processors may be further configured to dynamically change from the second DPD sampling rate to the first DPD sampling rate in response to the third frequency shifting from inside to outside the second band (and far enough away from an upper or lower frequency of the second band not to warrant immediate change back to the second DPD sampling rate).

Of course, persons having ordinary skill in the art will recognize that numerous circuits and functions are omitted from the preceding explanation and the drawing of FIG. 13 to avoid clutter in the drawing and unnecessary detail in the description of the example.

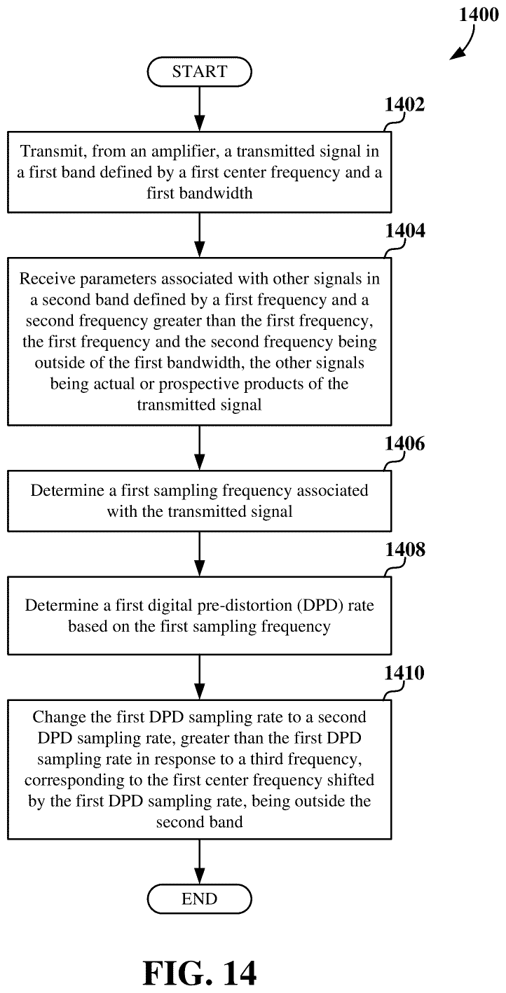

FIG. 14 is a flow chart illustrating an example process 1400 (e.g., a method) of wireless communication at an apparatus (e.g., a UE, a scheduled entity, a sidelink UE) in accordance with some aspects of the disclosure. As described below, some or all illustrated features may be omitted in a particular implementation within the scope of the present disclosure, and some illustrated features may not be required for implementation of all embodiments. In some examples, the process 1400 may be carried out by the apparatus 1300, as shown and described in connection with FIG. 13. The apparatus 1300 may be similar to, for example, any of the scheduled entities of FIGS. 1, 2, 12, and/or 13. In some examples, the process 1400 may be carried out by any suitable apparatus or means for carrying out the functions or algorithm described below.

At block 1402, the apparatus may transmit, from an amplifier (e.g., a power amplifier), a transmitted signal in a first band defined by a first center frequency and a first bandwidth. In other words, using FIG. 6A for convenience and not limitation, the apparatus may transmit, from the amplifier, the transmitted signal in a first transmission channel 608 defined by a first transmission channel center frequency 626 (X) and a first transmission channel bandwidth 609. For example, the transceiver control circuitry 1342, in combination with the power amplifier 1365 of the transceiver 1310, as shown and described in connection with FIG. 13, may provide a means for transmitting from an amplifier (e.g., a power amplifier), a transmitted signal in a first band defined by a first center frequency and a first bandwidth. In some examples, the first band may be a channel in a predefined radio frequency band. In some examples, a channel center frequency and a channel bandwidth may define the channel. According to some aspects, the first band may be a first channel among a plurality of channels in a predefined radio frequency band, the first center frequency and the first bandwidth may correspond to a first channel center frequency and a first channel bandwidth, and the one or more processors of the apparatus may be configured to make the change (to the DPD sampling rate) in association with the first channel, as distinct from the plurality of channels.

At block 1404, the apparatus may receive parameters associated with other signals in a second band defined by a first frequency and a second frequency, greater than the first frequency, the first frequency and the second frequency being outside of the first bandwidth, the other signals being actual or prospective products of the transmitted signal. In other words, using FIG. 6A for convenience and not limitation, the apparatus may receive parameters associated with other signals (e.g., receive the NS values) in a second band (e.g., an emission band 604) defined between and including the emission band lower frequency 620 and the emission band upper frequency 622, greater than the emission band lower frequency 620. The emission band lower frequency 620 (e.g., the first frequency) and the emission band upper frequency 622 (e.g., the second frequency) being outside of the first transmission channel bandwidth 609. The other signals being actual or prospective products of the transmitted signal. For example, the communication and processing circuitry 1341 and/or the transceiver control circuitry 1342 in combination with the transceiver 1310, as shown and described in connection with FIG. 13, may provide a means for receiving parameters associated with other signals in a second band defined by a first frequency and a second frequency greater than the first frequency, the first frequency and the second frequency being outside of the first bandwidth, the other signals being actual or prospective products of the transmitted signal. According to some aspects, a network signaling case specifies the parameters associated with the other signals. In some examples, a network signaling case may define the second band defined by the first frequency and the second frequency. According to some aspects, the parameters associated with the other signals may correspond to at least one of: a reduction to a preexisting maximum output power level in the second band, a limit to a preexisting level of permissible spurious emissions in the second band, or a change, including an update or an addition, to a preexisting spectral emission mask level covering the second band.

At block 1406, the apparatus may determine a first sampling frequency associated with the transmitted signal. For example, the sampling frequency and DPD sampling rate circuitry 1344, as shown and described in connection with FIG. 13, may provide a means for determining a first sampling frequency associated with the transmitted signal. According to some aspects, the first sampling frequency may be dependent on at least one of: a predefined radio frequency band, a channel center frequency, a channel bandwidth, and operating characteristics of the transmitter (e.g., the transmitter 500 as shown and described in connection with FIG. 5), a value of a starting resource block (sRB) and a number of resource blocks (nRB), a modulation of the transmitted signal, and a type of the transmitted signal.

At block 1408, the apparatus may determine a first digital pre-distortion (DPD) sampling rate based on the first sampling frequency. For example, the sampling frequency and DPD sampling rate circuitry 1344, as shown and described in connection with FIG. 13, may provide a means for determining a first digital pre-distortion (DPD) sampling rate based on the first sampling frequency.

At block 1410, the apparatus may change the first DPD sampling rate to a second DPD sampling rate, greater than the first DPD sampling rate in response to a third frequency, corresponding to the first center frequency shifted by the first DPD sampling rate, being outside the second band. In other words, using FIG. 6B for convenience and not limitation, the apparatus may change the first DPD sampling rate 630 to a second DPD sampling rate (not shown), greater than the first DPD sampling rate 630 in response to a spaced-apart frequency 627 (Y) (e.g., the third frequency) corresponding to the first transmission channel center frequency 626 (X) (e.g., the first center frequency) shifted by the first DPD sampling rate 630 (e.g., Y=X−|DPD sampling rate|), being outside the emission band 604 (e.g., outside of the second band). For example, the sampling frequency and DPD sampling rate circuitry 1344, as shown and described in connection with FIG. 13, may provide a means for changing the first DPD sampling rate to a second DPD sampling rate greater than the first DPD sampling rate in response to a third frequency, corresponding to the first center frequency shifted by the first DPD sampling rate, being outside the second band. According to some aspects, that apparatus may alternatively maintain the first DPD sampling rate in response to the third frequency being inside the second band.

In one example, the apparatus may be configured to use the DPD sampling rate to train a digital pre-distortion model associated with the transmitted signal. In one example, the apparatus may be configured to dynamically change the DPD sampling rate in response to at least one of: a change of the third frequency (e.g., a change of the spaced-apart frequency 627 (Y)), or a change of the second band defined by the first frequency and the second frequency (e.g., a change of the emission band 604 defined between and including the emission band lower frequency 620 (A) and the emission band upper frequency 622 (B), greater than the emission band lower frequency 620 (A)). In one example, that apparatus may be configured to dynamically change from the first DPD sampling rate to the second DPD sampling rate, greater than the first DPD sampling rate, to cause the third frequency to shift from outside to inside the second band (e.g., to cause the spaced-apart frequency 627 (Y) to shift from outside of the emission band 604 to inside the emission band 604). The apparatus may still be further configured to dynamically change from the second DPD sampling rate to the first DPD sampling rate, less than the second DPD sampling rate) to cause the third frequency (e.g., the spaced-apart frequency) to shift from the inside to the outside of the second band (e.g., the emission band). After block 1410, the process 1400 may end.

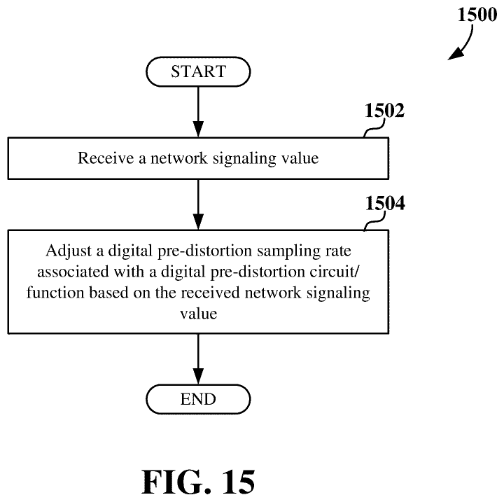

FIG. 15 is a flow chart illustrating an example process 1500 (e.g., a method) of wireless communication at an apparatus (e.g., a UE, a scheduled entity, a sidelink UE) in accordance with some aspects of the disclosure. Examples below may be provided with reference to FIG. 6A for convenience and not limitation. As described below, some or all illustrated features may be omitted in a particular implementation within the scope of the present disclosure, and some illustrated features may not be required for implementation of all embodiments. In some examples, the process 1500 may be carried out by the apparatus 1300, as shown and described in connection with FIG. 13. The apparatus 1300 may be similar to, for example, any of the scheduled entities of FIGS. 1, 2, 12, and/or 13. In some examples, the process 1500 may be carried out by any suitable apparatus or means for carrying out the functions or algorithm described below.

According to some aspects, the apparatus may include a digital pre-distortion circuit/function configured to provide one or more signals to an amplifier (e.g., a power amplifier). For example, the digital pre-distortion circuit/function 408, 520, 1218, the digital pre-distortion circuitry 1343, and/or the additional/alternative digital pre-distortion circuitry 1361, as variously shown and described in connection with FIGS. 4, 5, 12, and 13 may provide a means for providing one or more digitally pre-distorted signals to an amplifier.

At block 1502, the apparatus may receive a network signaling value. For example, the antenna array(s) 1314, in combination with the transmit/receive switch 1316, the LNA 1366, the second mixer 1367, the analog-to-digital converter 1369, and the modem 1360 as shown and described in connection with FIG. 13, may provide a means for receiving a network signaling value. The network signaling value may be similar to any of the network signaling values exemplified herein, including NS_43, NS_43U, NS_17, NS_XX, and Tables 1, 2, and 3. According to some aspects, the apparatus may receive the network signaling value from a network entity. In some examples, the network signaling value may be indicative of one or more transmission constraints associated with a network of the network entity. In some examples, the network signaling value may include information indicative of a constraint on emissions required by a network.

At block 1504, the apparatus may adjust a digital pre-distortion (DPD) sampling rate associated with a digital pre-distortion circuit/function based at least on the received network signaling value. Alternatively, the apparatus may adjust the DPD sampling rate in response to the network signaling value or in response to receiving the network signaling value. For example, the adjustment may be similar to any of the adjustments described and shown in connection with FIGS. 6A, 6B, 7A, 7B, 10, 11A, and/or 11B. By way of example, the one or more processors 1204, as shown and described in connection with FIG. 12, or the communication and processing circuitry 1341, as shown and described in connection with FIG. 13, may provide a means for adjusting a digital pre-distortion (DPD) sampling rate associated with a digital pre-distortion circuit/function based at least on the received network signaling value, or in response to the network signaling value, or in response to receiving the network signaling value. Thereafter, the process 1500 may end.

In one example, the apparatus may apply digital pre-distortion to one or more signals sampled at the adjusted DPD sampling rate utilizing the digital pre-distortion circuit. By way of example, the digital pre-distortion circuitry 1343 and/or the additional/alternative digital pre-distortion circuitry 1361, as shown and described in connection with FIG. 13, may provide a means for applying digital pre-distortion to one or more signals sampled at the adjusted DPD sampling rate utilizing the digital pre-distortion circuit.

According to some aspects, the network signaling value may be indicative of a predetermined second band (e.g., the emission band 604 (FIG. 6A)) spaced apart in frequency from a predetermined center frequency (e.g., a first transmission channel center frequency 626 given as X (FIG. 6A)). The network signaling value may be scheduled to the apparatus for a predetermined time (e.g., for a predetermined duration).

In some examples, the apparatus may increase the DPD sampling rate from a first DPD sampling rate to a second DPD sampling rate having a greater frequency (e.g., a higher frequency) than the first DPD sampling rate in response to a difference in frequency between the predetermined center frequency and a band edge of the second band (e.g., a difference in frequency between the first transmission channel center frequency 626 (X) and a closest one, relative to the first transmission channel center frequency 626 (X), of an emission band lower frequency 620 (A) or an emission band upper frequency 622 (B) of the emission band 604 of FIG. 6A) being greater than the first DPD sampling rate. According to some aspects, the apparatus may increase the DPD sampling rate from a first DPD sampling rate to a second DPD sampling rate in response to configuring the apparatus with the network signaling value and at least one transmission characteristic that match a stored network signaling value and an associated stored transmission characteristic, respectively. Once the network signaling value is no longer scheduled (e.g., because the time to utilize the scheduled network signaling value has expired), the apparatus may decrease the DPD sampling rate from the second DPD sampling rate to the first DPD sampling rate or any other DPD sampling rate based on the configuration of the transmitted signal (e.g., based on sampling frequency, transmission channel center frequency, and/or transmission channel bandwidth). In other words, and by way of example, once the network signaling value is no longer scheduled, the apparatus maybe configured to change the DPD sampling rate from the second DPD sampling rate to a third DPD sampling rate in response reconfiguring the apparatus to eliminate the match with the stored network signaling value and the associated stored transmission characteristic, respectively, wherein the third DPD sampling rate may be equal to the first DPD sampling rate or another DPD sampling rate different from the first DPD sampling rate and the second DPD sampling rate.

According to some aspects, the adjusting the DPD sampling rate associated with the digital pre-distortion circuit may be in response to the network signaling value being associated with at least one configured characteristic of the apparatus. For example, the at least one configured characteristic may include at least one of: a transmission band, a transmission channel center frequency, a transmission channel bandwidth, a transmission channel identifier, an operating characteristic of one or more transmitters coupled to one or more processors of the apparatus, a value of a starting resource block and a number of resource blocks, a modulation of a transmitted signal, or a type of the transmitted signal. In some examples, the transmission channel identifier may be at least one of: a center frequency, a frequency band defined between a lower channel frequency and an upper channel frequency, an absolute radio frequency channel number (ARFCN), a new radio ARFCN (NR-ARFCN), or a global synchronization channel number (GSCN).

Using FIG. 6A for purposes of explanation and not limitation, according to some aspects, the adjusting the DPD sampling rate 630 may be based on a position of a transmission channel center frequency 626 (X) within a transmission band 606 relative to an emission band edge (e.g., the emission band upper frequency 622 (B)) defined by the network signaling value. Alternatively, the apparatus may be configured to transmit a signal sampled at the DPD sampling rate in a transmission channel (e.g., the first transmission channel 608 having a first transmission channel center frequency 626) and adjust the DPD sampling rate based on a distance between the transmission channel center frequency and a closest one, relative to the transmission channel center frequency, of an emission band lower frequency and an emission band upper frequency defined by the network signaling value.

According to some aspects, the method may further include, or the adjusting the DPD sampling rate may further include, increasing the DPD sampling rate in response to a transmission channel center frequency being within a threshold distance of an emission band edge. By way of example, the digital pre-distortion circuitry 1343 and/or the additional/alternative digital pre-distortion circuitry 1361, as shown and described in connection with FIG. 13, may provide a means for increasing the DPD sampling rate in response to a transmission channel center frequency being within a threshold distance of an emission band edge.

According to some aspects, the method may further include applying, at the digital pre-distortion circuit, digital pre-distortion to a digital signal sampled at the adjusted DPD sampling rate, converting the digitally pre-distorted digital signal to an analog signal, upconverting, in frequency, the analog signal, and inputting the upconverted analog signal to a power amplifier configured to transmit at a transmission channel center frequency within the transmission channel bandwidth. In some examples, the power amplifier may have a non-linear transfer function, and an output of the power amplifier may be linearized by the digital pre-distortion applied to the digital signal sampled at the adjusted DPD sampling rate. By way of example, the digital pre-distortion circuitry 1343 and/or the additional/alternative digital pre-distortion circuitry 1361, as shown and described in connection with FIG. 13, may provide a means for applying, at the digital pre-distortion circuit, digital pre-distortion to a digital signal sampled at the adjusted DPD sampling rate. Furthermore, and still by way of example, the digital-to-analog converter 1362, as shown and described in connection with FIG. 13, may provide a means for converting the digitally pre-distorted digital signal to an analog signal. Furthermore, and still by way of example, the first mixer 1364, as shown and described in connection with FIG. 13, may provide a means for upconverting, in frequency, the analog signal. Furthermore, and still by way of example, the communication and processing circuitry 1341, in cooperation with the transceiver control circuitry 1342, the sampling frequency and DPD sampling rate circuitry 1344, and the power amplifier 1365, as shown and described in connection with FIG. 13, may provide a means for inputting the upconverted analog signal to a power amplifier configured to transmit at a transmission channel center frequency within the transmission channel bandwidth.

According to some aspects, the method may further include maintaining, in one or more memories, a table of a plurality of tabulated network signaling values and associated transmission characteristics, and still further include adjusting the DPD sampling rate associated with the digital pre-distortion circuit in response to matching the network signaling value and an associated configured transmission characteristic to one of the plurality of tabulated network signaling values and associated transmission characteristics, respectively. By way of example, the memory 1305, including the multidimensional table 1315 in cooperation with the digital pre-distortion circuitry 1343 and/or the additional/alternative digital pre-distortion circuitry 1361, and still further in cooperation with the sampling frequency and DPD sampling rate circuitry 1344, may provide a means for maintaining, in one or more memories, a table of a plurality of tabulated network signaling values and associated transmission characteristics, and still further include adjusting the DPD sampling rate associated with the digital pre-distortion circuit in response to matching the network signaling value and an associated configured transmission characteristic to one of the plurality of tabulated network signaling values and associated transmission characteristics, respectively.

According to some aspects, the method may further include increasing the DPD sampling rate from a first DPD sampling rate to a second DPD sampling rate in response to configuring the apparatus with the network signaling value and at least one transmission characteristic to match a stored network signaling value and an associated stored transmission characteristic, respectively. The method may still further include changing the DPD sampling rate from the second DPD sampling rate to a third DPD sampling rate in response to reconfiguring the apparatus to eliminate the match with the stored network signaling value and the associated stored transmission characteristic, respectively, where the third DPD sampling rate may be equal to the first DPD sampling rate or another DPD sampling rate different from the first DPD sampling rate and the second DPD sampling rate. By way of example, the memory 1305 including the multidimensional table 1315 in cooperation with the digital pre-distortion circuitry 1343 and/or the additional/alternative digital pre-distortion circuitry 1361, and still further in cooperation with the sampling frequency and DPD sampling rate circuitry 1344, may provide a means for increasing the DPD sampling rate from a first DPD sampling rate to a second DPD sampling rate in response to configuring the apparatus with the network signaling value and at least one transmission characteristic to match a stored network signaling value and an associated stored transmission characteristic, respectively, and the method may still further include changing the DPD sampling rate from the second DPD sampling rate to a third DPD sampling rate in response reconfiguring the apparatus to eliminate the match with the stored network signaling value and the associated stored transmission characteristic, respectively, where the third DPD sampling rate may be equal to the first DPD sampling rate or another DPD sampling rate different from the first DPD sampling rate and the second DPD sampling rate

According to some aspects, the method may include configuring a transmission channel having a first transmission channel band edge and a second transmission channel band edge, spaced apart from the first transmission channel band edge by a transmission channel bandwidth, and defining, based on the network signaling value, a first emission band edge proximal to the first transmission channel band edge and a second emission band edge distal from the first transmission channel band edge, and adjusting the DPD sampling rate associated with the digital pre-distortion circuit in response to the first transmission channel band edge being spaced-apart from the first emission band edge by less than a predetermined frequency separation. By way of example, the transceiver control circuitry 1342, in cooperation with the digital pre-distortion circuitry 1343 and/or the additional/alternative digital pre-distortion circuitry 1361, and still further in cooperation with the sampling frequency and DPD sampling rate circuitry 1344, may provide a means for configuring a transmission channel having a first transmission channel band edge and a second transmission channel band edge, spaced-apart from the first transmission channel band edge by a transmission channel bandwidth, and defining, based on the network signaling value, a first emission band edge proximal to the first transmission channel band edge and a second emission band edge distal from the first transmission channel band edge, and adjusting the DPD sampling rate associated with the digital pre-distortion circuit in response to the first transmission channel band edge being spaced-apart from the first emission band edge by less than a predetermined frequency separation.

According to some aspects, the method may include configuring a transmission channel having a transmission channel center frequency, and defining, based on the network signaling value, a first emission band edge proximal to the transmission channel center frequency and a second emission band edge distal from the transmission channel center frequency, and adjusting the DPD sampling rate associated with the digital pre-distortion circuit in response to the transmission channel center frequency being separated from the first emission band edge by more than the DPD sampling rate and less than the DPD sampling rate plus a predefined frequency value. By way of example, the transceiver control circuitry 1342, in cooperation with the digital pre-distortion circuitry 1343 and/or the additional/alternative digital pre-distortion circuitry 1361, and still further in cooperation with the sampling frequency and DPD sampling rate circuitry 1344, may provide a means for configuring a transmission channel having a transmission channel center frequency, and defining, based on the network signaling value, a first emission band edge proximal to the transmission channel center frequency and a second emission band edge distal from the transmission channel center frequency, and adjusting the DPD sampling rate associated with the digital pre-distortion circuit in response to the transmission channel center frequency being separated from the first emission band edge by more than the DPD sampling rate and less than the DPD sampling rate plus a predefined frequency value.

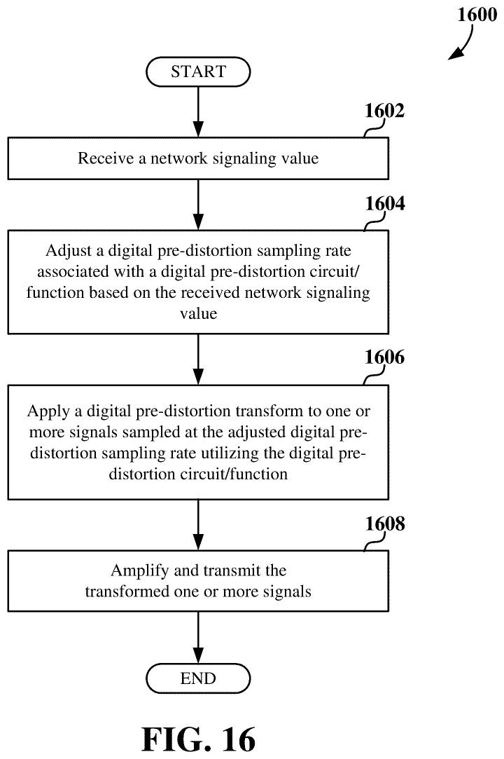

FIG. 16 is a flow chart illustrating an example process 1600 (e.g., a method) of wireless communication at an apparatus (e.g., a UE, a scheduled entity, a sidelink UE) in accordance with some aspects of the disclosure. As described below, some or all illustrated features may be omitted in a particular implementation within the scope of the present disclosure, and some illustrated features may not be required for implementation of all embodiments. In some examples, the process 1600 may be carried out by the apparatus 1300, as shown and described in connection with FIG. 13. The apparatus 1300 may be similar to, for example, any of the scheduled entities of FIGS. 1, 2, 12, and/or 13. In some examples, the process 1600 may be carried out by any suitable apparatus or means for carrying out the functions or algorithm described below.

At block 1602, the apparatus may receive a network signaling value. For example, the antenna array(s) 1314, in combination with the transmit/receive switch 1316, the LNA 1366, the second mixer 1367, and the analog-to-digital converter 1369, as shown and described in connection with FIG. 13, may provide a means for receiving a network signaling value. The network signaling value may be similar to any of the network signaling values exemplified herein, including NS_43, NS_43U, NS_17, NS_XX.

At block 1604, the apparatus may adjust a digital pre-distortion (DPD) sampling rate associated with a digital pre-distortion circuit/function based at least on the received network signaling value. For example, the adjustment may be similar to any of the adjustments described and shown in connection with FIGS. 6A, 6B, 7A, 7B, 10, 11A, and/or 11B. By way of example, the one or more processors 1204, as shown and described in connection with FIG. 12, or the communication and processing circuitry 1341, as shown and described in connection with FIG. 13 may provide a means for adjusting a digital pre-distortion (DPD) sampling rate associated with a digital pre-distortion circuit/function based at least on the received network signaling value.

At block 1606, the apparatus may apply digital pre-distortion to one or more signals sampled at the adjusted DPD sampling rate utilizing the digital pre-distortion circuit/function. For example, the digital pre-distortion circuit/function 1218, as shown and described in connection with FIG. 12 or the digital pre-distortion circuitry 1343 and/or the additional/alternative digital pre-distortion circuitry 1361, as shown and described in connection with FIG. 13, may provide a means for applying digital pre-distortion to one or more signals sampled at the adjusted DPD sampling rate utilizing the digital pre-distortion circuit/function.

At block 1608, the apparatus may amplify the transformed one or more signals. For example, the power amplifier 1224, as shown and described in connection with FIG. 12 or the power amplifier 1365, as shown and described in connection with FIG. 13, may provide a means for amplifying the transformed one or more signals.

Thereafter, the process 1600 may end. Of course, prior to the ending, the apparatus may transmit the amplified transformed one or more signals via, for example, the antenna or antenna array 1226, as shown and described in connection with FIG. 12, or the antenna array(s) 1314, as shown and described in connection with FIG. 13.

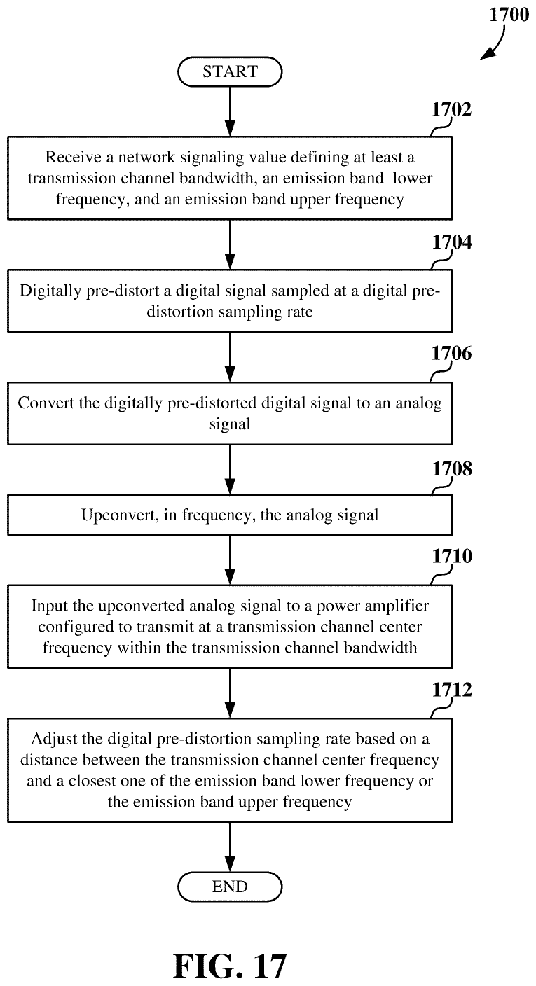

FIG. 17 is a flow chart illustrating an example process 1700 (e.g., a method) of wireless communication at an apparatus (e.g., a UE, a scheduled entity, a sidelink UE) in accordance with some aspects of the disclosure. As described below, some or all illustrated features may be omitted in a particular implementation within the scope of the present disclosure, and some illustrated features may not be required for implementation of all embodiments. In some examples, the process 1700 may be carried out by the apparatus 1300, as shown and described in connection with FIG. 13. The apparatus 1300 may be similar to, for example, any of the scheduled entities of FIGS. 1, 2, 12, and/or 13. In some examples, the process 1700 may be carried out by any suitable apparatus or means for carrying out the functions or algorithm described below.

At block 1702, the apparatus may receive a network signaling value defining at least a transmission channel bandwidth, an emission band lower frequency, and an emission band upper frequency. By way of example, the transceiver 1310, in association with the antenna array(s) 1314 and the transmit/receive switch 1316, as shown and described in connection with FIG. 13, may provide a means for receiving a network signaling value defining at least a transmission channel bandwidth, an emission band lower frequency, and an emission band upper frequency.

At block 1704, the apparatus may digitally pre-distort a digital signal sampled at a DPD sampling rate. By way of example, the digital pre-distortion circuitry 1343 and/or the additional/alternative digital pre-distortion circuitry 1361, as shown and described in connection with FIG. 13, may provide a means for digitally pre-distorting a digital signal sampled at a DPD sampling rate.

At block 1706, the apparatus may convert the digitally pre-distorted digital signal to an analog signal. By way of example, the digital-to-analog converter 1362, as shown and described in connection with FIG. 13, may provide a means for converting the digitally pre-distorted digital signal to an analog signal.

At block 1708, the apparatus may upconvert, in frequency, the analog signal. By way of example, the first mixer 1364, as shown and described in connection with FIG. 13, may provide a means for upconverting, in frequency, the analog signal.

At block 1710, the apparatus may input (e.g., apply) the upconverted analog signal to a power amplifier configured to transmit at a transmission channel center frequency within the transmission channel bandwidth. According to some examples, the power amplifier described in connection with block 1710 may operate, at least partially, in a non-linear region, an output of the power amplifier being linearized with respect to an input by the digital pre-distortion applied to the digital signal sampled at the adjusted DPD sampling rate. The scope of the disclosure encompasses all amplifiers, including power amplifiers. The scope of the disclosure encompasses amplifiers operating within both linear and non-linear regions of the transfer characteristics/functions of the amplifiers. For example, the communication and processing circuitry 1341, in cooperation with the transceiver control circuitry 1342, the sampling frequency and DPD sampling rate circuitry 1344, and the power amplifier 1365, as shown and described in connection with FIG. 13, may provide a means for inputting (e.g., applying) the upconverted analog signal to a power amplifier configured to transmit at a transmission channel center frequency within the transmission channel bandwidth.

At block 1712, the apparatus may adjust the DPD sampling rate based on a distance between the transmission channel center frequency and a closest one (relative to the transmission channel center frequency) of the emission band lower frequency and the emission band upper frequency (defined by the network signaling value). By way of example, the transceiver control circuitry 1342, the digital pre-distortion circuitry 1343, and/or the additional/alternative digital pre-distortion circuitry 1361, in cooperation with the sampling frequency and DPD sampling rate circuitry 1344, as shown and described in connection with FIG. 13, may provide a means for adjusting the DPD sampling rate based on a distance between the transmission channel center frequency and a closest one of the emission band lower frequency or the emission band upper frequency. Thereafter, the process 1700 may end.

According to some aspects, to adjust the DPD sampling rate based on the distance, the apparatus may be configured to one of: increase the DPD sampling rate in response to the DPD sampling rate being less than the distance; maintain the DPD sampling rate in response to the DPD sampling rate being greater than the distance; maintain the DPD sampling rate in response to the DPD sampling rate being less than the distance and the DPD sampling rate plus a margin being less than the distance; and increase the DPD sampling rate in response to the DPD sampling rate being less than the distance and the DPD sampling rate plus the margin being greater than the distance.

According to some aspects, adjusting the DPD sampling rate based on the distance may be done in response to matching the network signaling value and an associated configured transmission characteristic to one of the plurality of tabulated network signaling values and associated transmission characteristics, respectively.

According to some aspects, the apparatus may be configured to increase the DPD sampling rate from a first DPD sampling rate to a second DPD sampling rate in response to configuring the apparatus with the network signaling value and at least one transmission characteristic that match a stored network signaling value and an associated stored transmission characteristic, respectively, and change the DPD sampling rate from the second DPD sampling rate to a third DPD sampling rate in response reconfiguring the apparatus to eliminate the match with the stored network signaling value and the associated stored transmission characteristic, respectively, wherein the third DPD sampling rate may be equal to the first DPD sampling rate or another DPD sampling rate different from the first DPD sampling rate and the second DPD sampling rate.

According to some aspects, the apparatus may configure the transmission channel having the transmission channel center frequency. The apparatus may also define, based on the network signaling value, the emission band between the emission band lower frequency and the emission band upper frequency, greater than the emission band lower frequency. The apparatus may adjust the DPD sampling rate based on the distance by being further configured to increase or maintain the DPD sampling rate (i.e., one of increase and maintain). In some examples, increasing the DPD sampling rate may be in response to a first value corresponding to the DPD sampling rate being less than a second value corresponding to a distance between the transmission channel center frequency and a closest one, relative to the transmission channel center frequency, of the emission band lower frequency or the emission band upper frequency. In some examples, maintaining the DPD sampling rate may be done in response to the first value being greater than the second value.

According to some aspects, the apparatus may configure the transmission channel having the transmission channel center frequency and define, based on the network signaling value, the emission band between the emission band lower frequency and the emission band upper frequency, greater than the emission band lower frequency. According to such aspects, the apparatus may adjust the DPD sampling rate (associated with the digital pre-distortion circuit) based on the DPD sampling rate and the distance between the transmission channel center frequency and a closest one (relative to the transmission channel center frequency) of the emission band lower frequency or the emission band upper frequency.

According to some aspects, adjusting the DPD sampling rate may be in response to matching the network signaling value and the transmission channel bandwidth to a stored network signaling value and an associated stored transmission channel bandwidth, respectively, and further in response to the distance being more than the DPD sampling rate and less than the DPD sampling rate plus a margin (e.g., a predefined frequency span, or value of frequency). In some examples, the apparatus may maintain, in the one or more memories, a table of a plurality of tabulated network signaling values and associated transmission characteristics, where the stored network signaling value and the associated stored transmission channel bandwidth are included in the table.

According to some aspects, to adjust the DPD sampling rate, the apparatus may be configured to increase or maintain the DPD sampling rate (i.e., one of increase and maintain the DPD sampling rate). Increasing the DPD sampling rate may be in response to matching the network signaling value and the transmission channel bandwidth to a stored network signaling value and an associated stored transmission channel bandwidth, respectively, and in response to the distance being more than the DPD sampling rate and less than the DPD sampling rate plus a margin. Maintaining the DPD sampling rate may be in response to one of: the network signaling value and the transmission channel bandwidth failing to match the stored network signaling value and the associated stored transmission channel bandwidth, respectively; the distance being less than the DPD sampling rate; or the distance being more than the DPD sampling rate plus the margin.

In some examples, implementing adjustments to the DPD sampling rate, such as the adjustments described herein, may cause the apparatus to transmit, via the power amplifier, a linearized representation of the digitally pre-distorted digital signal sampled at an increased DPD sampling rate within the transmission channel bandwidth and transmit, within an emission band defined between the emission band lower frequency (or lower edge) and the emission band upper frequency (or upper edge), emissions constrained according to limits defined by the network signaling value. In some examples, the DPD sampling rate may additionally be determined based on at least one of: a transmission band, the transmission channel center frequency, the transmission channel bandwidth, a transmission channel identifier, an operating characteristic of one or more transmitters coupled to the one or more processors of the apparatus, a value of a starting resource block and a number of resource blocks, a modulation of a transmitted signal, or a type of the transmitted signal.

According to some aspects, in connection with each of the exemplary processes of FIGS. 14, 15, 16, and 17, the apparatus may include a digital pre-distortion circuit/function configured to provide one or more signals to an amplifier (e.g., a power amplifier). For example, the digital pre-distortion circuit/function 408, 520, 1218, and the digital pre-distortion circuitry 1343 and/or additional/alternative digital pre-distortion circuitry 1361 as variously shown and described in connection with FIGS. 4, 5, 12, and 13 may provide a means for providing one or more digitally pre-distorted signals to an amplifier.

Of course, in the above examples, the circuitry included in the processing circuit 514 of FIG. 5, the one or more processors 1204 of FIG. 12, and the processor 1304 of FIG. 13 are merely provided as examples. Other means for carrying out the described processes or functions may be included within various aspects of the present disclosure, including but not limited to the instructions stored in the one or more memories 1205 and/or one or more computer-readable media 1206 of FIG. 12 and the memory 1305 and/or computer-readable medium 1306 of FIG. 13, or any other suitable apparatus or means described in any one of the FIGS. 1, 2, 4A, 4B, 5, 12, and/or 13 utilizing, for example, the processes and/or algorithms described herein in relation to FIGS. 4A, 4B, 5, 6A, 6B, 7A, 7B, 10, 11A, 11B, 12, 13, 14, 15, 16, and/or 17.

The following provides an overview of aspects of the present disclosure:

Aspect 1: An apparatus, comprising: one or more transmitters; one or more memories; and one or more processors coupled to the one or more transmitters and the one or more memories, the one or more processors being configured to, individually or collectively, based at least in part on information stored in the one or more memories: transmit, from the one or more transmitters, a transmitted signal in a first band defined by a first center frequency and a first bandwidth, receive parameters associated with other signals in a second band defined by a first frequency and a second frequency greater than the first frequency, the first frequency and the second frequency being outside of the first bandwidth, the other signals being actual or prospective products of the transmitted signal, determine a first sampling frequency associated with the transmitted signal, determine a first digital pre-distortion (DPD) sampling rate based on the first sampling frequency, and change the first DPD sampling rate to a second DPD sampling rate, greater than the first DPD sampling rate in response to a third frequency, corresponding to the first center frequency shifted by the first DPD sampling rate, being outside the second band.

Aspect 2: The apparatus of aspect 1, wherein the one or more processors are further configured to: alternatively maintain the first DPD sampling rate in response to the third frequency being inside the second band.

Aspect 3: The apparatus of aspect 1 or aspect 2, wherein the first band is a channel in a predefined radio frequency band.

Aspect 4: The apparatus of aspect 3, wherein a channel center frequency and a channel bandwidth define the channel.

Aspect 5: The apparatus of any of aspects 1 through 4, wherein the first band is a first channel among a plurality of channels in a predefined radio frequency band, the first center frequency and the first bandwidth correspond to a first channel center frequency and a first channel bandwidth, and the one or more processors are further configured to make the change in association with the first channel, as distinct from the plurality of channels.

Aspect 6: The apparatus of any of aspects 1 through 5, wherein the first sampling frequency is dependent on at least one of: a predefined radio frequency band, a channel center frequency, a channel bandwidth, operating characteristics of the one or more transmitters, a value of a starting resource block (sRB) and a number of resource blocks (nRB), a modulation of the transmitted signal, or a type of the transmitted signal.

Aspect 7: The apparatus of any of aspects 1 through 6, wherein a network signaling case specifies the parameters associated with the other signals.

Aspect 8: The apparatus of any of aspects 1 through 7, wherein a network signaling case defines the second band defined by the first frequency and the second frequency.

Aspect 9: The apparatus of any of aspects 1 through 8, wherein the parameters associated with the other signals correspond to at least one of: a reduction to a preexisting maximum output power level in the second band, a limit to a preexisting level of permissible spurious emissions in the second band, or a change, including an update or an addition, to a preexisting spectral emission mask level covering the second band.

Aspect 10: The apparatus of any of aspects 1 through 9, wherein the one or more processors are further configured to use the first DPD sampling rate to train a DPD model associated with the transmitted signal.

Aspect 11: The apparatus of any of aspects 1 through 10, wherein the one or more processors are further configured to dynamically change the first DPD sampling rate in response to at least one of: a change of the third frequency, or a change of the second band defined by the first frequency and the second frequency.

Aspect 12: The apparatus of any of aspects 1 through 11, wherein the one or more processors are further configured to dynamically change from the first DPD sampling rate to the second DPD sampling rate, in response to the third frequency shifting from inside to outside the second band.

Aspect 13: The apparatus of aspect 12, wherein the one or more processors are further configured to dynamically change from the second DPD sampling rate to the first DPD sampling rate, in response to the third frequency shifting from outside to inside the second band.

Aspect 14: An apparatus, comprising: one or more memories; and one or more processors coupled to the one or more memories, the one or more processors being configured to, individually or collectively, based at least in part on information stored in the one or more memories: receive a network signaling value, and adjust a DPD sampling rate associated with a digital pre-distortion circuit based on the received network signaling value.

Aspect 15: The apparatus of aspect 14, wherein the one or more processors are further configured to receive the network signaling value from a network entity.

Aspect 16: The apparatus of aspect 15, wherein the network signaling value is indicative of one or more transmission constraints associated with a network of the network entity.

Aspect 17. The apparatus of any of aspects 14 through 16, wherein the one or more processors are further configured to apply digital pre-distortion to one or more signals sampled at the adjusted DPD sampling rate utilizing the digital pre-distortion circuit.

Aspect 18: The apparatus of any of aspects 14 through 17, wherein the network signaling value is indicative of a predetermined second band spaced apart in frequency from a predetermined center frequency, and the one or more processors are further configured to: increase the DPD sampling rate from a first DPD sampling rate to a second DPD sampling rate having a greater frequency than the first DPD sampling rate in response to a difference in frequency between the predetermined center frequency and a band edge of the predetermined second band being greater than the first DPD sampling rate.

Aspect 19: An apparatus, comprising: means for receiving a network signaling value, and means for adjusting a DPD sampling rate associated with a digital pre-distortion circuit based on the received network signaling value.

Aspect 20: The apparatus of aspect 19, wherein the network signaling value is indicative of a predetermined second band spaced apart in frequency from a predetermined center frequency, and the apparatus further comprises: means for increasing the DPD sampling rate from a first DPD sampling rate to a second DPD sampling rate having a greater frequency than the first DPD sampling rate in response to a difference in frequency between the predetermined center frequency and a band edge of the predetermined second band being greater than the first DPD sampling rate.

Aspect 21: An apparatus, comprising: one or more memories; and one or more processors coupled to the one or more memories, the one or more processors being configured to, individually or collectively, based at least in part on information stored in the one or more memories: receive a network signaling value, and adjust a digital pre-distortion (DPD) sampling rate associated with a digital pre-distortion circuit in response to the network signaling value.

Aspect 22: The apparatus of aspect 21, wherein the network signaling value includes information indicative of a constraint on emissions required by a network.

Aspect 23: The apparatus of aspect 21 or aspect 22, wherein the one or more processors are further configured to: adjust the DPD sampling rate associated with the digital pre-distortion circuit in response to the network signaling value being associated with at least one configured characteristic of the apparatus.

Aspect 24: The apparatus of aspect 23, wherein the at least one configured characteristic includes at least one of: a transmission band, a transmission channel center frequency, a transmission channel bandwidth, a transmission channel identifier, an operating characteristic of one or more transmitters coupled to the one or more processors of the apparatus, a value of a starting resource block and a number of resource blocks, a modulation of a transmitted signal, or a type of the transmitted signal.

Aspect 25: The apparatus of aspect 24, wherein the transmission channel identifier is at least one of: a center frequency, a frequency band defined between a lower channel frequency and an upper channel frequency, an absolute radio frequency channel number (ARFCN), a new radio ARFCN (NR-ARFCN), or a global synchronization channel number (GSCN).

Aspect 26: The apparatus of any of aspects 21 through aspect 25, wherein the one or more processors are further configured to: transmit a signal sampled at the DPD sampling rate in a transmission channel having a transmission channel center frequency; and adjust the DPD sampling rate based on a distance between the transmission channel center frequency and a closest one, relative to the transmission channel center frequency, of an emission band lower frequency and an emission band upper frequency defined by the network signaling value.

Aspect 27: The apparatus of aspect 26, wherein to adjust the DPD sampling rate based on the distance, the one or more processors are further configured to one of: increase the DPD sampling rate in response to the DPD sampling rate being less than the distance, maintain the DPD sampling rate in response to the DPD sampling rate being greater than the distance, maintain the DPD sampling rate in response to the DPD sampling rate being less than the distance and the DPD sampling rate plus a margin being less than the distance, and increase the DPD sampling rate in response to the DPD sampling rate being less than the distance and the DPD sampling rate plus the margin being greater than the distance.

Aspect 28: The apparatus of any of aspects 21 through aspect 27, wherein the one or more processors are further configured to: apply, at the digital pre-distortion circuit, digital pre-distortion to a digital signal sampled at the adjusted DPD sampling rate; convert the digitally pre-distorted digital signal to an analog signal; upconvert, in frequency, the analog signal; and input the upconverted analog signal to a power amplifier, an output of the power amplifier being linearized with respect to the input by the digital pre-distortion applied to the digital signal sampled at the adjusted DPD sampling rate.

Aspect 29: The apparatus of any of aspects 21 through aspect 28, wherein the one or more processors are further configured to: maintain, in the one or more memories, a table of a plurality of tabulated network signaling values and associated transmission characteristics; and adjust the DPD sampling rate associated with the digital pre-distortion circuit in response to matching the network signaling value and an associated configured transmission characteristic to one of the plurality of tabulated network signaling values and associated transmission characteristics, respectively.

Aspect 30: The apparatus of any of aspects 21 through aspect 29, wherein to adjust the DPD sampling rate, the one or more processors are further configured to: increase the DPD sampling rate from a first DPD sampling rate to a second DPD sampling rate in response to configuring the apparatus with the network signaling value and at least one transmission characteristic that match a stored network signaling value and an associated stored transmission characteristic, respectively; and change the DPD sampling rate from the second DPD sampling rate to a third DPD sampling rate in response to reconfiguring the apparatus to eliminate the match with the stored network signaling value and the associated stored transmission characteristic, respectively, wherein the third DPD sampling rate may be equal to the first DPD sampling rate or another DPD sampling rate different from the first DPD sampling rate and the second DPD sampling rate.

Aspect 31: The apparatus of any of aspects 21 through aspect 30, wherein the one or more processors are further configured to: configure a transmission channel having a transmission channel center frequency; define, based on the network signaling value, an emission band between an emission band lower frequency and an emission band upper frequency, greater than the emission band lower frequency; and adjust the DPD sampling rate associated with the digital pre-distortion circuit by being further configured to one of: increase the DPD sampling rate in response to a first value corresponding to the DPD sampling rate being less than a second value corresponding to a distance between the transmission channel center frequency and a closest one, relative to the transmission channel center frequency, of the emission band lower frequency or the emission band upper frequency, and maintain the DPD sampling rate in response to the first value being greater than the second value.

Aspect 32: The apparatus of any of aspects 21 through aspect 31, wherein the one or more processors are further configured to: configure a transmission channel having a transmission channel center frequency; define, based on the network signaling value, an emission band between an emission band lower frequency and an emission band upper frequency, greater than the emission band lower frequency; and adjust the DPD sampling rate associated with the digital pre-distortion circuit based on the DPD sampling rate and a distance between the transmission channel center frequency and a closest one, relative to the transmission channel center frequency, of the emission band lower frequency or the emission band upper frequency.

Aspect 33: A method at an apparatus, comprising: receiving a network signaling value, and adjusting a digital pre-distortion (DPD) sampling rate associated with a digital pre-distortion circuit in response to the network signaling value.

Aspect 34: The method of aspect 33, wherein the network signaling value includes information indicative of a constraint on emissions required by a network.

Aspect 35: The method of aspect 33 or aspect 34, further comprising: adjusting the DPD sampling rate associated with the digital pre-distortion circuit in response to the network signaling value being associated with at least one configured characteristic of the apparatus.

Aspect 36: The method of aspect 35, wherein the at least one configured characteristic includes at least one of: a transmission band, a transmission channel center frequency, a transmission channel bandwidth, a transmission channel identifier, an operating characteristic of one or more transmitters of the apparatus, a value of a starting resource block and a number of resource blocks, a modulation of a transmitted signal, or a type of the transmitted signal.

Aspect 37: The method of aspect 36, wherein the transmission channel identifier is at least one of: a center frequency, a frequency band defined between a lower channel frequency and an upper channel frequency, an absolute radio frequency channel number (ARFCN), a new radio ARFCN (NR-ARFCN), or a global synchronization channel number (GSCN).

Aspect 38: The method of any of aspects 33 through aspect 37, further comprising: transmitting transmit a signal sampled at the DPD sampling rate in a transmission channel having a transmission channel center frequency; and adjusting the DPD sampling rate based on a distance between the transmission channel center frequency and a closest one, relative to the transmission channel center frequency, of an emission band lower frequency and an emission band upper frequency defined by the network signaling value.

Aspect 39: The method of aspect 38, wherein the adjusting the DPD sampling rate based on the distance, further comprises one of: increasing the DPD sampling rate in response to the DPD sampling rate being less than the distance, maintaining the DPD sampling rate in response to the DPD sampling rate being greater than the distance, maintaining the DPD sampling rate in response to the DPD sampling rate being less than the distance and the DPD sampling rate plus a margin being less than the distance, and increasing the DPD sampling rate in response to the DPD sampling rate being less than the distance and the DPD sampling rate plus the margin being greater than the distance.

Aspect 40: The method of any of aspects 33 through aspect 39, further comprising: applying, at the digital pre-distortion circuit, digital pre-distortion to a digital signal sampled at the adjusted DPD sampling rate; converting the digitally pre-distorted digital signal to an analog signal; upconverting, in frequency, the analog signal; and inputting the upconverted analog signal to a power amplifier, an output of the power amplifier being linearized with respect to the input by the digital pre-distortion applied to the digital signal sampled at the adjusted DPD sampling rate.

Aspect 41: The method of aspect 33, further comprising: maintaining, in the one or more memories, a table of a plurality of tabulated network signaling values and associated transmission characteristics; and adjusting the DPD sampling rate associated with the digital pre-distortion circuit in response to matching the network signaling value and an associated configured transmission characteristic to one of the plurality of tabulated network signaling values and associated transmission characteristics, respectively.

Aspect 42: The method of any of aspects 33 through aspect 41, wherein adjusting the DPD sampling rate further comprises: increasing the DPD sampling rate from a first DPD sampling rate to a second DPD sampling rate in response to configuring the apparatus with the network signaling value and at least one transmission characteristic that match a stored network signaling value and an associated stored transmission characteristic, respectively; and changing the DPD sampling rate from the second DPD sampling rate to a third DPD sampling rate in response to reconfiguring the apparatus to eliminate the match with the stored network signaling value and the associated stored transmission characteristic, respectively, wherein the third DPD sampling rate may be equal to the first DPD sampling rate or another DPD sampling rate different from the first DPD sampling rate and the second DPD sampling rate.

Aspect 43: The method of any of aspects 33 through aspect 42, further comprising: configuring a transmission channel having a transmission channel center frequency; defining, based on the network signaling value, an emission band between an emission band lower frequency and an emission band upper frequency, greater than the emission band lower frequency; and adjusting the DPD sampling rate associated with the digital pre-distortion circuit by one of: increasing the DPD sampling rate in response to a first value corresponding to the DPD sampling rate being less than a second value corresponding to a distance between the transmission channel center frequency and a closest one, relative to the transmission channel center frequency, of the emission band lower frequency or the emission band upper frequency, and maintaining the DPD sampling rate in response to the first value being greater than the second value.

Aspect 44: The method of any of aspects 33 through aspect 43, further comprising: configuring a transmission channel having a transmission channel center frequency; defining, based on the network signaling value, an emission band between an emission band lower frequency and an emission band upper frequency, greater than the emission band lower frequency; and adjusting the DPD sampling rate associated with the digital pre-distortion circuit based on the DPD sampling rate and a distance between the transmission channel center frequency and a closest one, relative to the transmission channel center frequency, of the emission band lower frequency or the emission band upper frequency.

Aspect 45: An apparatus, comprising: one or more memories; and one or more processors coupled to the one or more memories, the one or more processors being configured to, individually or collectively, based at least in part on information stored in the one or more memories: receive a network signaling value defining at least a transmission channel bandwidth, an emission band lower frequency, and an emission band upper frequency, digitally pre-distort a digital signal sampled at a digital pre-distortion (DPD) sampling rate, convert the digitally pre-distorted digital signal to an analog signal, upconvert, in frequency, the analog signal, input the upconverted analog signal to a power amplifier configured to transmit at a transmission channel center frequency within the transmission channel bandwidth, and adjust the DPD sampling rate based on a distance between the transmission channel center frequency and a closest one of the emission band lower frequency or the emission band upper frequency.

Aspect 46: The apparatus of aspect 45, wherein the one or more processors are further configured to: adjust the DPD sampling rate in response to: matching the network signaling value and the transmission channel bandwidth to a stored network signaling value and an associated stored transmission channel bandwidth, respectively, and the distance being more than the DPD sampling rate and less than the DPD sampling rate plus a margin.

Aspect 47: The apparatus of aspect 46, wherein the one or more processors are further configured to: maintain, in the one or more memories, a table of a plurality of tabulated network signaling values and associated transmission characteristics, wherein the stored network signaling value and the associated stored transmission channel bandwidth are included in the table.

Aspect 48: The apparatus of any of aspect 45 through aspect 47, wherein to adjust the DPD sampling rate, the one or more processors are further configured to one of: increase the DPD sampling rate in response to matching the network signaling value and the transmission channel bandwidth to a stored network signaling value and an associated stored transmission channel bandwidth, respectively, and the distance being more than the DPD sampling rate and less than the DPD sampling rate plus a margin, or maintain the DPD sampling rate in response to at least one of: the network signaling value and the transmission channel bandwidth failing to match the stored network signaling value and the associated stored transmission channel bandwidth, respectively, the distance being less than the DPD sampling rate, or the distance being more than the DPD sampling rate plus the margin.

49: The apparatus of any of aspect 45 through aspect 48, wherein the one or more processors are further configured to: transmit, via the power amplifier, a linearized representation of the digitally pre-distorted digital signal sampled at an increased DPD sampling rate within the transmission channel bandwidth and transmit, within an emission band defined between the emission band lower frequency and the emission band upper frequency, emissions constrained according to limits defined by the network signaling value.

Aspect 50: The apparatus of any of aspect 45 through aspect 49, wherein the DPD sampling rate is also based on at least one of: a transmission band, the transmission channel center frequency, the transmission channel bandwidth, a transmission channel identifier, an operating characteristic of one or more transmitters coupled to the one or more processors of the apparatus, a value of a starting resource block and a number of resource blocks, a modulation of a transmitted signal, or a type of the transmitted signal.

Aspect 51: An apparatus configured for wireless communication comprising at least one means for performing a method of any one of aspects 1 through 50.

Aspect 52: A non-transitory computer-readable medium storing computer-executable code, comprising code for causing an apparatus to perform a method of any one of aspects 1 through 50.

Several aspects of a wireless communication network have been presented with reference to an exemplary implementation. As those skilled in the art will readily appreciate, various aspects described throughout this disclosure may be extended to other telecommunication systems, network architectures, and communication standards.

By way of example, various aspects may be implemented within other systems defined by 3GPP, such as Long Term Evolution (LTE), the Evolved Packet System (EPS), the Universal Mobile Telecommunication System (UMTS), and/or the Global System for Mobile (GSM). Various aspects may also be extended to systems defined by the 3rd Generation Partnership Project 2 (3GPP2), such as CDMA 2000 and/or Evolution-Data Optimized (EV-DO). Other examples may be implemented within systems employing IEEE 802.11 (Wi-Fi), IEEE 802.16 (WiMAX), IEEE 802.20, Ultra-Wideband (UWB), Bluetooth, and/or other suitable systems. The actual telecommunication standard, network architecture, and/or communication standard employed will depend on the specific application and the overall design constraints imposed on the system.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B, and object B touches object C, then objects A and C may still be considered coupled to one another-even if they do not directly physically touch each other. For instance, a first object may be coupled to a second object even though the first object is never directly physically in contact with the second object. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features, and/or functions illustrated in FIGS. 1-17 may be rearranged and/or combined into a single component, step, feature, or function or embodied in several components, steps, or functions. Additional elements, components, steps, and/or functions may also be added without departing from novel features disclosed herein. The apparatus, devices, and/or components illustrated in FIGS. 1-17 may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The method claims present elements of the various steps in a sample order and are not meant to be limited to the specific order or hierarchy presented unless specifically recited therein. While some examples illustrated herein depict only time and frequency domains, additional domains, such as a spatial domain, are also contemplated in this disclosure.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein but are to be accorded the full scope consistent with the language of the claims, where reference to an element in the singular is not intended to mean “one and only one” unless specifically so stated, but rather “one or more.” Unless specifically stated otherwise, the term “some” refers to one or more.

The word “obtain” as used herein may mean, for example, acquire, calculate, construct, derive, determine, receive, and/or retrieve. The preceding list is exemplary and not limiting. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public, regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

As used herein, the term “determine” or “determining” encompasses a wide variety of actions and, therefore, “determining” can include calculating, computing, processing, deriving, investigating, looking up (such as via looking up in a table, a database, or another data structure), inferring, ascertaining, measuring, and the like. Also, “determining” can include receiving (such as receiving information), accessing (such as accessing data stored in memory), transmitting (such as transmitting information), and the like. Also, “determining” can include resolving, selecting, obtaining, choosing, establishing, and other similar actions.

As used herein, a phrase referring to “at least one of” a list of items refers to any combination of those items, including single members. As an example, “at least one of: a, b, or c” is intended to cover: a, b, c, a-b, a-c, b-c, and a-b-c. As used herein, “or” is intended to be interpreted in the inclusive sense, unless otherwise explicitly indicated. For example, “a or b” may include a only, b only, or a combination of a and b. Similarly, a phrase referring to A and/or B may include A only, B only, or a combination of A and B. Additionally, the word “or” may be represented by the “/” symbol. As used herein, the structure “one of: A, B, and C” may be understood as meaning “A or B or C.”

As used herein, “based on” is intended to be interpreted in the inclusive sense, unless otherwise explicitly indicated. For example, “based on” may be used interchangeably with “based at least in part on,” “associated with,” or “in accordance with” unless otherwise explicitly indicated. Specifically, unless a phrase refers to “based on only ‘a,’” or the equivalent in context, whatever it is that is “based on ‘a,’” or “based at least in part on ‘a,’” may be based on “a” alone or based on a combination of “a” and one or more other factors, conditions, or information.

The various illustrative components, logic, logical blocks, modules, circuits, operations, and algorithm processes described in connection with the examples disclosed herein may be implemented as electronic hardware, firmware, software, or combinations of hardware, firmware, or software, including the structures disclosed in this specification and the structural equivalents thereof. The interchangeability of hardware, firmware, and software has been described generally, in terms of functionality, and illustrated in the various illustrative components, blocks, modules, circuits and processes described above. Whether such functionality is implemented in hardware, firmware, or software depends upon the particular application and design constraints imposed on the overall system.

Various modifications to the examples described in this disclosure may be readily apparent to persons having ordinary skill in the art, and the generic principles defined herein may be applied to other examples without departing from the spirit or scope of this disclosure. Thus, the claims are not intended to be limited to the examples shown herein but are to be accorded the widest scope consistent with this disclosure, the principles, and the novel features disclosed herein.

Additionally, various features that are described in this specification in the context of separate examples also can be implemented in combination in a single implementation. Conversely, various features that are described in the context of a single implementation can also be implemented in multiple examples separately or in any suitable subcombination. As such, although features may be described above as acting in particular combinations and even initially claimed as such, one or more features from a claimed combination can, in some cases, be excised from the combination, and the claimed combination may be directed to a subcombination or variation of a subcombination.

Similarly, while operations are depicted in the drawings in a particular order, this should not be understood as requiring that such operations be performed in the particular order shown or in sequential order or that all illustrated operations be performed to achieve desirable results. Further, the drawings may schematically depict one or more example processes in the form of a flowchart or flow diagram. However, other operations that are not depicted can be incorporated into the example processes that are schematically illustrated. For example, one or more additional operations can be performed before, after, simultaneously, or between any of the illustrated operations. In some circumstances, multitasking and parallel processing may be advantageous. Moreover, the separation of various system components in the examples described above should not be understood as requiring such separation in all examples, and it should be understood that the described program components and systems can generally be integrated together into a single software product or packaged into multiple software products.

What is claimed is:

1. An apparatus, comprising:
one or more memories; and
one or more processors coupled to the one or more memories, the one or more processors being configured to, individually or collectively, based at least in part on information stored in the one or more memories:
receive a network signaling value, and
adjust a digital pre-distortion (DPD) sampling rate associated with a digital pre-distortion circuit in response to the network signaling value.

2. The apparatus of claim 1, wherein the network signaling value includes information indicative of a constraint on emissions required by a network.

3. The apparatus of claim 1, wherein the one or more processors are further configured to:
adjust the DPD sampling rate associated with the digital pre-distortion circuit in response to the network signaling value being associated with at least one configured characteristic of the apparatus.

4. The apparatus of claim 3, wherein the at least one configured characteristic includes at least one of:
a transmission band,
a transmission channel center frequency,
a transmission channel bandwidth,
a transmission channel identifier,
an operating characteristic of one or more transmitters coupled to the one or more processors of the apparatus,
a value of a starting resource block and a number of resource blocks,
a modulation of a transmitted signal, or
a type of the transmitted signal.

5. The apparatus of claim 4, wherein the transmission channel identifier is at least one of:
a center frequency,
a frequency band defined between a lower channel frequency and an upper channel frequency,
an absolute radio frequency channel number (ARFCN),
a new radio ARFCN (NR-ARFCN), or
a global synchronization channel number (GSCN).

6. The apparatus of claim 1, wherein the one or more processors are further configured to:
transmit a signal sampled at the DPD sampling rate in a transmission channel having a transmission channel center frequency; and
adjust the DPD sampling rate based on a distance between the transmission channel center frequency and a closest one of an emission band lower frequency and an emission band upper frequency defined by the network signaling value.

7. The apparatus of claim 6, wherein to adjust the DPD sampling rate based on the distance, the one or more processors are further configured to one of:
increase the DPD sampling rate in response to the DPD sampling rate being less than the distance,
maintain the DPD sampling rate in response to the DPD sampling rate being greater than the distance,
maintain the DPD sampling rate in response to the DPD sampling rate being less than the distance and the DPD sampling rate plus a margin being less than the distance, and
increase the DPD sampling rate in response to the DPD sampling rate being less than the distance and the DPD sampling rate plus the margin being greater than the distance.

8. The apparatus of claim 1, wherein the one or more processors are further configured to:
apply, at the digital pre-distortion circuit, digital pre-distortion to a digital signal sampled at the adjusted DPD sampling rate;
convert the digitally pre-distorted digital signal to an analog signal;
upconvert, in frequency, the analog signal; and
input the upconverted analog signal to a power amplifier, an output of the power amplifier being linearized with respect to the input by the digital pre-distortion applied to the digital signal sampled at the adjusted DPD sampling rate.

9. The apparatus of claim 1, wherein the one or more processors are further configured to:
maintain, in the one or more memories, a table of a plurality of tabulated network signaling values and associated transmission characteristics; and
adjust the DPD sampling rate associated with the digital pre-distortion circuit in response to matching the network signaling value and an associated configured transmission characteristic to one of the plurality of tabulated network signaling values and associated transmission characteristics, respectively.

10. The apparatus of claim 1, wherein to adjust the DPD sampling rate, the one or more processors are further configured to:
increase the DPD sampling rate from a first DPD sampling rate to a second DPD sampling rate in response to configuring the apparatus with the network signaling value and at least one transmission characteristic that match a stored network signaling value and an associated stored transmission characteristic, respectively; and
change the DPD sampling rate from the second DPD sampling rate to a third DPD sampling rate in response to reconfiguring the apparatus to eliminate the match with the stored network signaling value and the associated stored transmission characteristic, respectively, wherein the third DPD sampling rate may be equal to the first DPD sampling rate or another DPD sampling rate different from the first DPD sampling rate and the second DPD sampling rate.

11. The apparatus of claim 1, wherein the one or more processors are further configured to:
configure a transmission channel having a transmission channel center frequency;
define, based on the network signaling value, an emission band between an emission band lower frequency and an emission band upper frequency, greater than the emission band lower frequency; and
adjust the DPD sampling rate associated with the digital pre-distortion circuit by being further configured to one of:
increase the DPD sampling rate in response to a first value corresponding to the DPD sampling rate being less than a second value corresponding to a distance between the transmission channel center frequency and a closest one of the emission band lower frequency or the emission band upper frequency, and
maintain the DPD sampling rate in response to the first value being greater than the second value.

12. The apparatus of claim 1, wherein the one or more processors are further configured to:
configure a transmission channel having a transmission channel center frequency;
define, based on the network signaling value, an emission band between an emission band lower frequency and an emission band upper frequency, greater than the emission band lower frequency; and
adjust the DPD sampling rate associated with the digital pre-distortion circuit based on the DPD sampling rate and a distance between the transmission channel center frequency and a closest one of the emission band lower frequency or the emission band upper frequency.

13. A method at an apparatus, comprising:
receiving a network signaling value, and
adjusting a digital pre-distortion (DPD) sampling rate associated with a digital pre-distortion circuit in response to the network signaling value.

14. The method of claim 13, wherein the network signaling value includes information indicative of a constraint on emissions required by a network.

15. The method of claim 13, further comprising:
adjusting the DPD sampling rate associated with the digital pre-distortion circuit in response to the network signaling value being associated with at least one configured characteristic of the apparatus.

16. The method of claim 15, wherein the at least one configured characteristic includes at least one of:
a transmission band,
a transmission channel center frequency,
a transmission channel bandwidth,
a transmission channel identifier,
an operating characteristic of one or more transmitters of the apparatus,
a value of a starting resource block and a number of resource blocks,
a modulation of a transmitted signal, or
a type of the transmitted signal.

17. The method of claim 16, wherein the transmission channel identifier is at least one of:
a center frequency,
a frequency band defined between a lower channel frequency and an upper channel frequency,
an absolute radio frequency channel number (ARFCN),
a new radio ARFCN (NR-ARFCN), or
a global synchronization channel number (GSCN).

18. The method of claim 13, further comprising:
transmitting transmit a signal sampled at the DPD sampling rate in a transmission channel having a transmission channel center frequency; and
adjusting the DPD sampling rate based on a distance between the transmission channel center frequency and a closest one of an emission band lower frequency and an emission band upper frequency defined by the network signaling value.

19. The method of claim 18, wherein the adjusting the DPD sampling rate based on the distance, further comprises one of:
increasing the DPD sampling rate in response to the DPD sampling rate being less than the distance,
maintaining the DPD sampling rate in response to the DPD sampling rate being greater than the distance,
maintaining the DPD sampling rate in response to the DPD sampling rate being less than the distance and the DPD sampling rate plus a margin being less than the distance, and
increasing the DPD sampling rate in response to the DPD sampling rate being less than the distance and the DPD sampling rate plus the margin being greater than the distance.

20. The method of claim 13, further comprising:
applying, at the digital pre-distortion circuit, digital pre-distortion to a digital signal sampled at the adjusted DPD sampling rate;
converting the digitally pre-distorted digital signal to an analog signal;
upconverting, in frequency, the analog signal; and
inputting the upconverted analog signal to a power amplifier, an output of the power amplifier being linearized with respect to the input by the digital pre-distortion applied to the digital signal sampled at the adjusted DPD sampling rate.

21. The method of claim 13, further comprising:
maintaining a table of a plurality of tabulated network signaling values and associated transmission characteristics; and
adjusting the DPD sampling rate associated with the digital pre-distortion circuit in response to matching the network signaling value and an associated configured transmission characteristic to one of the plurality of tabulated network signaling values and associated transmission characteristics, respectively.

22. The method of claim 13, wherein adjusting the DPD sampling rate further comprises:
increasing the DPD sampling rate from a first DPD sampling rate to a second DPD sampling rate in response to configuring the apparatus with the network signaling value and at least one transmission characteristic that match a stored network signaling value and an associated stored transmission characteristic, respectively; and
changing the DPD sampling rate from the second DPD sampling rate to a third DPD sampling rate in response to reconfiguring the apparatus to eliminate the match with the stored network signaling value and the associated stored transmission characteristic, respectively, wherein the third DPD sampling rate may be equal to the first DPD sampling rate or another DPD sampling rate different from the first DPD sampling rate and the second DPD sampling rate.

23. The method of claim 13, further comprising:
configuring a transmission channel having a transmission channel center frequency;
defining, based on the network signaling value, an emission band between an emission band lower frequency and an emission band upper frequency, greater than the emission band lower frequency; and
adjusting the DPD sampling rate associated with the digital pre-distortion circuit by one of:
increasing the DPD sampling rate in response to a first value corresponding to the DPD sampling rate being less than a second value corresponding to a distance between the transmission channel center frequency and a closest one of the emission band lower frequency or the emission band upper frequency, and
maintaining the DPD sampling rate in response to the first value being greater than the second value.

24. The method of claim 13, further comprising:
configuring a transmission channel having a transmission channel center frequency;
defining, based on the network signaling value, an emission band between an emission band lower frequency and an emission band upper frequency, greater than the emission band lower frequency; and
adjusting the DPD sampling rate associated with the digital pre-distortion circuit based on the DPD sampling rate and a distance between the transmission channel center frequency and a closest one of the emission band lower frequency or the emission band upper frequency.

25. An apparatus, comprising:
one or more memories; and
one or more processors coupled to the one or more memories, the one or more processors being configured to, individually or collectively, based at least in part on information stored in the one or more memories:
receive a network signaling value defining at least a transmission channel bandwidth, an emission band lower frequency, and an emission band upper frequency,
digitally pre-distort a digital signal sampled at a digital pre-distortion (DPD) sampling rate,
convert the digitally pre-distorted digital signal to an analog signal,
upconvert, in frequency, the analog signal,
input the upconverted analog signal to a power amplifier configured to transmit at a transmission channel center frequency within the transmission channel bandwidth, and
adjust the DPD sampling rate based on a distance between the transmission channel center frequency and a closest one of the emission band lower frequency or the emission band upper frequency.

26. The apparatus of claim 25, wherein the one or more processors are further configured to:
adjust the DPD sampling rate in response to:
matching the network signaling value and the transmission channel bandwidth to a stored network signaling value and an associated stored transmission channel bandwidth, respectively, and
the distance being more than the DPD sampling rate and less than the DPD sampling rate plus a margin.

27. The apparatus of claim 26, wherein the one or more processors are further configured to:
maintain, in the one or more memories, a table of a plurality of tabulated network signaling values and associated transmission characteristics, wherein
the stored network signaling value and the associated stored transmission channel bandwidth are included in the table.

28. The apparatus of claim 25, wherein to adjust the DPD sampling rate, the one or more processors are further configured to one of:
increase the DPD sampling rate in response to matching the network signaling value and the transmission channel bandwidth to a stored network signaling value and an associated stored transmission channel bandwidth, respectively, and the distance being more than the DPD sampling rate and less than the DPD sampling rate plus a margin, or
maintain the DPD sampling rate in response to at least one of:
the network signaling value and the transmission channel bandwidth failing to match the stored network signaling value and the associated stored transmission channel bandwidth, respectively,
the distance being less than the DPD sampling rate, or
the distance being more than the DPD sampling rate plus the margin.

29. The apparatus of claim 25, wherein the one or more processors are further configured to:
transmit, via the power amplifier, a linearized representation of the digitally pre-distorted digital signal sampled at an increased DPD sampling rate within the transmission channel bandwidth and transmit, within an emission band defined between the emission band lower frequency and the emission band upper frequency, emissions constrained according to limits defined by the network signaling value.

30. The apparatus of claim 25, wherein the DPD sampling rate is also based on at least one of:
a transmission band,
the transmission channel center frequency,
the transmission channel bandwidth,
a transmission channel identifier,
an operating characteristic of one or more transmitters coupled to the one or more processors of the apparatus,
a value of a starting resource block and a number of resource blocks,
a modulation of a transmitted signal, or
a type of the transmitted signal.
